(19) United States
(12) Patent Application Publication
(10) Pub. No.: US 2026/0160160 A1
(43) Pub. Date: Jun. 11, 2026

(54) MONITORING CEMENT INTEGRITY FOR HYDROGEN LEAKAGE

(71) Applicant: Halliburton Energy Services, Inc., Houston, TX (US)

(72) Inventors: Christopher Michael Jones, Houston, TX (US); Daniel Joshua Stark, Carrollton, TX (US); EHAB ABDELRAHMAN ALI NAJM, Abu Dhabi (GB); Wael Soliman Mohamed Elhawary, Houston, TX (US)

(73) Assignee: Halliburton Energy Services, Inc., Houston, TX (US)

(21) Appl. No.: 19/406,805

(22) Filed: Dec. 2, 2025

Related U.S. Application Data
(60) Provisional application No. 63/729,012, filed on Dec. 6, 2024.

(51) Int. Cl. E21B 47/117

(52) U.S. Cl. CPC E21B 47/117

(57) ABSTRACT

Methods and systems disclosed may comprise: disposing a downhole tool into a subsurface formation; and embedding a contrast agent composition at a first position with the downhole tool, wherein the contrast agent composition reacts with at least one target subsurface fluid or gas migrating through or around a barrier forming one or more reaction products. In addition, methods and systems may comprise performing one or more formation logging measurements capable of detecting one or more reaction products with the downhole tool; and analyzing the one or more formation logging measurements for hydrogen leakage.

### CROSS REFERENCE TO RELATED APPLICATIONS

This application claims the priority of U.S. Provisional Patent Application No. 63/729,012, filed Dec. 6, 2024, which is incorporated by reference in its entirety.

### BACKGROUND

Geologic Hydrogen (also referred to as White Hydrogen) refers to naturally occurring hydrogen gas (H₂) found within Earth's subsurface, independent of biological or anthropogenic sources. Unlike hydrogen derived from hydrocarbon sources (gray hydrogen), renewable energy-powered electrolysis (green hydrogen), or steam methane reforming with carbon capture (blue hydrogen), geologic hydrogen is generated through abiotic geological and geochemical processes, making it sustainable energy exploration.

White hydrogen, or naturally occurring geologic hydrogen (H₂), represents a promising frontier in the quest for sustainable and clean energy sources. Unlike green hydrogen, which is produced from water electrolysis, or blue hydrogen, derived from natural gas with carbon capture, white hydrogen is found naturally within the Earth's subsurface. This form of hydrogen has garnered increasing attention due to its potential to provide a cost-effective and environmentally friendly alternative to conventional fossil fuels. With its abundance in specific geological formations, white hydrogen could become a critical component of the global energy mix, contributing to the reduction of carbon emissions and the transition towards a more sustainable energy future.

One of the primary challenges in identifying hydrogen (H₂) separately from methane (CH₄) and other gases such as carbon dioxide (CO₂) and nitrogen (N₂) lies in the overlapping physical and chemical properties that these gases often exhibit in subsurface environments. H₂ and CH₄, for example, both contain hydrogen, which may complicate their differentiation using standard hydrogen-index-based tools. Additionally, the similar molecular sizes and behaviors of these gases may result in overlapping signals in techniques like nuclear magnetic resonance (NMR) and neutron logging, making it difficult to accurately quantify the concentration of each gas. Furthermore, the presence of water in many reservoirs, which also contributes to hydrogen signals, adds another layer of complexity. This necessitates the development and integration of advanced logging and analytical techniques that may finely discriminate between these gases based on their unique diffusion rates, relaxation times, and other specific properties. Achieving this level of differentiation is crucial for accurately assessing the economic viability of hydrogen-rich prospects.

Surface data logging techniques, while valuable, often face significant challenges in pinpointing the exact reservoir location of gases such as hydrogen (H₂). These methods typically provide a ratio of relative concentrations rather than absolute concentrations, making it difficult to precisely quantify the amount of gas, ie H₂, present in a specific layer of the subsurface. This issue is further complicated when nearby layers contribute to the gas mixture as it travels up the mud system during drilling, leading to merged signals that may obscure the true source and concentration of the gases. As a result, relying solely on surface data logging may introduce uncertainties that hinder the accurate assessment of hydrogen-rich reservoirs, underscoring the need for integrated subsurface logging techniques that may provide more detailed and reliable data.

Formation testing, while invaluable for confirming the content of a gas and providing high-quality samples for further analysis, is inherently limited by its need to be positioned for stationary measurements. This implementation makes it less practical for first-pass zonal identification, where rapid and continuous data acquisition across multiple layers is essential. Moreover, while formation testers are effective at directly measuring CO₂ and CH₄ concentrations, they cannot detect N₂ or H₂ directly, creating a gap in the ability to fully characterize the gas mixture. Additionally, these tools often struggle with accurately measuring the low concentrations of water vapor present in the gas, even when the gas is at saturation. These limitations highlight the need for a more comprehensive example that integrates formation testing with other logging techniques to achieve a complete and accurate assessment of potential hydrogen-rich zones.

Pulsed neutron logging is a valuable tool for detecting total hydrogen content within a formation, but it does not have the capability to discern the molecular speciation of hydrogen-bearing compounds. This means that while it may indicate the presence of hydrogen, it cannot differentiate between H₂, water, or hydrocarbons like methane (CH₄). On the other hand, Proton Nuclear Magnetic Resonance (NMR) logging offers the potential to separate methane from other gases based on its unique T1 and T2 relaxation time. The relaxation times of methane and H₂ are temperature, pressure, and concentration dependent, therefore, at certain downhole conditions, their values may significantly overlap. In addition, in reservoirs, both gas may be partially dissolved in formation water, which may further affect their relaxation time values. Such complication presents a significant challenge in quantifying H₂ and methane in the underground formation. These factors make H₂ difficult to directly measure using standard NMR logging techniques, as the H₂ signal may decay too rapidly to be captured effectively. Consequently, while both pulsed neutron and NMR tools contribute important insights, they are limited in their ability to independently and directly quantify hydrogen gas in its molecular form within the subsurface.

The dominant natural process producing geologic hydrogen is serpentinization, a hydration and oxidation reaction primarily involving mafic and ultramafic minerals, notably olivine and pyroxene. During serpentinization, water reacts with minerals such as olivine [(Mg,Fe)₂SiO₄], converting them into serpentine minerals [Mg₃Si₂O₅(OH)₄], Brucite [Mg(OH)₂] and magnetite (Fe₃O₄). The reaction involves the oxidation of iron from Fe²⁺ to Fe³⁺, releasing molecular hydrogen (H₂). The generalized reaction for serpentinization involving olivine is represented as: (Mg,Fe)₂SiO₄ (olivine)+H₂O→Serpentine+Brucite+Magnetite+H₂. The released hydrogen may migrate through geological formations and accumulate in geological traps, forming reservoirs that may potentially be targeted for commercial extraction.

Radiolysis is another mechanism for geologic hydrogen formation, involving the interaction between radioactive decay products (e.g., from uranium, thorium, and potassium) and subsurface water. The radiation emitted by these elements splits water molecules (H₂O) into hydrogen (H₂) and oxygen (O₂). This mechanism, though typically contributing smaller volumes compared to serpentinization, may nevertheless be significant over geological timescales, particularly in deep crystalline basements or areas rich in radioactive minerals.

Mechanical and frictional interactions associated with tectonic activity, faulting, and seismic events may also generate hydrogen through processes such as mechanochemical reactions. High pressures and shear forces during fault movements may directly dissociate water or produce radical species that subsequently recombine into hydrogen gas.

Hydrogen gas may be released directly from magmatic systems during volcanic activity. Although transient, this process contributes to localized hydrogen occurrences and may complement longer-term hydrogen production mechanisms. Geologic hydrogen represents a clean, potentially abundant, renewable resource with minimal environmental impact if effectively harnessed. Detecting and mapping geologic hydrogen accumulations pose challenges due to its chemical reactivity, high mobility, and lack of direct visibility with traditional hydrocarbon exploration methods. However, its distinctive chemical and physical properties offer unique opportunities for indirect detection through innovative petrophysical logging techniques, including nuclear logging, electromagnetic (EM) methods, acoustic logging, nuclear magnetic resonance (NMR), and formation testing. Identifying and characterizing geologic hydrogen reservoirs not only broadens our understanding of Earth's subsurface processes but also opens new avenues for sustainable energy resources, complementing the global transition toward renewable energy systems.

Geologic hydrogen (white hydrogen) is rarely found as a pure, isolated gas within subsurface reservoirs. Instead, it typically occurs in combination with various other naturally occurring gases such as carbon dioxide (CO₂), methane (CH₄), nitrogen (N₂) and to a lesser extent sometimes Helium (He). This co-occurrence results from the geochemical processes responsible for hydrogen production, which often simultaneously yield other gas species. For example, serpentinization reactions frequently generate hydrogen alongside smaller quantities of methane and may also mobilize or react with dissolved inorganic carbon, producing CO₂. Hydrogen over geologic time often reacts with any free carbon to produce Methane gas. Nitrogen is also associated with radiogenic production, volcanic and magmatic activity. Radiolytic reactions, similarly, often yield hydrogen gas in environments that may also accumulate nitrogen or trace noble gases like helium.

The presence of water is another common and complicating factor within geologic hydrogen reservoirs. Subsurface accumulations of hydrogen frequently coexist with formation water, present in both liquid and gaseous states depending on reservoir pressure, temperature, and composition. At elevated pressures and moderate temperatures typical of deep subsurface environments, water may exist primarily in liquid form, creating multiphase fluid conditions. These multiphase conditions may affect the partitioning behavior of hydrogen, carbon dioxide, methane, and nitrogen, leading to complex gas-liquid equilibria.

The multiphase nature of geologic hydrogen reservoirs introduces significant challenges for subsurface characterization, including fluid sampling and logging-based detection methods. Water saturation within reservoirs influences gas mobility, gas-phase distribution, and reservoir deliverability, affecting both the practical extraction of hydrogen and its detectability through petrophysical logging. Therefore, reliable identification and quantification of hydrogen in the subsurface may implement specialized logging techniques that clearly distinguish hydrogen from the various coexisting fluids, particularly CO₂, CH₄, N₂, and water, that commonly complicate these natural accumulations.

Geologic hydrogen and its associated gases (carbon dioxide, methane, nitrogen) may accumulate subsurface in various physical states depending on the reservoir's temperature, pressure, and composition. Under certain conditions, these gases may exist primarily dissolved within formation water, occupying what is conventionally known as a water leg of the reservoir. If reservoir conditions, specifically pressure and temperature, are conducive, hydrogen-rich gases may also separate out of solution to form a distinct, buoyant gas cap overlying a water-bearing reservoir zone. Thus, geologic hydrogen reservoirs may resemble conventional hydrocarbon accumulations, exhibiting a clear vertical fluid distribution, with a gas cap above an underlying water leg containing dissolved gases. Understanding and identifying this phase behavior is critical for effective detection, characterization, and potential extraction of naturally occurring hydrogen accumulations.

Typical reservoirs containing geologic hydrogen often exhibit conditions similar to or notably more extreme than conventional oil and gas reservoirs. While many traditional petroleum reservoirs maintain relatively benign conditions, geologic hydrogen accumulations frequently occur at higher temperatures and pressures. Typical hydrogen-rich reservoirs commonly exhibit temperatures ranging from about 75° C. to 200° C., yet may also exist at significantly elevated temperatures of 300° C. or even higher. Similarly, reservoir pressures typically fall within the moderate range of approximately 1,000 psi to 5,000 psi, but conditions may extend to extreme pressures of up to 20,000 psi or beyond. These elevated temperature and pressure conditions result from the deep geological environments and active geochemical processes, such as serpentinization or hydrothermal systems, that produce and trap geologic hydrogen, further emphasizing the necessity for specialized logging and detection examples designed to withstand such harsh subsurface conditions.

At present, no commercial petrophysical logging tool is explicitly designed to directly detect and differentiate molecular diatomic hydrogen (H₂) from other naturally occurring gases or fluids in subsurface reservoirs and especially those containing hydrogen. Conventional logging methods, such as acoustic and electromagnetic (EM) techniques, do not specifically detect hydrogen molecules; rather, these tools measure fundamental formation properties like acoustic velocity, acoustic impedance, formation density, electrical resistivity, dielectric permittivity, and conductivity. These measured properties indirectly reflect the presence of gas versus liquid or solid phases within reservoir formations. As a result, interpretation of acoustic and EM logs must rely on petrophysical analyses that infer the presence of gas accumulations generally, rather than explicitly identifying hydrogen gas specifically. Consequently, these techniques alone cannot distinguish molecular hydrogen from associated gases like methane (CH₄), nitrogen (N₂), carbon dioxide (CO₂), or water in its liquid and gaseous phases.

Other common petrophysical logging methods, notably Nuclear Magnetic Resonance (NMR) and nuclear logging techniques (such as neutron porosity and gamma-ray spectroscopy), do directly detect the presence of hydrogen nuclei. NMR, for example, provides measurements sensitive to hydrogen-containing fluids within the pore space, offering information about hydrogen content, fluid phase, porosity distribution, pore size distribution, fluid mobility, and fluid saturation. NMR using T1 and T2 signals may in theory distinguish H₂ gas from methane and gaseous water (and would be insensitive to nitrogen, helium and carbon dioxide), however, the signal separation is difficult especially in real world situations with mineralogical effects, pore size distribution effects, and temperature and pressure effects, especially if the methane and hydrogen gas are dissolved in a water leg, or adsorbed to surfaces as may be the case. Similarly, nuclear techniques such as neutron porosity logging detect hydrogen due to neutron moderation primarily by hydrogen nuclei. However, these nuclear-based methods inherently measure hydrogen in all chemical forms, be it molecular hydrogen gas, hydrocarbons such as methane, or water in various phases, without directly differentiating the specific chemical form of the hydrogen. Thus, although NMR and nuclear logging tools offer critical insights into the hydrogen-bearing fluid content of subsurface reservoirs, interpreting these data specifically for molecular hydrogen remains challenging due to ambiguities in discriminating between hydrogen-rich gas phases, liquid hydrocarbons, and water.

Formation testing may be used to detect pressure gradients which are indicative of fluid density but not uniquely composition. Also formation testing sensors (save NMR with its own forementioned complications) are generally not available to diatomic hydrogen, and though may sense water, carbon dioxide or methane cannot distinguish hydrogen from nitrogen or helium. It is also desirable to detect geologic hydrogen potential in the reservoir prior to formation testing.

Ultimately, accurately identifying and quantifying molecular diatomic hydrogen in geological reservoirs using existing logging techniques may implement an integrated petrophysical interpretation example. By combining measurements from multiple logging tools, including acoustic, EM, NMR, nuclear logs, and fluid sampling, geoscientists and paraphysicists may better infer the likely presence of molecular hydrogen accumulations. Even so, this indirect detection example highlights the existing technological gap and the clear need for specialized tools and innovative methodologies specifically designed to detect and differentiate molecular hydrogen from other hydrogen-containing compounds in subsurface environments.

Given the inherent limitations of conventional petrophysical logging techniques, either due to their inability to detect hydrogen specifically (as with acoustic and electromagnetic methods) or their inability to differentiate molecular diatomic hydrogen from other hydrogen-containing species (as with nuclear magnetic resonance and neutron-based methods), new methods would be useful to improve the detection and discrimination of geologic hydrogen reservoirs. A promising solution proposed herein involves the use of specialized chemical contrast agents that are introduced into the wellbore through drilling mud systems or deployed as targeted chemical “pills” directly into specific zones intended for logging.

Moreover, current methods for monitoring cement integrity and detecting hydrogen leakage within subsurface reservoirs, wellbores, pipelines, and related infrastructure are inadequate for reliably identifying early-stage fluid migration or breaches in isolation barriers. Existing examples often fail to detect minor leaks promptly or distinguish at least one reactive component within the subsurface formation fluid such as gases, such as molecular hydrogen, from background formation fluids and gases. Additionally, long-term, low-power, continuous monitoring solutions that may precisely locate and immediately report integrity issues are lacking, leading to delayed detection, increased operational risks, environmental hazards, and higher remediation costs. Therefore, improved systems and methodologies are needed that enable selective, immediate detection and accurate localization of hydrogen leakage or migration, combined with automated or remotely triggered corrective measures, enhancing operational safety, environmental compliance, and the long-term reliability of subsurface storage and transportation infrastructure.

### BRIEF DESCRIPTION OF THE DRAWINGS

These drawings illustrate certain aspects of some examples of the present disclosure and should not be used to limit or define the disclosure.

FIG. 1 illustrates a logging while drilling operation utilizing a pulsed neutron logging tool, in accordance with examples of the present disclosure.

FIG. 2 illustrates the pulsed neutron logging tool in a wireline operation, in accordance with examples of the present disclosure.

FIG. 3 is a diagram of illustrative examples of a pulsed neutron logging tool.

FIG. 4A-4D are diagrams illustrating different distances between parts within the pulsed neutron logging tool.

FIG. 5 illustrates the energy of a neutron as it interacts in a time sequence in the present disclosure.

FIGS. 6A-6C are different examples of a Nuclear Magnetic Resonance tool.

FIG. 7 illustrates a schematic of an information handling system.

FIG. 8 illustrates a schematic of a chip set.

FIG. 9 illustrates a computing network.

FIG. 10 illustrates a neural network.

### DETAILED DESCRIPTION

Examples disclosed herein may collectively provide comprehensive methods and systems for detecting, monitoring, and managing the leakage and migration of molecular hydrogen (H₂) and other reactive fluids within subsurface reservoirs, wellbore cements, and associated infrastructure. Specifically, reactive contrast agents are strategically embedded within cement or positioned at cement-formation interfaces, enabling chemical immobilization of migrating hydrogen and creating measurable reaction products detectable via downhole logging techniques. Permanently mounted, dormant sensor systems, configured for selective activation upon hydrogen exposure, emit acoustic, electromagnetic, electrical, or pressure-based telemetry signals to remotely indicate integrity breaches or fluid leakage. These sensors communicate either directly via wired connections or indirectly by modulating local fields to affect signal propagation in adjacent telemetry lines or fiber-optic cables. At surface installations, MEMS-based, microfluidic, optical, electroscopic, or electrophoretic sensors provide continuous hydrogen detection, coupled with automated control mechanisms that initiate immediate remedial actions, including automated sealing or self-healing processes. The described methods extend beyond wellbore environments, applicable to pipelines, subsea risers, downhole and surface equipment, processing facilities, and storage infrastructure, significantly enhancing overall asset-integrity management, operational safety, and environmental protection throughout the operational lifespan.

The commercial advantages provided by these claims include significantly enhanced detection accuracy and sensitivity for hydrogen and fluid leakage events, enabling rapid identification and precise localization of integrity breaches within wellbores, reservoirs, pipelines, and storage facilities. By enabling early-stage detection through embedded reactive contrast agents and permanently mounted dormant sensors, these methods substantially reduce risks associated with leaks, corrosion, and structural failures. The real-time or near-real-time telemetry and automated control mechanisms further minimize response times, thereby limiting environmental impacts, operational downtime, and costly remediation efforts. Additionally, these technologies facilitate proactive asset management and preventive maintenance, ultimately extending infrastructure lifespan and reliability. Collectively, these advancements contribute to improved regulatory compliance, reduced operational expenditures, minimized environmental liabilities, and increased public and investor confidence, directly enhancing overall economic performance and operational sustainability in hydrogen production, storage, transportation, and related industrial applications.

Combining proton NMR signal amplitude and relaxation time measurements for H2 and CH₄ with pulsed neutron logging for total hydrogen index offers a promising example to identifying zones with high residual hydrogen content, which could be indicative of H₂. The proton NMR signal is proportional to the total hydrogen content in the formation, and the relaxation time distribution and diffusivity distribution measurements is used to distinguish H2 fraction vs. methane fraction of the hydrogen content, as well as the hydrogen from formation water. However, as the NMR signal is weak, especially at low pressure and high temperature, the error bar of the total proton amplitude may be high. Thus, the pulsed neutron tool captures the overall hydrogen content within the formation may be a constraint to reduce the uncertainty of the quantification of hydrogen contents by NMR. By comparing the proton NMR signal amplitude and relaxation time measurements for H2 and CH₄ with pulsed neutron logging for total hydrogen index, it may be possible to identify discrepancies or residual hydrogen. This complementary use of NMR and pulsed neutron data could thus enable a more nuanced interpretation of subsurface conditions.

Once a potential zone of high residual hydrogen content is identified, which may be indicative of H₂, a stationary measurement using NMR may be employed to improve the signal-to-noise ratio (SNR) and enhance the accuracy of the detection. By halting the tool in the identified zone, the NMR pulse sequence may be specifically tuned to target H₂, thereby increasing the sensitivity of the measurement. An exemplary pulse sequence for the logging measurement is CPMG. This sequence allows for rapid acquisition of multiple echoes, improving SNR while minimizing signal loss from the fast diffusion of methane and geological H₂ gas molecules in the magnetic field gradient of the logging tool. Additionally, multiple echo spacing pulse sequence measurement may be deployed to resolve the diffusivity difference between liquid (formation water) and gaseous (methane and H2) phases, or between the two hydrogen containing gases, thereby further enhance the detection capability of different fluid types. The stationary measurement example, combined with an optimized pulse sequence, provides a robust method to confirm the presence of H₂ in the formation, thereby strengthening the interpretation and reducing the uncertainty in evaluating the economic potential of the zone.

Surface data logging may play a crucial role in identifying broad areas of interest by providing an initial overview of the gas composition in the subsurface. This technique may confirm the ratio of hydrogen to other gases within a broad area, albeit as a merged signal that combines contributions from multiple layers as the gas travels up the mud system. Once these areas of interest are identified, the NMR and pulsed neutron logging signals may be similarly analyzed in a merged fashion to validate these ratios and detect any potential missing gases, such as He that does on rare occasion infiltrate the reservoir, that were not accounted for in the 4 gas model. Additionally, surface data logging gas chromatograms offer the capability to precisely identify and quantify the gases present in the sample. This allows for the elimination of certain gases from consideration, sharpening the focus on those that are present and may indicate the presence CO2, N2 or CH4. Elimination of all hydrocarbon gases would nearly guarantee any signals obtained from NMR logging or pulsed neutron logging are due to the presence of H2. Liquid or bound hydrogen is very separable in T1, T2 NMR space and may be directly accounted for in the NMR logging. The integration of surface data logging with subsurface NMR and pulsed neutron measurements thus provides a comprehensive example to confirming the gas composition, improving the accuracy of hydrogen prospecting efforts.

Once high-potential layers are identified through conventional logging and surface data logging, formation testing may be employed to gather detailed information about the reservoir sections. This includes measuring the pressure within these potential reservoir sections to develop a pressure gradient, which is directly related to the reservoir's gas density. Formation testing allows for stationary measurements during pump outs, where the methane content, and higher hydrocarbons, if necessary, along with CO₂ content, may be precisely determined. Additionally, the formation tester may record crucial parameters such as pressure, temperature, gas compressibility, viscosity, mobility and gas density during these pump outs. The gas density measured by the pump out sensor may then be calibrated against the density derived from the pressure gradient, ensuring accuracy and providing a comprehensive understanding of the reservoir's gas composition. This integration of formation testing with other logging data enables a more accurate characterization of the reservoir, further validating the presence and concentration of economically viable levels of hydrogen.

Equation of state (EOS) modeling is a may be used to quantitatively determine the concentrations of gas components within a reservoir, even for those gases that cannot be directly observed. By integrating data from at least two of the multiphysics tools discussed such as NMR, pulsed neutron logging, surface data logging (SDL) gas analysis, and formation testing, EOS modeling enables a more complete and accurate characterization of the gas mixture in the reservoir. The model works by describing the thermodynamic properties of the gas mixture, including pressure, temperature, volume, and composition, allowing for the estimation of the concentration of individual gas components based on or constrained or regularized by available measurements. Further, utilizing multiple of the multiphysics measurements, a best fit estimate of the gas concentrations may be made. The best fit analysis may additionally be refined for the water saturated gas estimate. Also, by including the uncertainty estimates of each of the Multiphysics measurements, an estimate of the gas concentration in the reservoir may be made that optimizes the total uncertainty.

When combining NMR and formation testing with EOS modeling, the process begins with the NMR tool, which provides detailed information about the relaxation times (T1 and T2) of the gases present. While NMR may directly measure methane (CH₄) concentrations, it may not directly observe hydrogen (H₂) due to its short T1 and T2 relaxation times. Formation testing, on the other hand, provides critical measurements of gas density, compressibility, pressure, temperature, and viscosity, along with the concentrations of gases like CH₄ and CO₂. These data points are crucial inputs for EOS modeling, which uses them to estimate the overall composition of the gas mixture, including components like H₂ and N₂ that are not directly detected by the NMR or formation tester.

EOS modeling may reconcile the NMR-derived methane concentrations with the overall gas density and compressibility measurements obtained from formation testing. By applying the EOS to this integrated dataset, it is possible to infer the presence and concentration of H₂ and other undetected gases. For instance, if the modeled gas density from the EOS is higher than what would be expected from the methane and CO₂ concentrations alone, the model may suggest the presence of additional gases like H₂, contributing to the overall density.

Another effective combination involves pulsed neutron logging and SDL gas analysis. Pulsed neutron logging provides a total hydrogen index, which reflects the presence of all hydrogen-bearing compounds in the formation. However, it cannot distinguish between different hydrogen-containing molecules, such as H₂, CH₄, and water. SDL gas analysis, performed at the surface, may measure the relative concentrations of different gases, including those that might be difficult to detect downhole. These surface measurements, although they provide merged signals from various depths, may be integrated with downhole data in the EOS model to refine the interpretation.

In this case, EOS modeling takes the hydrogen index from pulsed neutron logging and compares it with the known concentrations of CH₄ and other gases from SDL analysis. By using the EOS to account for the contributions of each gas to the overall hydrogen index, the model may infer the proportion of hydrogen that may be attributed to H₂, as opposed to CH₄ or water. This quantitative determination is crucial for assessing the economic viability of hydrogen extraction from the reservoir, particularly in identifying zones where H₂ concentration is sufficiently high to warrant further development.

The stated combinations are exemplary and other combinations not directly stated may be combined using equation of state modeling. Equation of state (EOS) modeling techniques include a range of examples tailored to different applications, from the Ideal Gas Law, which assumes perfect gas behavior, to the Van der Waals equation, which corrects for molecular size and intermolecular forces. More sophisticated models like the Peng-Robinson and Soave-Redlich-Kwong (SRK) equations are widely used in petroleum engineering to predict the behavior of real gases under high pressure and temperature conditions. Additionally, PC-SAFT (Perturbed Chain-Statistical Associating Fluid Theory) offers a molecular-based EOS that is particularly effective for complex mixtures, such as those involving associating or polymeric fluids. Experimental techniques, such as laboratory PVT (Pressure-Volume-Temperature) analysis, complement these models by providing empirical data to refine and validate EOS predictions, ensuring accuracy in real-world applications.

Proxy modeling techniques, including but not limited to machine learning and symbolic regression models, as well as empirical modeling, may serve as effective alternatives to traditional equation of state (EOS) models. These examples leverage large datasets to identify patterns and relationships within complex systems, enabling the development of predictive models that may approximate the behavior of gas mixtures under various conditions. Machine learning models, for example, may be trained on historical data to predict gas properties with high accuracy, while symbolic regression may generate interpretable equations that mimic the underlying physics of the system. Empirical models, which are based on observed data rather than theoretical principles, may also provide reliable estimates for specific applications where conventional EOS models may fall short. These proxy models offer flexibility and adaptability, making them valuable tools in scenarios where traditional EOS methods are either too complex or not feasible.

The concept relies on selectively reactive contrast agents that specifically interact with target subsurface fluid or gas comprising molecular diatomic hydrogen (H₂), hydrogen sulfide, carbon dioxide, methane, ethane, any downhole fluid or gas and/or any combination thereof, while remaining inert or unreactive toward other commonly encountered fluids and gases, such as water (including acidic formation waters) and carbon-bound hydrogen species (e.g., methane or other hydrocarbons) or carbon dioxide. Candidate classes of such selective reactants include several types of metal hydride precursors, which readily and selectively form stable hydrides upon exposure to molecular hydrogen. Additionally, certain nitrogen-containing organic molecules, particularly nitriles and imines, demonstrate well-characterized and rapid hydrogenation reactions at moderate subsurface conditions (temperatures typically ranging from approximately 75° C. up to and beyond 200° C., and pressures from about 1,000 psi to 20,000 psi). These reactions may further be catalyzed to extend the number and type of hydrolyzation reactions available. These metal hydride, nitrile and imine species may function effectively as contrast agents themselves, transforming chemically upon exposure to molecular hydrogen, or they may be engineered further to incorporate additional detectable features.

To leverage their chemical selectivity in petrophysical logging, these hydrogen-specific contrast agents could be further enhanced by coupling them to other detectable functional groups or materials. Examples of such enhancements include attachment of acoustically resonant microspheres to facilitate acoustic logging identification, incorporation of organometallic complexes with distinct and uniquely detectable nuclear signatures (e.g., elements with characteristic neutron capture cross-sections or gamma-ray emissions), or conjugation to electrically conductive or resistive nanoparticles to yield clearly identifiable electromagnetic logging responses. In other examples, these contrast agents could be designed to precipitate selectively within hydrogen-rich formations, thereby physically altering formation properties in a measurable fashion detectable by logging tools.

By employing these selective hydrogen-reactive contrast agents, existing petrophysical logging tools, originally limited in their ability to uniquely identify molecular hydrogen, can now indirectly detect and differentiate H₂-rich zones through observable chemical, acoustic, nuclear, electromagnetic, or geometric changes induced specifically by molecular hydrogen. This example significantly enhances the resolution and reliability of geologic hydrogen detection and characterization, addressing existing technological gaps and enabling more effective exploration and development of natural hydrogen reservoirs. These techniques may additionally be applied to formation testing techniques in the reservoir or in the formation tester to enhance formation testing detection.

Metal hydrides are exceptionally promising candidates for detecting molecular hydrogen (H₂) in geological reservoirs due to their unique capability to selectively absorb and chemically bind hydrogen gas. During our comprehensive exploration of various metal hydrides, multiple specific types emerged as particularly suitable due to their favorable reaction kinetics, temperature stability, and selectivity towards molecular hydrogen. These metal hydrides include intermetallic alloys such as titanium-iron hydride (TiFe), lanthanum-nickel hydride (LaNi₅), magnesium hydride (MgH₂), and zirconium-based hydrides (e.g., ZrMn₂, ZrV₂). Each of these hydride precursors exhibits rapid hydrogen uptake at moderate to elevated subsurface conditions (typically ranging from about 75° C. up to 200° C. or more), with minimal or no reactivity toward common interfering species such as water, methane, carbon dioxide, or nitrogen.

To facilitate deployment into reservoir formations for petrophysical logging, the chosen example involves dispersing finely ground precursor powders, ranging from micro- to nano-sized particles, into a stable suspension medium. While an aqueous suspension could theoretically function, practical considerations strongly favor employing an organic, oil-based carrier fluid. Oil-based suspensions offer distinct advantages, including improved hydrogen solubility, enhanced diffusivity, minimal oxidative or hydroxide passivation of particle surfaces, and superior dispersion stability. When hydrogen gas diffuses through reservoir formations into contact with these finely dispersed hydride precursors, a rapid and selective absorption reaction occurs. Hydrogen molecules are chemically and physically bound, forming stable metal hydride compounds through the insertion of hydrogen atoms interstitially into the metal lattice.

An important and unique feature of this reaction is the subsequent physical and structural change of the suspended particles. Initially dispersed nano- or micro-sized precursor powders undergo substantial volumetric expansion upon hydride formation. This swelling leads to particle aggregation, interparticle bridging, and ultimately results in the creation of a robust, interlocking network of metal hydride particles within the pore structure of the reservoir rock. The formation of this interconnected solid matrix alters the petrophysical characteristics of the formation in measurable ways, such as changes in acoustic velocity and attenuation, formation resistivity, electromagnetic response, porosity, permeability, and NMR signals, allowing conventional logging tools to indirectly but reliably detect the localized presence of molecular hydrogen.

A particularly advantageous property of this interlocking metal hydride network is its reversibility under controlled conditions. Upon reduction of formation pressure, such as might occur during deliberate reservoir depressurization or fluid production, the absorbed hydrogen may desorb spontaneously, returning the hydride matrix to its original metallic precursor state. Furthermore, complete and rapid reversal of this network may be induced chemically via acid washing (generally below pH 2-3 a safe zone for most arctic reservoirs with pH 4-6), which dissolves the metallic components, liberating the bound hydrogen as free gas, and returning the reservoir formation to its original state. The dissolution reaction occurs rapidly in the presence of many acids (hydrochloric acid, acetic acid etc.), making it straightforward to manage operationally.

Thus, the strategic use of micro- to nano-sized metal hydride precursor particles, suspended in an organic or oil-based medium and further mixed into an oil based mud or as a specific pill, offers a versatile, highly selective, and practically reversible means of detecting molecular hydrogen in subsurface geological reservoirs. The formation of a distinctive interlocking particle network upon hydrogen uptake provides an innovative, indirect method to unequivocally identify and characterize hydrogen-rich formations using conventional petrophysical logging tools, significantly improving the reliability and resolution of geological hydrogen detection.

TABLE 1
Some characteristics of potential hydride forming alloys.

| | | Pressure | | |
|---|---|---|---|---|
| Alloy/ | Temp. Range | Suitability | Stability & | Cost & |
| Hydride | Suitability | (68-345 bar) | Practicality | Availability |
| TiFe | Excellent | Excellent | Excellent | Good, |
| | (75-200° C.) | | | affordable |
| MgH₂ | Moderate | Excellent | Good | Very |
| | (≥150- | | | inexpensive |
| | 200° C.) | | | |
| Zr-based | Excellent | Excellent | Excellent | Higher cost |
| | (75-200° C.) | | | |
| LaNi₅-type | Good | Excellent | Excellent | Moderate |
| | (75-150° C. | | | cost |
| | best) | | | |
| Sc | Good | Excellent | Excellent | High Cost |
| | (100-300° C.) | | | |
| Ti | Good | Excellent | Excellent | Good |
| | (75-150° C.) | | | |

When metal hydride precursors (such as TiFe, LaNi₅, Mg, or Zr-based alloys) are finely dispersed in an organic or oil-based suspension medium, the formation of metal hydrides proceeds very rapidly and efficiently. Oil-based liquids offer several key kinetic advantages: Minimal Oxide or Hydroxide Formation-Oil prevents or greatly reduces the oxidation or passivation of metal surfaces, thereby maintaining clean, reactive interfaces for efficient hydrogen uptake. Enhanced Hydrogen Solubility and Diffusion-Oils generally provide superior hydrogen solubility and diffusivity compared to water, enabling rapid transport of hydrogen molecules directly to the metal particle surfaces. Fast Reaction Kinetics-Under moderate conditions typical of subsurface environments (approximately 75-200° C. and pressures around 1000-5000 psi), hydride formation in oil-based slurries typically occurs in seconds to a few minutes. This rapid reaction ensures practical effectiveness for logging and subsurface detection purposes. Overall, oil-based suspensions closely approximate the fast reaction kinetics observed with dry powders, making them highly practical and favorable for field applications.

Conversely, dispersing metal hydride precursors in water-based slurries introduces some kinetic limitations and practical challenges, although may still be useful in some environments: Surface Passivation (Oxidation/Hydroxide Formation)—Water promotes the formation of oxide and hydroxide layers on particle surfaces, significantly reducing the direct metal-gas interface and severely inhibiting hydrogen absorption. Low Hydrogen Solubility and Poor Diffusion—The limited solubility and diffusivity of hydrogen in water slow hydrogen transport to particle surfaces, further slowing the reaction. Slow or reduced Hydride Formation-Under the same moderate conditions (75-200° C., 1000-5000 psi), hydride formation in aqueous slurries is slowed, occurring on the scale of tens of minutes to hours. Though technically feasible over extended times especially if logging is to occur hours after the contrast agent enters the reservoir, aqueous suspensions may be less practical for rapid field deployments due to their poor kinetics.

When introduced into the reservoir, the contrast-agent slurry, composed of micro- to nano-sized metal hydride precursor particles suspended in an organic, oil-based medium, penetrates into the subsurface formation through the existing pore and/or fracture network. Initially, this suspension migrates radially outward from the borehole due to differential pressure applied during deployment (typically through drilling mud circulation or a specialized pill injection), infiltrating deeply into the pore structure. The fine particle size and low viscosity of the carrier fluid facilitate efficient and relatively uniform penetration into porous zones of the formation, distributing the precursor particles along flow paths and across fluid interfaces.

As the metal hydride precursor particles within the suspension encounter formation fluids containing molecular hydrogen, rapid chemical reactions occur selectively at these fluid-particle interfaces. Specifically, molecular hydrogen dissolved or present in gaseous form within the formation fluids migrates toward and reacts with these precursor particles. This reaction effectively consumes the hydrogen at the interface, locally decreasing the hydrogen concentration and establishing a concentration gradient that continually draws additional hydrogen from the surrounding reservoir region toward the reactive front. This diffusion-driven mechanism significantly amplifies local hydrogen fluxes, concentrating hydrogen gas within a well-defined reaction zone around the wellbore in a localized ring, or other oblong shape dependent on the permeability profile. Further the metal or any associated metals are also concentrated in this region to the exclusion of the carrier slurry and any formation fluids.

The hydride formation reaction not only chemically binds the hydrogen but also induces significant volumetric expansion and particle agglomeration, resulting in the formation of a robust, interconnected hydride-particle network within the pore space. This process rapidly decreases local permeability and porosity, forming a distinct, concentrated, cylindrical or oblong-shaped region of reacted particles surrounding the borehole. The geometry of this reaction zone, often resembling a “bathtub ring”, depends primarily on the reservoir's original porosity, permeability distribution, and heterogeneity. Uniform reservoir conditions typically result in symmetrical, cylindrical reaction zones around the wellbore, whereas formations characterized by heterogeneous permeability or porosity distribution yield more oblong or irregular-shaped hydride deposition patterns aligned with preferential fluid-flow pathways.

This resulting geometric pattern provides a unique and measurable signature readily detectable by various petrophysical logging tools. Specifically, the sharply defined boundaries, reduced permeability, and altered acoustic, nuclear, electromagnetic, and NMR characteristics of the hydride-rich region yield distinctly identifiable signals. Consequently, this controlled, reactive contrast-agent deposition pattern significantly enhances the ability to detect and delineate molecular hydrogen-bearing reservoir zones, offering a powerful tool for improved subsurface characterization and evaluation of geologic hydrogen accumulations.

The introduction and subsequent reaction of metal hydride precursor particles with molecular hydrogen in subsurface reservoirs significantly enhance electromagnetic (EM) logging responses due to distinct changes in electrical and dielectric properties within the reservoir formation. Upon exposure to hydrogen, these initially dispersed metallic precursor particles undergo a rapid transformation, forming stable metal hydride networks characterized by interlocked, conductive pathways. Because this interconnected hydride structure possesses significantly different electromagnetic characteristics compared to the surrounding unreacted formation fluids and carrier suspension medium, both typically exhibiting much lower electrical conductivity, the resulting cylindrical or oblong-shaped hydride-rich region presents a pronounced electromagnetic contrast that is readily detectable by EM logging tools.

Firstly, the hydride reaction front creates a strongly conductive annular region around the borehole, effectively forming a distinctive conductive “shell” within the less conductive reservoir matrix or formation fluid background. This conductive ring structure drastically alters the local resistivity profile measured by induction and laterolog tools, providing a clearly identifiable and measurable EM anomaly. Such anomalies manifest as characteristic patterns in resistivity logs, distinctly reflecting the geometry and position of the metal hydride deposition region. Furthermore, the unique spatial arrangement and interlocking nature of the conductive hydride particle network greatly enhance the detection sensitivity of multi-depth resistivity measurements, enabling more accurate quantification of the extent and shape of hydrogen-bearing zones.

Secondly, in addition to conductivity contrasts, the metal hydride region exhibits notable differences in dielectric properties compared to the host formation and fluid-saturated pore spaces. Dielectric logging methods, which rely on measurements of dielectric permittivity and associated polarization effects, would reveal pronounced contrast due to the distinctly lower dielectric permittivity of the metal hydride interlocking network relative to fluid-filled pore spaces. This strong dielectric contrast further increases the detectability and interpretability of the hydride-precipitated zone, especially in complex reservoir conditions.

Lastly, the geometrically distinct “bathtub ring” or cylindrical deposition pattern of the hydride network offers a unique spatial signature that may be effectively detected and characterized by modern, multi-axis EM logging instruments. Multi-axis EM logging tools measure resistivity and dielectric properties along different spatial orientations, thus providing enhanced directional sensitivity. These tools are particularly adept at resolving anisotropic and geometrically complex features, precisely capturing the shape, size, and orientation of the cylindrical or oblong hydride formation around the wellbore.

The introduction of metal hydride precursors and the formation of a metal hydride framework around the borehole significantly enhance detection capabilities of nuclear logging techniques. One primary mechanism arises from the distinct increase in bulk density associated with the aggregated metallic hydride network. Metal hydrides, formed from precursor alloys such as TiFe, LaNi₅, Mg-based hydrides, or zirconium-based alloys, possess notably higher densities compared to typical reservoir fluids, formation rock, or the oil-based slurry medium. As the dispersed precursor particles react and aggregate, creating an interconnected, dense metallic network, the near-wellbore formation region exhibits a clearly measurable density contrast detectable by nuclear density logging tools.

To maximize the clarity of nuclear detection, several operational strategies may be employed. For instance, after sufficient reaction time for hydride formation, the original pill or mud containing unreacted precursor slurry may be flushed from the borehole and near-wellbore environment using controlled over pressurization or underbalanced circulation techniques. By intentionally displacing the unreacted slurry materials deeper into the formation, beyond the primary zone of hydride precipitation, background interference from dispersed precursor particles is minimized or eliminated. Consequently, the nuclear logging measurements become focused exclusively on the dense metallic hydride network itself, enhancing the clarity and reliability of detection.

Additionally, the detectability of the hydride framework may be greatly enhanced by carefully engineering the precursor alloys to contain trace amounts of highly nuclear-sensitive elements. Examples include gadolinium (Gd), europium (Eu), hafnium (Hf), boron (B), samarium (Sm), or cadmium (Cd), all elements characterized by exceptionally large neutron absorption cross-sections. Incorporation of these elements, even in very low concentrations, dramatically increases the contrast agent's nuclear detectability, particularly for neutron-based logs, enabling highly sensitive differentiation of the hydride region from surrounding reservoir material.

Further enhancement may be achieved by incorporating specific elements or isotopes within the precursor alloy that naturally emit gamma radiation. Elements such as potassium-40 (\hat{ }40K), thorium-232 (\hat{ }232Th), or uranium isotopes (\hat{ }235U, \hat{ }238U) emit distinctive gamma-ray signatures easily recognizable by gamma-ray spectroscopy logging tools. Trace incorporation of these radioactive elements provides a uniquely identifiable signature, unequivocally marking the reacted metal hydride zone.

An additional example for enhancing the detectability and unambiguous identification of reactive contrast agents involves embedding specific radiogenic isotopes within the contrast agent formulation to yield a unique, detectable signature that is orthogonal to the naturally occurring radioactive elements found in subsurface formations. Subsurface reservoirs commonly contain background concentrations of naturally occurring radiogenic elements, such as potassium (K), thorium (Th), and uranium (U), which may interfere with nuclear logging techniques, complicating the direct detection and differentiation of injected contrast agents. In other examples, addressing this interference involves performing differential logging (discussed herein), whereby a baseline log is acquired prior to contrast-agent introduction, and a subsequent log is obtained following the chemical reaction of the contrast agent, attributing any differential response specifically to the contrast agent reaction. However, this differential example inherently may implement additional logging time and operational complexity.

To improve upon this, radiogenic may instead be embedded within the reactive contrast agent in a pattern creating an orthogonal radioactive signature clearly distinguishable from naturally occurring isotopes. The presence of this uniquely orthogonal radiogenic signal therefore directly indicates selective reaction between the injected contrast agent and the targeted formation-fluid component, such as molecular hydrogen. This example significantly simplifies interpretation, eliminates the necessity of pre-injection baseline logging runs, and enhances detection confidence and reliability.

Furthermore, this orthogonal example may be extended beyond radiogenic isotopes to include other intrinsic properties of the reactive contrast agent that differentiate it from the formation background, such as unique acoustic signatures, electromagnetic responses, nuclear magnetic resonance (NMR) characteristics, physical properties (density or porosity effects), or specific chemical signatures. These orthogonal contrast-agent properties, including radiogenic labeling, may further be strategically varied with respect to depth. For example, specific radiogenic isotopes or isotope combinations may be systematically introduced or withdrawn at defined depth intervals, producing distinct and recognizable depth-dependent patterns. This depth-dependent modulation of contrast-agent properties yields a readily interpretable spatial distribution, further enhancing detection accuracy and simplifying log interpretation.

Therefore, by embedding radiogenic isotopes orthogonally into reactive contrast agents, robust and unambiguous differentiation of the injected contrast agent may be achieved from the natural formation background, significantly enhancing the efficiency, reliability, and interpretive clarity of subsurface fluid-component characterization.

In summary, nuclear logging techniques benefit substantially from the introduction and selective reaction of metal hydride contrast agents through multiple complementary mechanisms. The creation of a dense metallic hydride network inherently enhances nuclear density detection. Strategic operational flushing techniques minimize interference from unreacted precursor slurry. Finally, modification of precursor alloys by incorporating highly neutron-sensitive elements or gamma-ray-emitting isotopes further increases detectability and specificity, significantly improving the reliability of geologic hydrogen identification and characterization through nuclear logging methods.

Porosity-sensitive logging techniques, such as neutron porosity, density porosity, and nuclear magnetic resonance (NMR) logs, may effectively detect the distinctive geometric pattern created by the metal hydride contrast-agent reaction. As the hydride precursors chemically bind hydrogen gas and form an interconnected metallic hydride network within the pore structure, local porosity and permeability are significantly reduced. This newly formed, dense interlocking framework substantially alters the pore space geometry, decreasing available fluid-filled void space and thus distinctly lowering the measured porosity in a well-defined cylindrical or oblong-shaped region surrounding the borehole. Consequently, porosity logs clearly delineate this reaction zone as a region of significantly reduced porosity relative to adjacent unaffected formation zones, offering an additional robust petrophysical indicator of molecular hydrogen accumulations.

The permeability and porosity characteristics of the interconnected metal hydride network may be precisely controlled and tuned by adjusting various key parameters of the contrast agent design. Specifically, the initial particle size distribution of the precursor materials strongly influences the final geometry, pore-throat sizes, and connectivity within the hydride network. Using extremely fine (nano-scale) precursor particles tends to produce a densely packed hydride matrix with minimal residual porosity and significantly reduced permeability, whereas coarser particles (micro-scale) yield comparatively larger pore-throat sizes, resulting in a more permeable and less tightly-packed network structure, or using a combination of size distribution to produce an ultra-dense network.

Additionally, the chemical composition and intrinsic nature of the hydride-forming materials themselves may be tailored to further modulate network properties. Selecting alloys or intermetallic compounds that expand significantly upon hydrogenation results in a more pronounced reduction in porosity and permeability due to increased volumetric swelling and tighter interlocking. Conversely, hydride precursors exhibiting minimal expansion upon hydrogen uptake would maintain relatively greater residual permeability within the reaction zone, permitting controlled fluid flow through the network.

Introducing non-hydride-forming particles or inert additives into the precursor slurry provides yet another effective strategy for finely adjusting permeability and porosity. By blending reactive hydride-forming particles with inert or passive particles possessing distinct particle-size distributions, it is possible to engineer controlled porosity pathways and defined permeability characteristics within the precipitated hydride network. For instance, introducing larger-sized inert particles creates interstitial void spaces and interconnected flow pathways, maintaining controlled levels of porosity and permeability within the reacted region. Such adjustments allow customized hydride network characteristics, ranging from nearly impermeable, densely interlocked matrices ideal for clearly marking reaction zones, to partially permeable hydride networks designed to preserve moderate fluid mobility. This example provides considerable flexibility for optimizing contrast-agent performance to suit specific reservoir conditions, logging sensitivities, and subsequent operational objectives.

Discussed below are different measurement operations and how they benefit and may be applied in Multiphysics co-inversion example. Any number of different measurement techniques discussed below as well as the applications of their techniques may be applied to any other techniques comprising contrast-agent-based methodologies or any other methodology to acquire additional information, especially pertaining to locating geologic hydrogen in a subterranean formation. In examples, integrating these complementary logging measurements, electromagnetic (including conductivity and magnetic susceptibility), acoustic, NMR, and nuclear porosity logging, reactive contrast-agent-based methodologies become significantly enhanced.

Conventional open-hole acoustic logging equipment, commonly used to measure formation compressional (P-wave) and shear (S-wave) velocities, may readily detect this near-wellbore acoustic alteration. The hydride network generates distinct acoustic reflections and altered travel-time signatures due to its high rigidity, density, and reduced porosity, thus clearly delineating the reacted formation zone around the borehole. Acoustic velocity profiles derived from conventional sonic logs will exhibit pronounced increases in velocity within the hydride reaction zone, accompanied by observable reflections at the boundary between reacted and unreacted reservoir intervals. Additionally, acoustic tools configured in a pitch-catch arrangement along the wellbore could also detect this cylindrical or oblong hydride zone, revealing characteristic wave patterns indicative of the unique near-wellbore acoustic heterogeneity created by the hydride deposition.

Furthermore, specialized acoustic logging tools originally intended for cement bond evaluation (acoustic cement bond logging tools, distinct from ultrasonic pulse-echo methods) may be particularly effective in identifying and quantifying the hydride network presence. Cement bond loggers typically measure radial acoustic signals transmitted along and behind casing or in the near-wellbore annulus. Due to their sensitivity to radial acoustic impedance contrasts, these tools are uniquely well-suited to detect the robust cylindrical “ring” or zone of interconnected hydride material formed around the borehole. In this scenario, the hydride network behaves analogously to a solid annular region or a cement-like structure, producing clear and readily identifiable acoustic signatures. Therefore, acoustic cement bond logging equipment may effectively exploit these radial impedance contrasts, offering a valuable and perhaps uniquely effective method for detecting and characterizing hydride frameworks and the associated presence of molecular hydrogen accumulations in subsurface reservoirs. In this fashion, the geometry of the hydride networks may be analyzed and further used to characterize unique properties of the underlying formation's permeability and porosity that led to the distribution of the hydride networks in the first place. Although acoustic logging described herein is uniquely suited to discover the nature of the geometry of the precipitated hydrides, other logging techniques may be used to augment or provide independent measurement. For instance, azimuthal eddy current logging may be used to discover the conductive locations around the wellbore, and nuclear may be used to determine precise localities albeit more near wellbore, which may be taken as a corrective interpretation or a co-invasions.

The application of metal hydride contrast agents to create distinctive, measurable alterations in subsurface formations significantly enhances the detection and characterization of molecular hydrogen accumulations. However, optimal interpretation and robust confirmation of these formations benefit greatly from a corroborative example, integrating multiple complementary logging techniques. Specifically, electromagnetic (EM), nuclear (density and neutron-based), nuclear magnetic resonance (NMR), porosity, and acoustic logs collectively deliver independent but complementary measurements. These independent observations, each sensitive to different physical properties and uniquely altered by the metal hydride contrast agent, may be combined to provide mutually reinforcing confirmation of molecular hydrogen presence, distribution, and concentration.

Leveraging these diverse logging datasets, a multiphysics co-inversion example further enhances interpretational accuracy and reliability. Multiphysics co-inversion refers to simultaneously and jointly interpreting multiple types of log data, each sensitive to different formation properties, such as electrical conductivity, dielectric permittivity, nuclear density, neutron capture cross-section, acoustic velocity, acoustic impedance, porosity, and pore-size distribution, to achieve a coherent, physically consistent reservoir model. Such joint inversions substantially reduce the ambiguity inherent in single-method interpretations, thereby providing a robust and reliable identification of the reacted hydride zone and associated molecular hydrogen accumulations. Corroborative analysis of acoustic impedance boundaries, EM resistivity contrasts, nuclear density variations, distinct NMR relaxation time signatures, and porosity reductions converge to yield precise reservoir characterization.

Practically, this multiphysics integration may be achieved using standard inversion methodologies, such as iterative forward modeling and constrained nonlinear inversions, or through advanced proxy modeling and machine learning techniques. Proxy models (surrogate modeling methods) effectively approximate complex physical responses of formations to metal hydride precipitation without extensive computational overhead. Machine learning algorithms, such as supervised learning methods (e.g., artificial neural networks, support vector machines, random forests) and unsupervised learning (e.g., clustering algorithms), can rapidly assimilate, analyze, and integrate diverse logging datasets, identifying characteristic multidimensional patterns uniquely indicative of the hydride-formed zones. These computational tools thus significantly streamline the multiphysics interpretation workflow, providing reliable, real-time or near-real-time detection and quantification of molecular hydrogen accumulations within geological reservoirs.

Ultimately, combining corroborative interpretation across multiple logging modalities with advanced multiphysics co-inversion methodologies offers the most robust and reliable example for subsurface hydrogen detection. Such integrated examples maximize interpretational confidence, reduce uncertainty, and facilitate the accurate identification and evaluation of geologic hydrogen reservoirs.

Accurate detection and quantification of molecular diatomic hydrogen (H₂) within subsurface reservoirs may implement rigorous log characterization and calibration procedures, particularly due to the complexity introduced by interfering gas species and reservoir conditions. To achieve this, logging responses may be carefully calibrated against known concentrations of hydrogen and common interferent gases such as nitrogen (N₂), carbon dioxide (CO₂), methane (CH₄), helium (He), and other potential interfering components, within gas or water legs of representative subterranean reservoirs. Such calibration is ideally performed by directly acquiring formation fluid samples through formation testing tools, enabling subsequent laboratory analysis and providing robust field-specific calibration data. This example allows logs to be precisely calibrated for particular fields, and even facilitates broader, global calibration across analogous reservoir types, significantly enhancing interpretive accuracy.

However, given the limited number of naturally occurring reservoirs containing confirmed accumulations of molecular hydrogen, an alternative and proactive characterization strategy involves deliberate injection of controlled hydrogen-rich fluid compositions into representative reservoir formations. Injection of hydrogen may be effectively accomplished using coiled tubing, drill-stem tests (conducted in reverse), or formation-testing equipment operated in injection mode. Through this methodology, reservoirs may be precisely logged both prior to and following hydrogen injection, allowing comprehensive comparative analysis of log responses under controlled conditions. Injection mixtures may deliberately include common interfering gases, thereby enabling accurate deconvolution of logging signals and robust identification of the unique signatures associated specifically with molecular diatomic hydrogen, even in the presence of typical subsurface interferents.

Careful targeting of basins and fields where hydrogen exploration will commence provides further assurance that, if present, geological hydrogen accumulations may be confidently identified based on calibrated log responses. Furthermore, such deliberate characterization and calibration efforts may clarify and pinpoint the most economically efficient combinations of logging tools needed to confidently identify and quantify geological hydrogen deposits. Importantly, calibration and characterization experiments may be performed either in conjunction with the use of selective reactive contrast agents or independently, to determine whether simpler interpretation methods are sufficient or if contrast-agent-enhanced detection significantly improves reliability and accuracy.

In scenarios involving injection into reservoir formations, acoustic logging tools may be effectively utilized to track the position, distribution, and migration patterns of hydrogen following injection. If hydrogen is injected into a predominantly aqueous reservoir environment, controlling injection rates, temperatures, and pressures allows precise management of hydrogen phase behavior, ensuring hydrogen remains fully dissolved in water to maintain single-phase injection. In other examples, hydrogen may be pre-mixed into formation-compatible water at surface conditions, ensuring single-phase fluid injection and minimizing complications arising from multiphase fluid distributions. Additionally, gaseous hydrogen injections into water-bearing reservoirs may be analyzed carefully at gas-water margins, exploiting partial dissolution phenomena to generate calibration points that are representative of real-world subsurface conditions.

To further ensure formation-fluid compatibility and isolate the influence of molecular hydrogen on logging responses, reservoir water containing dissolved hydrogen may be produced, surface-blended with controlled hydrogen concentrations, and re-injected into the reservoir. This method ensures fluid compatibility while clearly distinguishing log response changes attributable solely to molecular diatomic hydrogen presence. These deliberate and controlled calibration and characterization tests significantly enhance log interpretation reliability and allow operators to confidently apply derived calibrations not only locally but also as global proxies for geologically analogous formations worldwide.

The formation of an interconnected metal hydride network significantly influences the formation's fluid mobility, creating a clearly measurable alteration that may be detected through formation testing procedures such as pre-tests and mini drill-stem tests (mini-DST). The precipitated hydride material, occupying pore spaces and interconnecting to form a rigid metallic matrix, results in a substantial reduction in local permeability and fluid mobility around the wellbore. This reduced permeability zone may be readily identified through standard formation-tester mobility measurements. Pre-test mobility values measured after hydride precipitation will show markedly lower mobility compared to initial or baseline measurements, providing a robust diagnostic indicator of the presence of a hydride network.

Furthermore, the distinct permeability reduction introduced by the hydride network may be intentionally designed to have a specific, engineered mechanical strength or pressure threshold. Thus, during formation testing operations, deliberate pump-down or pressurization of the formation tester probe may initially indicate very low mobility or permeability until a specific, predefined “breakthrough” pressure is reached. At this engineered threshold, the structural integrity of the precipitated hydride network is compromised or fractured, causing an immediate and measurable increase in permeability. This distinct event, a clearly detectable pressure response coupled with a sudden rise in measured fluid mobility, provides additional, highly diagnostic evidence of the hydride network's presence and mechanical characteristics.

Moreover, formation testing systems offer the additional capability to directly probe and verify the presence of a hydride framework through controlled acid-wash treatments. By first performing baseline permeability tests (pre-tests or mini-DSTs), followed by localized introduction of mild acid solutions through the formation tester, operators may intentionally dissolve and remove the metallic hydride network around the probe zone. Subsequent repeat permeability measurements post-acid wash would reveal a clear and significant permeability recovery or increase, further verifying the original presence of the hydride precipitate. This controlled operational sequence, initial testing, targeted acid dissolution, and repeat permeability testing, provides an unequivocal, field-verifiable method to confirm and quantify the formation of the metal hydride framework and associated molecular hydrogen accumulation.

Formation testing tools commonly incorporate internal sensors designed to measure detailed properties of reservoir fluids, including optical spectroscopy sensors, density sensors, capacitance sensors, dielectric sensors, resistivity sensors, and ultrasonic acoustic sensors. Although these sensors are highly sensitive, they do not inherently discriminate molecular hydrogen (H₂) from other gases or fluids such as methane, carbon dioxide, nitrogen, or water. However, by strategically introducing selective hydrogen-reactive contrast agents, specifically metal hydride precursors or hydrogen-sensitive nitrile and imine compounds, directly within the internal sensor modules, it becomes possible to enable these sensors to detect and quantify molecular hydrogen specifically and reliably.

For example, optical spectroscopy sensors, which typically measure absorption or scattering properties of fluids, could integrate metal hydride precursors or nitrile/imine compounds that undergo distinct colorimetric, spectroscopic, or scattering property changes upon hydrogen absorption. Also, the hydrolysis of contrast compounds changes the spectroscopic signature of compound. The contrast agents may be bound in an immobile matric for probing by sensor optical or not. Such matrices may include polymer matrices ceramic matrices including but not limited to zeolites or hydrogels. The presence of molecular hydrogen would thus yield immediate and highly specific optical responses, clearly differentiating hydrogen-rich fluids from other gases or liquids. Similarly, fluid-density sensors within the formation tester could detect hydrogen-specific interactions through density changes triggered by selective precipitation or volumetric expansion of the metal hydride contrast agent upon hydrogen reaction.

In addition, in examples provided herein, Accurate sampling and quantification of molecular hydrogen (H₂) in formation testing may be significantly improved by modifying traditional sampling tool designs and methodologies. One beneficial modification includes applying specialized coatings to the metallic surfaces of titanium-based formation testing equipment to minimize or eliminate the absorption and adsorption of hydrogen. Such coatings may be thin films deposited via chemical vapor deposition (CVD), physical vapor deposition (PVD), or electrolysis. Exemplary coating materials suitable for this application include, but are not limited to, silicon (Si), silicon oxide (SiO₂), and aluminum oxide (Al₂O₃). These coatings effectively create a diffusion barrier and significantly reduce hydrogen uptake by the underlying metal surfaces. Additionally, the coatings may modify the surface affinity characteristics, rendering the tool surface hydrophilic, which inherently repels molecular hydrogen and further reduces surface adsorption and subsequent absorption into the tool material.

Another beneficial modification involves minimizing or entirely eliminating the use of elastomer-based sealing materials within the formation tester tool, replacing them instead with robust metal-to-metal sealing mechanisms. Elastomers commonly employed in downhole sampling tools may interact chemically with molecular hydrogen, resulting in absorption or permeation of hydrogen into these materials. This interaction may alter hydrogen sample integrity and significantly impact analytical accuracy. Metal-to-metal seals effectively eliminate these hydrogen-reactive surfaces, preserving the original composition and integrity of the hydrogen sample collected from the reservoir.

Finally, modifying formation testers to enable the capture of very small (micro-volume) fluid samples specifically for hydrogen analysis provides an additional analytical advantage. Unlike petroleum reservoir fluid analyses that typically implement large-volume samples for complex compositional evaluation, molecular hydrogen sampling benefits from smaller-scale fluid capture, which simplifies handling and minimizes contamination risks. These micro-volume samples are sufficient for accurate detection and quantification of molecular hydrogen via analytical techniques such as mass spectroscopy, thus efficiently supporting targeted hydrogen reservoir evaluations without the logistical and analytical complexities associated with larger sample volumes.

Capacitance and dielectric sensors may also benefit from incorporating hydrogen-reactive contrast agents. When metal hydrides form within these sensors, significant changes in dielectric constant or capacitance properties occur due to the altered electrical polarization characteristics of the formed hydride materials. These measurable dielectric property changes provide a robust indication of molecular hydrogen presence. Additionally, resistivity sensors within the formation tester may leverage the significantly increased electrical conductivity introduced by hydride formation, enabling unambiguous identification of molecular hydrogen through rapid resistivity shifts upon interaction.

Finally, ultrasonic, sonic, and/or any frequency of acoustic sensors integrated into formation testing modules offer another powerful avenue for contrast-agent-enabled hydrogen detection. The selective formation of hydrides induces substantial and measurable changes in acoustic velocity, acoustic impedance, and acoustic attenuation. Consequently, the ultrasonic sensors within the formation tester could directly and rapidly detect the presence of molecular hydrogen through characteristic acoustic signal changes resulting from contrast agent reactions.

By modifying formation tester sensors with these selective hydrogen-reactive contrast agents, either as thin coatings, internal layers, bound in permeable but immobile matrices or integrated sensor components, operators gain a powerful and unprecedented capability for direct, immediate, and highly specific molecular hydrogen detection in situ. This example significantly expands the capability of existing formation tester sensor technologies, enabling real-time and robust identification of geologic hydrogen accumulations.

Acoustic logging techniques provide valuable insights into subsurface formations by measuring wave propagation properties such as compressional wave velocity (Vp), shear wave velocity (Vs), acoustic impedance, and attenuation. In formations partially saturated with molecular hydrogen (H₂), acoustic logging measurements will exhibit a distinctive responses due to hydrogen's unique fluid properties. Hydrogen gas, having notably higher acoustic velocity with substantially lower density compared to typical reservoir fluids and other gases (such as methane or carbon dioxide), significantly influences acoustic propagation characteristics. Specifically, compressional wave velocities measured in hydrogen-rich zones typically appear elevated relative to zones saturated with heavier gases. This results in distinctive velocity anomalies that may help differentiate hydrogen-bearing intervals from conventional hydrocarbon-gas-bearing or water-saturated intervals.

The remarkably low density of hydrogen gas also reduces the bulk density and acoustic impedance of the formation, despite increased acoustic velocities. This combination of increased velocity with markedly reduced density creates clear impedance contrasts detectable through acoustic reflection measurements, facilitating identification of hydrogen-rich zones. Furthermore, hydrogen's extremely low molecular weight and low viscosity may result in reduced acoustic wave attenuation. Consequently, acoustic waves traveling through hydrogen-bearing zones often exhibit clearer signals with lower dispersion and energy loss compared to zones saturated with heavier or more viscous fluids.

Integration of acoustic logging data with other multiphysics logging techniques, such as neutron logging and nuclear magnetic resonance (NMR), further enhances diagnostic capability. Specifically, distinctive acoustic velocity and impedance signatures combined with neutron-derived hydrogen indices and unique NMR relaxation responses create a robust, multi-dimensional characterization example. Thus, acoustic logging provides a valuable complementary method for detecting and accurately delineating naturally occurring hydrogen reservoirs.

Accurate identification and characterization of hydrogen-bearing zones within subsurface formations greatly benefit from integrated multiphysics logging interpretation and inversion techniques. Multiphysics inversion refers to the combined and simultaneous processing and interpretation of datasets acquired from different geophysical logging technologies, each sensitive to distinct physical properties of the formation. For hydrogen exploration, this integration commonly includes acoustic logging, pulsed neutron logging, nuclear magnetic resonance (NMR) logging, surface data logging (SDL), and formation testing, among others. Each of these methods independently provides partial insights, acoustic logging responding sensitively to fluid velocities and densities, neutron logging measuring total hydrogen indices, NMR logging distinguishing fluid types through relaxation times, and formation testing providing direct fluid composition and physical properties.

The application of multiphysics inversion exploits the complementary sensitivities of these diverse logging datasets. By employing advanced inversion algorithms including physics-informed machine learning methods (e.g., Physics-Informed Neural Networks, Fourier Neural Operators, or operator-based neural networks), or traditional computational inversion techniques combined with equation-of-state modeling, comprehensive and physically consistent reservoir models may be rapidly developed. These inversion methodologies incorporate governing physical equations and constraints directly into the processing workflow, significantly reducing uncertainties associated with individual measurements. For example, the distinctive acoustic velocity increase and lowered density observed in acoustic logging of hydrogen-rich zones, when interpreted alongside high total hydrogen indices from neutron logs and distinctive short relaxation signatures from NMR logs, yield robust constraints on hydrogen distribution and saturation.

Moreover, integrating surface logging, pressure and compositional data from formation testing, and acoustic impedance contrasts through multiphysics inversion allows differentiation between hydrogen generated by geological serpentinization, radiogenic processes, or other subsurface reactions. Consequently, multiphysics inversion provides a comprehensive, integrated example, enhancing the reliability and accuracy of hydrogen exploration. This integrated workflow is particularly effective for resolving the inherent complexities and ambiguities that arise from relying on any single measurement type, thereby substantially improving subsurface characterization, reservoir assessment, and exploration decision-making.

### Other Nuclear Logging Petrophysical Technologies:

Nuclear logging encompasses several downhole geophysical techniques that utilize interactions between emitted nuclear radiation and subterranean formations to measure various petrophysical properties. Each nuclear logging method leverages distinct physical interactions to yield quantitative and qualitative information about the reservoir and fluids within pore spaces. Nuclear logging methods each provide distinct, specialized insights into subsurface formations. Their combined application offers a comprehensive framework for accurate reservoir evaluation and fluid characterization.

Neutron porosity logging methods involve emitting high-energy neutrons into the formation from either pulsed neutron generators or continuous neutron sources, such as Americium-Beryllium (Am—Be). The emitted neutrons lose energy through elastic scattering, predominantly with hydrogen nuclei, thus providing measurements highly sensitive to hydrogen concentration. Because hydrogen is abundant in water, hydrocarbons, and gases, neutron logs yield porosity estimates and fluid-saturation information. By analyzing the neutron-induced gamma-ray emission or neutron capture rates, these logs may also differentiate between gas-bearing and liquid-bearing intervals, enabling the identification of gas zones, including potentially hydrogen-rich intervals.

Gamma-gamma logging utilizes gamma radiation, commonly sourced from Cesium-137, emitted into the formation. Gamma rays interact with electrons in the formation material through Compton scattering, resulting in scattered gamma radiation detected at various spacing intervals from the source. The measured scattered gamma-ray intensity directly correlates to the electron density of the formation, from which bulk density is derived. The resulting density data is critical for accurately determining formation porosity, lithology variations, and identifying density contrasts indicative of different rock types or fluid-bearing intervals.

Spectral gamma-ray logging measures natural gamma radiation emitted by formations from naturally occurring radioactive isotopes, primarily potassium-40 (K-40), uranium-238 (U-238), and thorium-232 (Th-232). Because these isotopes are often concentrated in shales and specific mineralogy, spectral gamma-ray logging aids significantly in determining clay content, lithological composition, and mineralogical distributions. Additionally, these logs help delineate stratigraphic units and are frequently employed in correlation and reservoir-quality evaluations.

Neurton Capture (Sigma) logging may utilize pulsed neutron or chemical source capture logging measures the rate at which thermal neutrons, generated from pulsed neutron sources, are captured by elements within the formation. Each element captures neutrons at different characteristic rates (capture cross-section, or sigma), producing distinct gamma-ray emissions. By measuring neutron capture rates and gamma-ray signatures, pulsed neutron capture logs effectively differentiate fluid types, specifically distinguishing between hydrocarbons and formation water. This technique is particularly useful in cased-hole logging scenarios, reservoir depletion monitoring, and enhanced oil recovery assessments.

Carbon to Oxygen pulsed neutron spectroscopy logs emit high-energy neutrons into the formation, causing elements to emit gamma rays at unique energies indicative of their atomic composition. By analyzing the energy spectra of these induced gamma rays, carbon-to-oxygen ratios (C/O ratios) may be accurately determined. Since hydrocarbons contain carbon and formation water is predominantly composed of oxygen and hydrogen, C/O ratios reliably indicate hydrocarbon saturation within the formation, facilitating reservoir characterization in both open and cased-hole scenarios.

Neutron-gamma activation logging, or neutron activation logging, relies on neutron-induced gamma-ray emission after activation of specific elements within the formation. Different elements emit gamma radiation at unique energies upon neutron activation. By measuring these characteristic emissions, this method identifies and quantifies elemental concentrations, including chlorine (useful for assessing salinity), sulfur (indicative of hydrocarbons), and other elements critical for comprehensive elemental analysis and mineralogical assessment.

Although not generally considered nuclear logging, NMR logging employs magnetic fields and radio-frequency pulses to polarize hydrogen nuclei within formation fluids, subsequently measuring the rate at which these nuclei relax to their equilibrium state. The relaxation times (T₁ and T₂) vary significantly based on fluid type, viscosity, and pore-size distribution. As a result, NMR logging accurately quantifies total porosity, distinguishes fluid types (oil, gas, water), assesses permeability, estimates hydrocarbon viscosity, and characterizes the pore-size distribution and fluid mobility within reservoir intervals. Utilizing pore size distribution or other direct signal inversion methods, fluid mobility and or rock permeability may be calculated which in combination with other petrophysical analysis described herein, may be used to constrain inversion of the presence of molecular hydrogen.

Multiphysics inversion techniques that combine Nuclear Magnetic Resonance (NMR), pulsed neutron hydrogen index measurements, and porosity-permeability analyses benefit significantly from integrating petrophysical parameters obtained through nuclear logging methods. Each parameter provides unique and complementary constraints that improve the accuracy and reliability of interpreting subsurface molecular hydrogen (H₂) distributions.

Neutron porosity measurements reflect the total hydrogen content in formation pore spaces, independent of fluid type. High neutron-derived hydrogen indices indicate elevated hydrogen content but cannot directly differentiate molecular hydrogen from hydrocarbons or water. When used in multiphysics inversion, neutron porosity acts as a baseline constraint, defining zones of elevated hydrogen saturation. Combined with NMR or acoustic velocity data, discrepancies between expected fluid properties (such as densities and relaxation characteristics) and the total neutron hydrogen index may indicate residual hydrogen content attributable specifically to molecular hydrogen rather than hydrocarbons or formation water.

Bulk density derived from gamma-gamma logging provides precise measurements of formation density, which, when integrated with neutron porosity data, helps discriminate fluid-filled porosity from gas-saturated porosity. Since molecular hydrogen has an exceptionally low density compared to other formation fluids, regions with anomalously low bulk density combined with elevated neutron-derived hydrogen indices strongly constrain inversions toward identifying hydrogen-rich gas zones rather than denser hydrocarbon or brine-saturated intervals.

Natural gamma-ray data provide robust constraints on formation lithology, shale content, and mineralogical composition. Accurate lithological identification from spectral gamma-ray measurements helps refine porosity and permeability models, essential for correctly interpreting fluid distributions. Constraining lithology helps isolate genuine petrophysical anomalies caused by hydrogen-bearing fluids rather than lithological variability or mineralogical heterogeneity.

Sigma logging provides insights into the fluid saturation state through neutron-capture cross-section differences among various fluids, while carbon-oxygen (C/O) spectroscopy logs distinctly differentiate hydrocarbons from water. By clearly identifying water and hydrocarbon presence or absence, these methods indirectly constrain the residual hydrogen signals measured by neutron porosity and NMR logs, thus isolating intervals where hydrogen saturation cannot be explained by conventional hydrocarbon or aqueous fluids, thereby signaling molecular hydrogen.

Elemental concentrations, such as chlorine or sulfur obtained from activation logging, constrain fluid salinity, mineralogy, and presence of hydrocarbon-associated elements. Such elemental distributions may delineate hydrocarbon-bearing versus non-hydrocarbon-bearing zones, indirectly supporting identification of anomalous hydrogen presence that cannot be attributed to typical reservoir fluids.

NMR logging directly measures fluid relaxation characteristics, providing crucial constraints on fluid type and viscosity. Molecular hydrogen exhibits uniquely rapid relaxation times distinct from hydrocarbons, facilitating direct fluid-typing constraints. NMR-derived permeability and pore-size distribution also offer robust parameters for constraining fluid mobility and rock permeability. Accurate permeability characterization enables detailed modeling of hydrogen migration pathways and reservoir fluid mobility, further refining multiphysics inversion results.

Integrating porosity from neutron-density cross-plot analysis with permeability from NMR-derived pore-size distributions provides additional constraints for fluid mobility and storage capacity. Zones with high porosity and significant permeability, yet showing anomalous fluid responses such as low-density gas signatures or rapid NMR relaxation signals, become prime candidates for molecular hydrogen reservoirs. These combined constraints enable precise spatial localization and volumetric quantification of hydrogen-rich intervals.

Collectively, integrating these petrophysical parameters obtained from nuclear logging methods as constraints within a multiphysics inversion framework substantially improves the ability to identify, characterize, and quantify molecular hydrogen occurrences in subsurface formations. Such integration reduces ambiguity inherent in individual measurements, allowing clear differentiation between molecular hydrogen and conventional formation fluids, and supports accurate, reliable exploration and reservoir evaluation decisions.

Integration with Geological and Geochemical Contexts: Accurate identification and characterization of naturally occurring molecular hydrogen (H₂) reservoirs through multiphysics logging are significantly strengthened when integrated with comprehensive geological and geochemical contexts. Geological and geochemical factors play critical roles in controlling the distribution, accumulation, mobility, and longevity of hydrogen within subsurface formations. By explicitly incorporating geological frameworks and geochemical processes into multiphysics interpretations, reservoir evaluations become substantially more robust, predictive, and reliable.

The geological context of hydrogen accumulation involves specific conditions and structural elements that facilitate hydrogen generation, migration, trapping, and preservation. Key geological considerations include rock types, fault and fracture networks, structural traps, and stratigraphic barriers. For example, hydrogen generation commonly occurs through serpentinization reactions where ultramafic igneous rocks interact with water under suitable temperature and pressure conditions, producing distinctive hydrogen-rich fluid signatures. Similarly, radiogenic hydrogen may be produced from radioactive decay reactions within basement rocks or adjacent lithologies rich in radioactive elements. Clearly identifying these geological contexts through seismic surveys, structural mapping, and correlation with regional geology provides critical prior knowledge to guide logging operations and interpretive strategies.

Fault and fracture networks particularly influence hydrogen mobility and accumulation. Hydrogen, having exceptionally low molecular weight and viscosity, migrates rapidly through connected fracture systems or permeable fault zones. High-quality acoustic logging, density-neutron cross plots, and NMR-derived permeability and pore-size distributions combined with structural mapping help delineate these migration pathways, identifying preferential fluid-flow corridors and potential reservoir compartments. Identifying structural traps or stratigraphic sealing units (such as shale or evaporite layers) is crucial, as these barriers enable the retention and concentration of migrating hydrogen. Lithology-sensitive logs, such as gamma-ray spectroscopy and density logging, provide direct constraints for assessing seal integrity and effectiveness, essential for accurately predicting long-term hydrogen storage potential within subsurface reservoirs.

Integrating geochemical analyses significantly enhances multiphysics interpretations, especially regarding hydrogen source attribution, reaction histories, and subsurface geochemical interactions. Isotopic signatures of hydrogen (e.g., β²H) or related elements (such as carbon or sulfur isotopes in associated minerals or fluids) yield critical diagnostic information that distinguishes between geological, radiogenic, microbial, and anthropogenic hydrogen origins. For instance, hydrogen formed via serpentinization typically exhibits distinctive isotopic ratios clearly differentiated from radiogenic hydrogen produced by radioactive decay or microbial hydrogen associated with biogenic processes.

Geochemical characterization of minerals and formation fluids through elemental logging techniques (e.g., neutron activation logging), combined with surface-derived isotopic analyses from sampled gases, enables comprehensive reservoir fluid geochemical fingerprinting. Evaluating elemental compositions, such as high concentrations of iron or magnesium in ultramafic rocks associated with serpentinization processes, may further constrain hydrogen generation models. Additionally, tracking chemical interactions such as mineral-hydrogen reactions or microbial metabolic processes provides insights into subsurface hydrogen dynamics, reservoir recharge mechanisms, and potential chemical or biological sinks influencing hydrogen concentration and preservation.

Understanding geochemical interactions between hydrogen and reservoir rocks and fluids is critical for predicting reservoir performance and fluid compositional evolution over time. Molecular hydrogen may interact chemically with mineral surfaces, altering reservoir permeability and storage properties. For example, prolonged hydrogen exposure may result in mineralogical alterations or induce redox reactions that modify porosity, permeability, and rock mechanical stability. Nuclear logging methods sensitive to mineralogy and elemental distributions, such as gamma spectroscopy or neutron-induced gamma activation logging, help identify regions of geochemical alteration, thereby refining predictive reservoir modeling.

Furthermore, microbial activity in subsurface formations represents another critical geochemical context. Microorganisms in reservoirs may either consume hydrogen (e.g., methanogenesis) or generate hydrogen (e.g., fermentation reactions), significantly affecting net hydrogen accumulation. Combining logging data with direct fluid sampling and geochemical analyses (including isotopic characterization and microbial DNA analyses) effectively distinguishes abiotic from biogenic hydrogen sources, allowing accurate prediction of hydrogen stability and long-term reservoir viability.

Integration of geological and geochemical contexts into logging programs informs the optimal selection and operational configuration of logging tools and techniques. Pre-drilling geological evaluations (seismic surveys, surface geological mapping, basin history analyses) inform the deployment strategy for neutron, acoustic, and NMR logging to target expected hydrogen-bearing intervals, migration pathways, and structural traps. Concurrently, surface geochemical analyses of drilling mud returns or gas samples inform real-time operational decisions, enhancing data reliability and immediate interpretive capability.

Explicitly integrating geological and geochemical contexts significantly enhances the interpretative accuracy and reliability of multiphysics logging techniques used for identifying and characterizing subsurface hydrogen reservoirs. Geological structural understanding provides essential frameworks for predicting hydrogen migration and accumulation patterns, while geochemical analyses clarify fluid origins, reaction pathways, and reservoir dynamics. Such comprehensive integration fosters robust reservoir modeling, reduces interpretive uncertainties, and strengthens decision-making in hydrogen exploration and resource development.

### Long-Term Reservoir Behavior: Hydrogen Mobility and Reservoir Dynamics:

The long-term viability and performance of subsurface hydrogen reservoirs depend significantly on the intrinsic mobility and dynamic behavior of molecular hydrogen (H₂) within geological formations. Hydrogen exhibits notably high diffusivity, significantly greater than methane, carbon dioxide, or other typical subsurface fluids. This distinctive property directly influences reservoir dynamics, fluid migration patterns, containment integrity, and long-term reservoir management strategies. Understanding hydrogen mobility and its implications for reservoir containment is therefore crucial and may be effectively assessed through integrated multiphysics logging datasets.

Hydrogen's exceptionally high diffusivity arises primarily from its extremely small molecular size, low molecular weight, and relatively weak intermolecular interactions. In porous and fractured reservoir rocks, hydrogen tends to diffuse rapidly through the pore spaces, micro-fractures, and any connected flow paths. This enhanced mobility means that even subtle variations in rock permeability, porosity, or fracture connectivity strongly influence hydrogen migration. Consequently, hydrogen reservoirs may exhibit unique temporal behaviors, such as rapid pressure equilibration, fluid redistribution, or gradual diffusion-driven migration into adjacent reservoir compartments or sealing units over extended timescales.

Due to these rapid diffusional processes, effective identification and characterization of hydrogen-bearing intervals implement precise measurements of fluid mobility and rock permeability. Nuclear Magnetic Resonance (NMR) logging techniques provide detailed pore-size distributions, permeability estimates, and direct quantification of fluid mobility, which are crucial for understanding hydrogen flow behavior. Additionally, acoustic logging data provide complementary information on formation porosity, density, stiffness, and fracture distribution, parameters critical to accurately modeling hydrogen diffusivity and reservoir-scale mobility patterns.

Long-term hydrogen reservoir viability critically depends on the effectiveness of cap rocks or stratigraphic seals that limit vertical and lateral hydrogen migration. Cap rocks typically comprise low-permeability lithologies, such as shales, mudstones, salt layers (evaporites), or tight carbonates, which effectively trap fluids due to their reduced permeability and fine-grained pore structures. Assessing cap rock integrity for hydrogen containment implements accurate evaluation of sealing capacity, mechanical stability, fracture presence, and geochemical compatibility with hydrogen.

Integrated multiphysics logging datasets provide robust capabilities for detailed cap rock characterization. Gamma-ray logging and spectral gamma-ray logging clearly delineate shale-rich intervals or evaporitic sealing layers, while gamma-gamma density and neutron-density cross plots quantify porosity, rock density, and pore structure, essential parameters in seal evaluation. Pulsed neutron capture (Sigma) logging or elemental spectroscopy further helps assess seal lithological composition and continuity, reinforcing predictions of effective hydrogen containment.

Additionally, acoustic logging offers detailed information regarding rock mechanical properties and fracture detection within cap rocks. Variations in acoustic impedance, shear-wave velocities, and attenuation properties may effectively identify micro-fractures, faults, or discontinuities that may compromise seal integrity. NMR logging may further aid in cap rock assessment by quantifying microporosity and immobile fluid content within the seal, indicating low-permeability conditions ideal for sustained hydrogen containment.

Given hydrogen's high diffusivity and tendency for rapid migration, understanding potential reservoir leakage paths is paramount. Multiphysics logging datasets, complemented by formation testing and downhole sampling, facilitate detailed leakage risk evaluations. Pulsed neutron hydrogen index measurements may detect hydrogen saturations in reservoir-adjacent formations or cap rocks, indicating potential leakage or diffusion pathways. Acoustic logging, combined with image logs, identifies fracture networks and faults capable of channeling hydrogen out of the intended reservoir zone.

Reservoir leakage risk assessment also involves careful analysis of pressure gradients and reservoir fluid equilibria derived from formation testing data via formation testing. Anomalous pressures, density contrasts, or compositional variations between reservoir intervals and adjacent units detected via multiphysics logging and formation testing indicate potential hydrogen diffusion or leakage pathways. These signals prompt focused geochemical sampling and isotopic analyses to confirm leakage scenarios and identify specific hydrogen sources and migration pathways. Formation testing may also provide rock fracture and closure parameters for cap rock integrity during drilling completion or production operations.

Over longer timescales, hydrogen reservoirs may undergo notable dynamic changes due to diffusion-driven redistribution, geochemical reactions, microbial activity, or mechanical alterations within reservoir rocks. Multiphysics logging conducted periodically throughout the reservoir's lifecycle provides critical baseline and time-lapse datasets, capturing evolving reservoir conditions and fluid distributions. Changes in hydrogen index from pulsed neutron logging, acoustic impedance contrasts from acoustic logging, or fluid mobility alterations from NMR logging serve as sensitive indicators of reservoir fluid redistribution or loss.

Geochemical interactions, such as hydrogen-mineral reactions or microbial hydrogen consumption, may also induce temporal reservoir changes. Elemental logging methods, isotopic analyses, and periodic downhole fluid sampling may detect geochemical alterations or microbial processes influencing reservoir fluid stability and hydrogen longevity. Accurate quantification of these dynamic interactions enables predictive modeling of reservoir behavior, significantly improving reservoir management strategies and extraction planning.

Integrating hydrogen mobility, containment evaluations, leakage risk assessments, and dynamic reservoir behavior into a comprehensive reservoir management strategy ensures long-term sustainability and operational reliability. Detailed multiphysics characterization of reservoir intervals and cap rock integrity, informed by ongoing geological and geochemical monitoring, supports optimized reservoir development, minimizes operational risks, and informs corrective or adaptive management decisions when reservoir changes are detected.

In summary, explicitly addressing hydrogen mobility, reservoir containment, leakage risk assessments, and reservoir dynamics through integrated multiphysics logging significantly enhances long-term reservoir evaluations and management. Detailed cap rock analyses and periodic reservoir monitoring reinforce predictive capabilities, mitigate operational risks, and support sustainable hydrogen reservoir development and utilization.

Data Quality Control, Measurement Uncertainty, and Logging Tool Calibration and Verification:

The successful identification, quantification, and characterization of molecular hydrogen (H₂) within subsurface reservoirs relies heavily upon high-quality logging data with well-understood uncertainties. Rigorous data quality control, robust uncertainty quantification, and meticulous logging tool calibration and verification protocols are therefore essential for ensuring accurate reservoir assessments and reliable interpretations derived from multiphysics logging methods, including neutron logging, nuclear magnetic resonance (NMR), and acoustic logging.

Each logging method employed for hydrogen characterization, neutron, acoustic, and NMR logging, possesses inherent sources of measurement uncertainty and systematic error, which must be explicitly acknowledged, quantified, and managed. For neutron logging methods, significant sources of uncertainty include statistical variations in neutron counts, background radiation fluctuations, borehole environmental effects (such as variations in borehole size, casing presence, or borehole fluid composition), and uncertainties in neutron transport modeling assumptions. Neutron logging results, such as hydrogen index measurements and neutron-induced gamma-ray spectroscopy data, are particularly sensitive to borehole geometry, tool standoff, and mud cake properties, thus necessitating careful statistical and environmental corrections.

Similarly, acoustic logging uncertainties primarily arise from variations in borehole geometry, tool centralization, fluid coupling efficiency, and formation heterogeneities. Acoustic wave velocity measurements may be influenced by borehole fluid density, fluid composition changes, mud invasion, and variations in rock anisotropy, each introducing potential systematic errors. Additional uncertainty may stem from attenuation measurements and signal dispersion, particularly in fractured or gas-bearing formations, necessitating specialized correction algorithms and detailed statistical modeling.

For NMR logging, primary uncertainty sources include signal-to-noise ratios, temperature- and pressure-dependent relaxation behaviors, tool calibration drift, and borehole fluid contamination. Since molecular hydrogen exhibits distinctively rapid NMR relaxation times, accurately capturing these transient signals introduces additional measurement challenges. Uncertainties related to tool sensitivity, echo-spacing optimization, and pulse-sequence selection must be thoroughly evaluated and incorporated into data processing workflows.

To address these uncertainties comprehensively, advanced uncertainty quantification methods, such as Monte Carlo simulations, statistical error propagation modeling, and Bayesian inference examples particularly effective. Monte Carlo methods explicitly model neutron and gamma-ray transport scenarios or acoustic wave propagation across a wide range of possible conditions, allowing robust statistical quantification of measurement uncertainties under realistic reservoir environments. Bayesian uncertainty analysis combines prior geological or petrophysical knowledge with observed logging data to rigorously quantify confidence intervals and probabilistic predictions for hydrogen presence and reservoir properties. Implementing these sophisticated statistical and computational frameworks significantly enhances the rigor, transparency, and interpretive reliability of multiphysics logging analyses.

Accurate hydrogen reservoir characterization further demands meticulous logging tool calibration and verification protocols specifically tailored to detect molecular hydrogen reliably. Effective calibration ensures measurement consistency, reliability, and comparability across logging runs, wellbores, and reservoir intervals. Calibration procedures for neutron logging tools, acoustic logging systems, and NMR logging devices must explicitly include conditions representative of hydrogen-rich reservoir scenarios.

For neutron logging tools, calibration commonly utilizes laboratory standards and test formations that replicate known hydrogen indices or known elemental compositions closely resembling expected subsurface conditions. Calibration fluids, gases, or fluid-saturated rock standards specifically formulated to represent molecular hydrogen-bearing intervals (such as hydrogen-saturated laboratory samples or synthetic formations) provide robust baseline references. Calibration tests employing these standards should occur periodically, both prior to and immediately following critical logging operations, ensuring the integrity and accuracy of hydrogen index measurements and neutron-derived compositional interpretations.

Acoustic logging tool calibration similarly involves employing controlled laboratory conditions, calibration standards, and well-characterized test formations. Laboratory acoustic standards, materials with precisely known acoustic velocities, impedances, and attenuation characteristics, enable rigorous verification of acoustic logging measurements. Specifically designed acoustic calibration tanks or test wells containing gas mixtures with known hydrogen concentrations and pressures may be employed to verify acoustic response accuracy under hydrogen-rich conditions. Ensuring acoustic tool centralization and repeatability, validating waveform quality, and rigorously assessing tool response against controlled standards significantly improve measurement accuracy and reliability.

NMR logging tool calibration must specifically target transient and short relaxation characteristics typical of molecular hydrogen. Precise calibration involves laboratory reference samples of known hydrogen composition, relaxation times, and hydrogen saturation, thus enabling optimization of NMR pulse sequences (such as Carr-Purcell-Meiboom-Gill, or CPMG) for capturing rapid hydrogen relaxation signals. Periodic laboratory recalibration of NMR tool sensitivity, pulse-sequence timing, echo-spacing configurations, and temperature- and pressure-dependent relaxation adjustments further ensure high-quality NMR measurements tailored explicitly for molecular hydrogen detection.

Complementary to calibration protocols, rigorous verification procedures, including periodic downhole fluid sampling, laboratory isotopic analyses, and cross-validation against independent logging measurements, confirm tool calibration and measurement reliability under actual field conditions. Downhole formation testers and fluid-sampling tools designed to prevent hydrogen contamination or reaction (such as specialized coatings or metal-to-metal seals) provide reliable reference samples for laboratory mass spectrometry, isotopic characterization, or compositional analyses. Comparing these laboratory-derived hydrogen concentrations and isotopic signatures against logging-derived hydrogen indices, NMR relaxation signatures, and acoustic responses provides critical validation of logging accuracy and confirms calibration effectiveness.

Ongoing field verification protocols also encompass periodic repeat logging runs to evaluate measurement repeatability, statistical data quality control procedures to detect systematic anomalies, and adaptive calibration adjustments based on observed deviations or uncertainties. Comprehensive data quality control workflows involving immediate review of raw data, noise-level analysis, tool performance checks, and environmental corrections further enhance data accuracy and interpretative confidence.

Explicitly addressing data quality control, uncertainty quantification, and meticulous logging tool calibration and verification procedures significantly improves the reliability and interpretative accuracy of multiphysics logging datasets used for molecular hydrogen reservoir characterization. Well-documented calibration protocols, robust statistical uncertainty analyses, and ongoing field verification programs provide essential quality assurance and quality control mechanisms, thereby strengthening reservoir assessment decisions, reducing operational risks, and ensuring accurate long-term hydrogen reservoir management.

In summary, comprehensive attention to data quality, measurement uncertainty, and logging tool calibration and verification, integrating advanced statistical modeling, laboratory-based calibration standards, and rigorous field verification procedures, constitutes an essential foundation for accurate, reliable, and defensible multiphysics logging interpretations in hydrogen exploration and reservoir characterization efforts.

Formation-testing tools offer versatile opportunities for inferring and quantifying the presence of molecular hydrogen (H₂) within reservoir fluids, utilizing direct downhole measurements of fluid properties combined with advanced fluid analysis. In certain examples, downhole phase-behavior measurements, such as accurately determining bubble points or saturation pressures in water-containing fluids, as well as measurements of gas compressibility, density, acoustic velocity, and viscosity at known reservoir temperatures and pressures, may collectively indicate the presence and concentration of molecular hydrogen within mixed fluid systems. Such indirect indications of hydrogen are especially robust when independent measurements of interfering components such as water, methane (CH₄), and carbon dioxide (CO₂) are available through complementary analytical techniques, including optical spectroscopy within the formation tester module.

Furthermore, incorporating downhole Nuclear Magnetic Resonance (NMR) sensors into formation testers significantly enhances the discrimination of molecular hydrogen from other inert gas species like nitrogen (N₂) and helium (He), given the distinctly different NMR relaxation and diffusion characteristics of these gases. Molecular hydrogen exhibits notably different diffusion constants and T2 relaxation behaviors, enabling clear differentiation from helium and nitrogen within mixtures. Consequently, careful characterization and calibration of NMR response to these gases provide direct diagnostic measurements that substantially enhance interpretive accuracy, specifically distinguishing molecular hydrogen from other inert gas species.

In cases where nitrogen is present and other inert gases such as helium are confidently known to be absent from the reservoir environment, the nitrogen concentration may be directly inferred after hydrogen determination, streamlining the interpretive workflow. However, if multiple inert gases, including nitrogen and helium, are potentially present, the application of additional complementary measurements becomes highly beneficial. Combining phase-behavior or density measurements with NMR or acoustic velocity measurements provides multiple independent data points, forming a robust set of equations that may accurately resolve gas mixtures containing multiple inert gas components simultaneously. Thus, comprehensive integration of phase behavior, acoustic, density, viscosity, optical spectroscopy, and NMR logging measurements within formation-testing tools deliver a powerful and flexible analytical framework for precise detection, quantification, and differentiation of molecular hydrogen from commonly encountered subsurface gas mixtures.

An additional sensor that may enhance downhole fluid analysis within formation testing tools is mass spectroscopy. Traditionally, mass spectrometric techniques have not been deployed downhole due to technical challenges associated with maintaining the necessary ultrahigh vacuum conditions implemented for repeated measurements. However, recent advances in chip-based mass spectrometry systems provide promising opportunities to overcome these challenges, enabling practical downhole implementation. Specifically, miniature chip-based mass spectrometer components, carefully tuned to specific elemental or molecular masses, may be pre-packaged within hermetically sealed chambers under ultrahigh vacuum conditions, thus enabling direct downhole analysis even under harsh reservoir conditions.

Such chip-based mass spectrometry sensors may be specifically configured to detect and quantify key subsurface gas species, including atomic hydrogen (H), molecular hydrogen (H₂), helium (He), nitrogen (N₂), carbon dioxide (CO₂), hydrogen sulfide (H₂S), water vapor (H₂O), methane (CH₄) and mercury (Hg). Dedicated microfabricated chips may target single molecular masses or narrow mass ranges corresponding specifically to these gaseous species, thus enabling rapid, precise, and highly selective downhole identification and quantification. Ionization for mass spectrometric detection may be achieved directly on-chip through miniature radioactive ionization sources (e.g., trace alpha emitters or beta emitters) or by vacuum ultraviolet (VUV) radiation, requiring only trace amounts of radiation in well-contained, shielded environments.

A significant practical advantage of chip-based mass spectroscopy for downhole use is the extremely small sample volume implemented, typically ranging from microliters down to nanoliters of gas per analysis. Such minimal sample implements significantly simplify maintaining and preserving the necessary ultrahigh vacuum pressure conditions within static measurement chambers, facilitating repeatable and reliable downhole measurements. Additionally, specialized getters, such as zeolite-based sorbents or chemically active getter materials, can be integrated within the mass spectrometer housing to actively maintain ultrahigh vacuum conditions, further ensuring consistent performance and reliability over multiple downhole measurements.

To further enhance analytical accuracy, gas samples may be pre-processed prior to analysis by employing integrated desiccants to effectively dry the gas, eliminating water-derived hydrogen contamination. Moreover, controlled phase separation of formation fluids may be reliably accomplished within formation-testing tools through depressurization mechanisms such as pre-test pistons, ensuring pure gas-phase analysis and further enhancing measurement reliability.

Ultimately, the integration of miniaturized chip-based mass spectrometry into downhole formation-testing tools represents a significant technological advancement. It expands analytical capabilities, enabling direct downhole detection and precise quantification of molecular hydrogen and other key gaseous components. This advancement complements existing sensor technologies, significantly enhancing the accuracy, reliability, and resolution of subsurface fluid characterization for effective reservoir evaluation and exploration. Chips further allow the potential for redundancy of measurements (i.e. multiple H2 chips, multiple H2S chips etc).

An important practical advantage of using selective hydrogen contrast agents such as metal hydride-based contrast agents for molecular hydrogen detection is the ease with which temporary formation damage or permeability reduction caused by hydride precipitation may be reversed following logging operations. Once the presence of molecular hydrogen is successfully identified and characterized through comprehensive logging, restoration of reservoir permeability and mobility is straightforward, allowing efficient subsequent production operations or additional exploration activities. Two principal operational strategies exist for reversing the precipitated hydride network and restoring original formation properties: controlled acid wash treatments and managed differential pressure drawdown.

Acid wash treatments represent a particularly effective and rapid method for dissolving metal hydride deposits around the wellbore. By applying mild acids, such as dilute hydrochloric acid or other acid solutions commonly used in oilfield operations, the metallic hydride network may be quickly dissolved and fully removed. Acid injection may be performed locally and precisely through formation testing probes, coiled tubing, or conventional stimulation equipment, rapidly restoring near-wellbore permeability and returning the reservoir to its original condition. Such targeted acid washes ensure that any formation damage caused by the hydride network is both temporary and easily reversed.

In other examples, controlled differential pressure drawdown offers a gentle, chemical-free means of reversing hydride formation and removing temporary formation damage. Under gradual reduction of reservoir pressure or controlled fluid withdrawal, the molecular hydrogen bound within the hydride network desorbs spontaneously. This process naturally reverts hydrides back into their precursor metallic state, effectively breaking apart the interconnected particle framework. Gradual drawdown methods restore permeability and fluid mobility gradually and naturally, offering a straightforward operational option without chemical interventions.

In exploratory drilling scenarios, where the primary objective is simply to detect and confirm the presence of molecular hydrogen, temporary formation damage induced by hydride precipitation may not pose significant operational concern, as subsequent sidetrack wells or dedicated production wells may be drilled separately. Thus, the primary logging operation in an exploratory well may readily tolerate temporary permeability reduction or formation alteration, knowing that full cleanup operation and reversal may be easily achieved afterward, or in other examples, bypassed altogether by drilling separate production-oriented sidetracks.

Additional operational methods for reversing hydride formation could involve localized heating or thermal stimulation. Moderate thermal elevation achieved through steam injection or electrical heating elements may induce rapid hydrogen desorption from metal hydrides, restoring permeability efficiently. Another possibility includes employing chemical reducing agents, such as mild hydride-destabilizing solutions, to specifically target and dissolve the hydride network, thereby restoring permeability.

In summary, formation cleanup operations following hydride-based contrast agent logging is straightforward and operationally convenient. Techniques such as acid wash treatments, controlled pressure drawdown, localized thermal stimulation, or mild chemical reduction offer reliable, efficient methods for reversing temporary formation damage, ensuring that reservoirs remain fully producible following successful identification and characterization of geologic hydrogen accumulations.

Formation testing tools may be effectively utilized to perform controlled injection and subsequent withdrawal experiments with hydrogen or hydrogen-containing gas mixtures, enabling comprehensive characterization of reservoir relative permeability, hydrogen recovery, and fluid-rock interactions. Specifically, hydrogen or hydrogen-based mixtures, potentially including controlled proportions of common reservoir gases such as nitrogen, carbon dioxide, helium, or methane, can be injected into the reservoir formation through the formation tester's probe assembly at controlled pressures and rates. Following injection, the formation tester is then operated to withdraw fluids from the injected formation interval, facilitating direct measurements of total fluid recovery, gas-to-water ratios, and recovery efficiency as a function of time.

During the withdrawal phase of the test, formation testers equipped with specialized internal sensors may measure total gas concentration, allowing for precise calculation of the percent of hydrogen-containing gas relative to the produced water volume. Furthermore, continuous measurement of formation pressures, differential pressures, and independent phase flow rates provides detailed temporal profiles of fluid mobility, permeability, and relative permeability to hydrogen-rich gas mixtures versus aqueous fluids. Such temporal data sets significantly enhance the quantitative understanding of hydrogen mobility and phase interactions within the reservoir environment.

In addition to total gas quantification, formation testers incorporating advanced analytical sensors, including optical spectroscopy sensors, NMR sensors, sonic velocity measurements, or chip-based mass spectroscopy sensors, can further analyze gas-phase composition dynamically during the withdrawal phase. By precisely tracking compositional variations over time, the data clearly identifies potential gas-phase differentiation resulting from selective mineralogical interactions with individual gas components. Observed temporal compositional changes provide direct indications of mineral-fluid interactions, such as selective adsorption, capillary retention, mineralogical reactions, or other physico-chemical phenomena. These measurements clearly establish whether specific mineralogical environments within the reservoir are favorable or unfavorable for sustained hydrogen accumulation and effective long-term production.

This experimental example may be systematically performed at multiple key stages, including prior to introduction of contrast agents, during active reaction of the contrast agents, and following the cleanup operation and reversal of the contrast-agent-induced alterations. Conducting such experiments at multiple sequential points provides robust baseline comparisons and a direct assessment of how the contrast agents and their reaction products affect formation permeability, hydrogen recovery efficiency, and fluid-mineral interactions. Ultimately, this systematic injection-withdrawal example using the formation tester delivers a uniquely comprehensive evaluation, not only determining relative permeability and phase mobility but also identifying and quantifying critical reservoir interactions such as gas reactivity, capillary phenomena, and mineralogical affinities for hydrogen. This robust characterization directly informs reservoir evaluation, exploration decisions, and field-development planning for molecular hydrogen prospects.

Relative permeability characterizes the ability of a porous rock formation to conduct fluid flow when multiple fluid phases, such as gas and water, are simultaneously present. Formation-testing tools provide an efficient and accurate method for measuring relative permeability directly in situ, offering significant advantages over laboratory measurements by capturing true reservoir conditions.

In a typical relative permeability experiment conducted with a formation tester, the tool's probe is sealed against the formation interval of interest. Initially, a baseline measurement of formation pressure and mobility is performed, often referred to as a “pre-test,” to establish initial reservoir conditions. Subsequently, a carefully controlled fluid phase, such as molecular hydrogen, a hydrogen-containing gas mixture, or another fluid of interest, is injected into the formation at a known pressure and flow rate. This injection displaces the native formation fluids and establishes a known saturation condition around the probe zone.

Following injection, a controlled withdrawal (“drawdown”) operation is conducted, where the formation tester extracts fluids from the previously injected interval at measured flow rates, while simultaneously recording dynamic pressure changes. During withdrawal, the formation tester continuously measures the produced fluid composition, differentiating between water and gas phases. Sensors integrated into the formation tester, including optical, density, acoustic, NMR, or mass spectrometry sensors, allow precise quantification of fluid composition, enabling the calculation of fluid saturations as a function of time.

Relative permeability is then determined by analyzing these measured pressure responses and fluid flow rates in combination with fluid composition data. As fluids are withdrawn, changes in measured pressures and saturations enable direct calculation of effective permeability to each fluid phase, providing relative permeability curves that accurately represent reservoir conditions. Multiple injection and withdrawal cycles may further refine these curves and increase measurement accuracy.

By performing these relative permeability tests directly within the reservoir, formation testers provide reliable, in situ characterization of fluid-flow behavior under realistic subsurface conditions. Such measurements are crucial for accurately predicting reservoir performance, fluid recovery efficiency, and for optimizing production or injection strategies, especially in reservoirs containing molecular hydrogen or other unique fluid phases.

Additionally, deploying the metal hydride contrast agents as targeted chemical “pills” rather than continuously circulating within the drilling mud may be particularly advantageous when managing potential formation damage is a critical operational consideration. Pills may be precisely directed and carefully placed at specific vertical locations within the wellbore, allowing operators to selectively target zones of interest for hydrogen detection, while leaving adjacent intervals completely unaffected. This localized and targeted application minimizes the overall extent of any temporary formation alteration or permeability reduction, thus significantly reducing the scope and scale of post-logging cleanup operations. Consequently, using targeted contrast-agent pills provides an ideal operational strategy for exploration or evaluation wells, ensuring minimal overall reservoir impact while reliably detecting and characterizing molecular hydrogen accumulations.

Contrast-agent pills offer operational flexibility, as they may be introduced into the wellbore through various practical deployment methods. For example, pills may be precisely placed as discrete fluid “gaps” or distinct segments within the drilling mud flow, enabling accurate vertical positioning of the reactive agents during drilling operations. In other examples, pills may be delivered directly to the desired reservoir depth via drill pipe or coiled tubing, allowing for careful and targeted injection with precise control over volume, pressure, and placement. Additionally, formation testing equipment provides yet another effective means for pill deployment, enabling direct injection of controlled contrast-agent volumes into formation zones through the formation tester's probe. This versatility of deployment methods ensures that hydride contrast agents may be introduced efficiently and precisely, optimizing hydrogen detection capability while simultaneously minimizing formation damage or operational complexity.

The implementation of differential logging, performing successive logging runs before, during, and after the introduction and activation of the hydrogen-reactive contrast agent, provides a powerful, direct method for validating molecular hydrogen presence and clearly characterizing its kinetics within reservoir formations. Differential logging involves conducting an optimal baseline logging measurement prior to introducing the contrast agent, followed by optional one or more subsequent logging runs at controlled intervals after contrast-agent placement, and ultimately, optionally a final logging measurement after the completion of cleanup operations. By systematically comparing formation properties at these distinct time points, operators obtain robust, temporally resolved evidence of selective hydrogen reaction and contrast-agent activation, significantly enhancing the confidence and reliability of geologic hydrogen detection.

The initial baseline logging measurement provides essential reference data, capturing the native petrophysical properties of the formation, such as acoustic velocity, acoustic impedance, electrical resistivity, dielectric constant, neutron and density responses, NMR T2 distributions, and fluid mobility, before any contrast-agent-induced alterations occur. Following this baseline measurement, the contrast agent (in pill or mud slurry form) is introduced into the targeted formation zone, initiating selective chemical reactions in the presence of molecular hydrogen. Subsequent logging runs conducted at defined intervals (ranging from hours to days, depending on tailored reaction kinetics and contrast-agent formulation) then clearly reveal measurable changes or deltas relative to baseline conditions. These measured differences, captured at multiple time points, directly confirm and quantify the progressive formation and growth of the metal hydride network, validating that the contrast agent has been activated specifically by molecular hydrogen.

Performing multiple intermediate logging runs at controlled intervals further provides valuable kinetic information about the hydrogen reaction process. Such temporal data not only confirm the selective chemical activation of the contrast agent but also yield quantitative insights into reaction rates and spatial progression of the hydride formation front within the reservoir. This temporal information may be especially advantageous when employing water-based slurries, which inherently exhibit slower hydride formation kinetics due to reduced hydrogen solubility, diffusivity, and surface reactivity. In such scenarios, incremental logging measurements over extended intervals clearly document gradual changes in formation properties, offering unequivocal validation of selective hydrogen-driven reaction processes that might otherwise be difficult to interpret from a single logging run alone.

Finally, conducting a differential logging run after completion of the cleanup operation, whether through acid wash treatments, controlled pressure drawdown, thermal stimulation, or other reversal methods, further confirms the reversible nature of the formation alteration. The measured return of formation properties to their original baseline conditions conclusively demonstrates that observed alterations were temporary and specifically due to selective hydrogen-induced reactions, rather than permanent formation changes. Thus, the differential logging example not only validates the selective reaction of the contrast agent but also confirms its reversible and controllable nature, minimizing concerns regarding lasting formation damage or permeability impairment.

Although metal hydride formation kinetics are typically quite rapid, reaction rates may be deliberately controlled or slowed down through careful engineering of the precursor particles, selection of suspension media, or choice of additives, specifically to facilitate differential logging operations. By adjusting parameters such as particle size distribution (larger are slower typically), surface coatings (such as oxide coatings), alloy composition (mixing in inert or poisoning dopants), and choice of aqueous or semi-aqueous media (including emulsions), it becomes possible to tailor the kinetics to achieve optimal timing aligned with planned logging sequences. For example, slowing down the hydride reaction rate may allow sufficient time for performing two sequential logging passes, such as one upward and one downward pass, or even multiple sequential passes (e.g., up and down twice), providing well-resolved intermediate data points that accurately capture the evolving formation response.

This tailored kinetic control provides significant practical advantages. Logging tools may effectively capture initial baseline conditions, followed by early-stage reaction conditions, and subsequently later-stage reaction states, clearly documenting a progressive evolution in formation properties. Such deliberate kinetic tuning significantly improves temporal resolution, providing precise intermediate snapshots of hydride formation and clearly demonstrating the progressive reaction driven selectively by molecular hydrogen.

Consequently, controlled reaction kinetics ensure optimal alignment with operational logging schedules, enhancing the interpretability and robustness of differential logging datasets. Operators thus gain clear, incremental evidence of selective hydrogen-driven reactions, validating the efficacy and selectivity of the contrast agent in the targeted reservoir intervals.

Although the primary example disclosed herein involves the use of metal hydride-based contrast agents for selective detection and characterization of molecular hydrogen in subsurface formations, this is in no way intended to limit the scope or applicability of the techniques described. The methods, concepts, and principles presented herein may be broadly applied to a variety of engineered chemical contrast agents, including but not limited to hydrolyzing compounds, amines, nitriles, imines, metal-organic frameworks, epoxides, and other reactive chemical species. Accordingly, any disclosure or illustrative examples specifically described in terms of metal hydrides should be understood as representative and fully extendable by analogy and functional equivalence to other classes of contrast agents, as would be readily recognized and implemented by those skilled in the art.

Although the preceding discussion primarily focused on the use of metal hydride-based contrast agents for molecular hydrogen detection, it is important to recognize that hydrolysable organic compounds, such as nitriles, imines, esters, amides, lactones, carbamates, hydro silanes, and related functional groups, represent valuable other examples. These hydrolysable agents may similarly be introduced as suspensions, pills, or tailored fluid systems into reservoir formations, creating distinctive and measurable alterations in formation properties analogous to the metal hydride systems previously described. However, employing hydrolysable compounds involves specific operational adjustments, such as consideration of hydrolysis stability, selection based on reservoir chemistry (including water, acidity, CO₂, and organic carbon content), and management of reaction kinetics. These considerations and adjustments are further explored in the sections that follow, highlighting both the similarities and distinct practical considerations associated with hydrolysable contrast agents as effective alternatives to metal hydrides for molecular hydrogen detection.

Imines and nitriles represent an attractive alternative class of hydrogen-selective contrast agents, owing to their strong and selective hydrogenation reactions at moderate to elevated subsurface temperatures and pressures (typically 75° C.-200° C. and up to 5,000 psi or higher). However, their practical utility as contrast agents in geological reservoirs strongly depends on their stability toward hydrolysis and other competing reactions, especially considering common reservoir fluids and gases, comprising liquid water, gaseous water vapor, carbon dioxide (CO₂), nitrogen (N₂), methane (CH₄), and the presence of mineral and organic matter.

Under the given subsurface conditions, imines (—C═N—) are relatively more susceptible to hydrolysis compared to nitriles, particularly in the presence of liquid water or acidic formation fluids. Hydrolysis of imines leads to formation of the corresponding primary amines and aldehydes or ketones, thus potentially reducing the selectivity and sensitivity of hydrogen detection. However, the reaction kinetics and equilibrium strongly depend on the pH, temperature, and the specific chemical environment. Under neutral or mildly basic reservoir conditions, hydrolysis rates of carefully selected imines may remain sufficiently slow or negligible, ensuring that hydrogenation reactions (which are kinetically rapid and thermodynamically favorable at these temperatures and pressures) predominate. Selecting imines with bulky substituents or incorporating hydrophobic groups may significantly reduce susceptibility to hydrolysis by limiting water access to reactive centers.

Nitriles (—C≡N), by contrast, generally exhibit significantly greater hydrolytic stability under moderate subsurface conditions, making them highly suitable for selective hydrogen detection applications. While nitrile hydrolysis is thermodynamically possible, yielding carboxylic acids or amides, it usually implements strongly acidic or basic conditions combined with elevated temperatures and prolonged reaction times. Under typical reservoir conditions (near-neutral pH, moderate temperatures around 75-200° C., and pressures up to 5,000 psi or more), nitrile hydrolysis kinetics remain extremely slow, typically negligible compared to their rapid and highly selective hydrogenation reactions. Therefore, nitriles represent robust and reliable contrast agents that remain selective toward hydrogen even in the presence of significant amounts of liquid water, water vapor, CO₂, CH₄, and N₂.

Additionally, common geological reservoir interferents, such as carbon dioxide, methane, and nitrogen, do not readily react chemically with either imines or nitriles under these moderate reservoir conditions. The absence of strong chemical reactivity ensures minimal interference or competitive reaction pathways. Similarly, typical reservoir minerals, clays, and organic matter generally exhibit negligible reactivity toward nitriles and carefully selected imines at these moderate temperatures and near-neutral pH, further maintaining selectivity for hydrogen detection.

In practical application, nitriles represent the more favorable choice as selective hydrogen-reactive contrast agents due to their inherent chemical robustness, superior resistance to hydrolysis, and lack of reactivity with common reservoir interferents. While imines remain an option under carefully controlled reservoir conditions or with specifically designed chemical structures, nitriles consistently offer superior selectivity, stability, and overall practical reliability under realistic geological reservoir conditions.

Although nitriles and imines represent ideal selective hydrogenation contrast agents due to their balanced hydrolytic stability and selective reactivity with molecular hydrogen, alternative hydrolysable compounds may also be suitable contrast agents under specific reservoir conditions. Compounds such as esters, lactones, amides, carbamates, anhydrides, acetals, ketals, and hydro silanes may exhibit favorable hydrogenation or hydrogen-sensitive reactions under tailored subsurface conditions. For example, esters and lactones may be selectively hydrogenated or ring-opened at relatively lower temperatures, provided acidic fluids and significant carbon dioxide concentrations are absent. Similarly, carbamates and amides may function as contrast agents under elevated temperature conditions, especially when reservoir fluids exhibit minimal acidity or limited water content. Acetals, ketals, and hydro silanes may offer additional tailored reactivity profiles, particularly useful when interfering species such as organic carbon, carbon dioxide, or acidic water are not present in substantial quantities. Consequently, careful selection and consideration of reservoir-specific temperature, pressure, chemical environment, and interferent compounds enable effective utilization of a broad range of hydrolysable compounds as contrast agents for hydrogen detection under certain well-defined conditions.

Hydrolysable contrast-agent compounds (such as nitriles, imines, esters, amides, lactones, carbamates, or hydro silanes) offer additional unique opportunities for reservoir detection beyond their selective hydrogen reactions alone. Upon selective reaction with molecular hydrogen followed by subsequent hydrolysis or further chemical transformations, these compounds yield specific reaction byproducts that themselves may be engineered to provide directly detectable signatures or significant modifications of formation properties. Such hydrolysis reaction products, often including amines, aldehydes, carboxylic acids, silanols, alcohols, or other polar intermediates, may subsequently interact or complex with formation minerals, ions, or specifically introduced chemical additives, resulting in the precipitation of insoluble compounds, formation of immobile gels, or significant changes in fluid viscosity and mobility.

These secondary reaction products and precipitates may be engineered to include specialized tracers or chemically reactive functional groups, significantly enhancing their detectability by conventional petrophysical logging tools. For example, hydrolysis byproducts or intermediate reaction products may form insoluble precipitates containing highly neutron-absorbing elements, such as gadolinium, europium, hafnium, boron, or cadmium, thereby providing distinct and easily identifiable nuclear logging signatures. Similarly, stable gels or polymeric byproducts formed upon hydrolysis could be designed to incorporate electrically conductive or resistive materials (metallic nanoparticles, conductive polymers, or organometallic complexes), thus offering significant electromagnetic logging contrast.

Beyond the inclusion of specific tracers, the reaction byproducts themselves may directly modify reservoir formation properties in ways readily detectable by logging tools. For instance, hydrolysis-induced precipitates or polymeric gels formed in situ within the pore space may significantly reduce local permeability and porosity, thereby yielding measurable changes in fluid mobility, pressure response, and porosity-sensitive logs. In addition, certain organic reaction products such as polymeric amines or gels formed by carbamates and amides exhibit distinctly identifiable Nuclear Magnetic Resonance (NMR) relaxation time signatures due to bound hydrogen environments, allowing their direct identification through NMR logging techniques.

Ultimately, exploiting the hydrolysis byproducts of hydrogen-reactive contrast agents provides multiple pathways for enhancing reservoir detection and characterization. The strategic design and selection of these byproducts, leveraging their ability to precipitate, form gels, alter formation properties, or incorporate specific nuclear and electromagnetic tracers, offer versatile, robust examples for significantly amplifying detection signals and unambiguously identifying molecular hydrogen accumulations within complex subsurface environments.

The formation of immobile gels or polymeric precipitates resulting from hydrolysable contrast agents provides a powerful method for enhanced logging detection; however, ensuring ease of cleanup and minimizing permanent formation damage remain essential operational considerations. An important advantage of employing engineered gel-forming contrast agents lies in their inherent reversibility and controlled degradation, allowing straightforward post-logging remediation. These gels may be specifically designed with built-in chemical or structural characteristics that facilitate rapid and efficient removal, restoration of formation permeability, and minimal long-term reservoir impact.

One effective strategy for controlled gel degradation involves incorporating chemical or thermally labile cross-linkers or functional groups within the gel structure. Such cross-linkers may be deliberately chosen to degrade or depolymerize upon exposure to mild chemical breakers (weak acids, oxidizing agents, or mild reducing agents) or modest thermal stimuli. Introducing dilute acid solutions, peroxide-based breakers, or mild oxidative compounds into the near-wellbore region may efficiently and completely degrade these engineered gels, rapidly restoring formation permeability and porosity to pre-logging conditions. This method ensures minimal residual formation damage, easy operational control, and rapid cleanup turnaround.

In other examples, gels may be engineered to be highly sensitive to specific pH adjustments or salinity changes. By strategically introducing mild chemical solutions that alter formation water chemistry, such as controlled brine solutions or slightly acidic buffers, operators may trigger rapid gel destabilization and dissolution. Such carefully controlled chemical adjustments offer straightforward cleanup protocols that swiftly reverse any temporary formation blockage created by the gelled contrast agents.

Moreover, formation damage mitigation may be further simplified by formulating gels to have intrinsic mechanical fragility. These mechanically weak gels easily break down under moderate differential pressure drawdown conditions, facilitating rapid permeability restoration simply through controlled flowback or gentle production drawdown. This mechanical reversibility simplifies operational logistics, minimizing the need for chemical cleanup treatments altogether. Engineered gels produced from hydrolysable contrast agents inherently allow simple, controlled, and efficient cleanup and reversal of temporary formation damage. By incorporating chemically degradable cross-linkers, pH- or salinity-sensitive functionalities, or mechanically weak gel structures, operators may confidently employ gel-forming contrast agents for robust hydrogen detection, while ensuring ease of cleanup and minimal long-term reservoir impact.

Hydrolyzing precursor compounds offer innovative opportunities to create specialized “reverse-contrast” detection strategies, leveraging their unique chemical transformation characteristics upon selective hydrogen reaction and subsequent hydrolysis. One compelling example involves integrating these hydrolysable compounds into engineered resonating microspheres or microcapsules designed specifically for acoustic detection. Prior to reacting with molecular hydrogen, these engineered spheres possess distinctive acoustic resonance frequencies, easily measurable by acoustic logging tools. Upon selective hydrogenation and subsequent hydrolysis, however, structural integrity of these spheres is compromised, resulting in rapid degradation, breakage, or collapse of the resonating structure. Consequently, previously prominent acoustic resonances dramatically diminish or entirely disappear, providing a clear and direct acoustic “reverse-contrast” signal, unequivocally indicating hydrogen-induced chemical transformation and confirming molecular hydrogen presence.

Another innovative example utilizes hydrolyzing precursor compounds to chemically trap molecular hydrogen in structurally distinct forms characterized by unique fluid mobility and distinct Nuclear Magnetic Resonance (NMR) relaxation properties. For example, upon selective hydrogenation and subsequent controlled hydrolysis, precursors may yield polymeric or gel-like byproducts that physically encapsulate hydrogen gas in micro-bubble or emulsion-like structures, creating distinct fluid mobility regimes detectable by NMR logging. Such hydrogen-encapsulated emulsions or gels exhibit significantly altered T₂ relaxation signatures, producing characteristically intermediate or shortened relaxation times clearly distinguishable from free gaseous hydrogen or dissolved hydrogen in formation fluids. These unique trapped-hydrogen forms yield direct and unmistakable NMR detection signatures, providing powerful and reliable confirmation of molecular hydrogen accumulation and selective contrast-agent activation.

Ultimately, incorporating hydrolyzing precursor compounds into engineered reverse-contrast acoustic spheres or uniquely hydrogen-trapping gel-like structures significantly expands logging detection capabilities. These strategies leverage the selective hydrogen-induced structural breakdown of resonating spheres and the distinct NMR mobility signatures of hydrogen-trapped gels or emulsions, creating clear, direct, and uniquely measurable petrophysical signals confirming molecular hydrogen presence within subsurface reservoirs.

The selective hydrogen-reactive contrast agents described here, comprising metal hydride precursors, hydrolyzing compounds, and engineered reverse-contrast detection agents, may be effectively deployed and measured using both wireline logging and Logging-While-Drilling (LWD) technologies. In wireline operations, contrast-agent pills or suspensions may be precisely introduced into targeted formation intervals either via controlled circulation through the drilling fluid, direct placement through drill pipe or coiled tubing, or through targeted injection using wireline formation testers. Subsequent wireline logging measurements, encompassing electromagnetic, nuclear, NMR, acoustic, dielectric, and formation tester-based sensors, provide direct, high-resolution detection of the chemically induced formation changes, clearly indicating the presence and extent of molecular hydrogen accumulations.

Similarly, the contrast-agent methodologies outlined herein are fully compatible with Logging-While-Drilling (LWD) systems. In LWD applications, the contrast agents may be incorporated directly into the drilling mud system or introduced periodically as discrete pills, systematically penetrating into the formation as drilling progresses. Formation reactions occur during or shortly after drilling, and subsequent LWD tool measurements taken at strategic intervals or after brief circulation stoppages capture the progressive reaction and formation alteration in real time. LWD tools incorporating electromagnetic, nuclear, acoustic, dielectric, and NMR sensors provide continuous or periodic measurements, enabling near-real-time detection of the developing hydride networks or other reaction byproducts around the borehole.

For either wireline or LWD operations, the temporal resolution achievable through differential logging techniques, where initial baseline measurements are followed by intermediate and post-reaction logs, offers a powerful means to quantify reaction kinetics, validate selective hydrogen activation, and confirm the presence of hydrogen-rich zones. In addition, the inherent compatibility of these contrast agents with standard operational procedures ensures seamless integration into existing logging workflows, providing robust, practical solutions for reliable geologic hydrogen detection across diverse operational scenarios.

In addition to their subsurface diagnostic capability, hydrogen-selective contrast agents, such as metal hydride precursors and hydrolyzing compounds, may be integrated directly into drilling mud systems to capture and preserve molecular hydrogen (H₂) encountered during drilling operations. When geological hydrogen-bearing formations are penetrated, hydrogen gas naturally diffuses or flows into the circulating drilling mud within the borehole. By incorporating finely dispersed contrast-agent particles directly within the drilling mud, molecular hydrogen encountered during drilling becomes chemically bound and immobilized immediately upon contact, forming stable hydrides or reaction byproducts. This rapid and selective chemical trapping of hydrogen significantly reduces gas losses or dilution during circulation, effectively preserving the original hydrogen signature for subsequent analysis at surface.

Once returned to surface, the drilling mud containing the reacted contrast-agent particles serves as a stable reservoir preserving hydrogen in chemically bound form. Surface-based analytical methods, such as thermal desorption, controlled depressurization, acid digestion, or chemical decomposition, may then release and quantify the chemically bound hydrogen, precisely identifying and quantifying molecular hydrogen encountered in the subsurface. This method provides a direct, robust measurement of the molecular hydrogen content in situ, overcoming typical surface gas-analysis known to those skilled in the art as surface data logging or mud logging challenges such as hydrogen volatility, contamination, or dilution in circulating fluids.

Furthermore, this preservation and capture method offers substantial advantages over conventional mud gas logging, which typically relies on continuous extraction and analysis of free hydrogen gas from circulating mud at surface conditions, a process often complicated by gas dispersion, low hydrogen solubility, and significant dilution. By chemically stabilizing hydrogen immediately upon entry into the borehole fluids, contrast agents ensure representative and accurate preservation of hydrogen concentrations encountered within the reservoir, enhancing surface analytical reliability and providing clear, definitive confirmation of geologic hydrogen presence and abundance.

Incorporating selective hydrogen-reactive contrast agents directly into drilling mud systems provides a highly effective strategy for capturing, stabilizing, and preserving molecular hydrogen encountered during drilling. This example enhances surface analysis accuracy, significantly reduces operational uncertainty, and provides a direct, reliable method to detect and quantify naturally occurring hydrogen within geological reservoirs. Further it may provide additional safety by reducing flux of hydrogen gas to surface should there be substantial influx, but also capture the hydrogen downhole to reduce kicks or mitigate blowouts.

Reactive contrast agents, such as metal hydrides or hydrolyzing compounds specifically engineered to chemically trap molecular hydrogen, may be effectively utilized to preserve hydrogen within core samples during the coring process, subsequent transport, and analysis at surface. Preservation of hydrogen-rich cores may be accomplished through two primary examples, both leveraging the selective reactivity of these agents.

In the first example, reactive contrast agents are deployed within the near-wellbore environment before the coring operation begins. After the contrast agents have had sufficient time to react and selectively trap molecular hydrogen present within the formation, coring is performed through this reacted zone. Because hydrogen is chemically bound to the contrast agents within the pore structure, significantly less hydrogen loss occurs when the cores are retrieved to surface. This reactive preservation substantially improves the accuracy and reliability of subsequent hydrogen-content analyses performed on the recovered cores.

A second example involves directly incorporating reactive contrast agents into the core barrel itself. During coring operations, the core barrel, either a conventional full-core barrel or a sidewall coring device, is pre-filled or lined with the reactive contrast agent. In this arrangement, any hydrogen escaping from the core sample during depressurization or transport may react immediately with the contrast agent present in the core barrel, ensuring chemical preservation of hydrogen within the sealed core environment. Upon retrieval, the core barrel is typically placed within a sealed core container, further enhancing hydrogen retention. These sealed core containers may be either pressure-compensated or non-pressure-compensated. Pressure-compensated core barrels allow the core samples to remain near formation pressures during transport, significantly minimizing depressurization and hydrogen loss, effects commonly exacerbated by thermal contraction of fluids during retrieval. In cases where sealed containers are non-pressure-compensated, hydrogen loss occurs primarily due to reduction in hydrostatic pressure as the core is brought to surface; however, the presence of reactive contrast agents within the sealed barrel mitigates such losses by chemical trapping.

Beyond core samples, reactive contrast agents may also significantly enhance the preservation of hydrogen in fluid samples acquired via formation testers or drill-stem tests. In such fluid sampling scenarios, after the cleanup pump-out phase, fluid samples collected in downhole sample chambers may be exposed to reactive contrast agents incorporated directly into the sampling chambers. Hydrogen that would otherwise diffuse or react out of the samples during retrieval and depressurization is selectively and chemically immobilized, ensuring accurate representation of formation fluid composition upon subsequent laboratory analysis.

Therefore, the strategic use of hydrogen-selective contrast agents provides a versatile and robust methodology for preserving molecular hydrogen in core and fluid samples, substantially improving analytical reliability, and providing direct evidence for subsurface hydrogen accumulations.

Reactive contrast agents, such as metal hydrides or hydrolyzing compounds specifically engineered to chemically trap molecular hydrogen, may be effectively utilized to preserve hydrogen within core samples during the coring process, subsequent transport, and analysis at surface. Preservation of hydrogen-rich cores may be accomplished through two primary examples, both leveraging the selective reactivity of these agents.

In the first example, reactive contrast agents are deployed within the near-wellbore environment before the coring operation begins. After the contrast agents have had sufficient time to react and selectively trap molecular hydrogen present within the formation, coring is performed through this reacted zone. Because the hydrogen is chemically bound to the contrast agents within the pore structure, significantly less hydrogen loss occurs when the cores are retrieved to surface. This reactive preservation substantially improves the accuracy and reliability of subsequent hydrogen-content analyses performed on the recovered cores.

Utilizing hydrogen-selective reactive contrast agents to preserve subsurface core and fluid samples not only prevents loss of molecular hydrogen during retrieval but also significantly improves subsequent analysis of hydrogen content. By measuring reaction products formed through the selective immobilization of hydrogen, such as metal hydrides, stable organic hydrides, gels, or other chemical reaction byproducts, accurate determination of original hydrogen concentration in bottom-hole samples becomes possible. Laboratory-based analytical techniques including spectroscopy, X-ray diffraction, nuclear magnetic resonance, mass spectrometry, or thermal desorption may precisely quantify these reaction products, thereby providing a robust, indirect measure of the original hydrogen content captured in situ.

In addition, the preserved hydrogen in chemically bound form within contrast agents may be selectively released at the surface using reversible chemical or physical methods. Controlled chemical reactions, such as mild acid digestion or application of selective reducing or oxidizing agents, can effectively liberate the chemically immobilized hydrogen, enabling conventional gas-phase analytical techniques, such as gas chromatography, mass spectrometry, Raman spectroscopy, or infrared spectroscopy, to directly quantify molecular hydrogen. In other examples, carefully controlled phase-behavior reversibility methods, such as temperature elevation or controlled depressurization, may also liberate hydrogen gas from the reacted contrast agent, facilitating direct quantification and analysis using conventional laboratory instrumentation.

Thus, reactive contrast agents provide dual analytical advantages: first, they preserve hydrogen within subsurface samples during retrieval; second, they enable precise determination of hydrogen content either by directly analyzing stable reaction products or by subsequently releasing hydrogen for conventional detection. This versatility significantly enhances the reliability and accuracy of bottom-hole hydrogen measurements, supporting improved reservoir characterization and exploration decisions.

While the previous discussion primarily focused on the selective detection of molecular hydrogen (H₂), the principles and methodologies described herein may be effectively extended, with certain adjustments, to detect hydrogen sulfide (H₂S) within subsurface reservoirs. Specifically, metal hydride-based contrast agents exhibit very low to negligible reactivity with hydrogen sulfide under typical subsurface conditions (75-200° C., 1,000-5,000 psi), as the primary interaction mechanism involves hydrogen insertion into metal lattices rather than formation of sulfides. Similarly, most classes of hydrolyzing contrast-agent compounds, including esters, lactones, amides, carbamates, acetals, ketals, and anhydrides, also exhibit minimal or negligible reactivity with H₂S under moderate reservoir conditions, further preserving their selectivity towards molecular hydrogen.

However, certain hydrolyzing compound classes, specifically hydro silanes and silanes, as well as epoxides, demonstrate moderate chemical reactivity with hydrogen sulfide, particularly under elevated temperature conditions or in the presence of catalytic impurities. Acyl chlorides, in particular, exhibit rapid and highly selective reaction kinetics with H₂S, readily forming stable and detectable thioesters or similar sulfur-containing compounds at moderate reservoir conditions. Thus, these specific compound classes (hydro silanes, silanes, epoxides, and especially acyl chlorides) may serve as highly effective alternative contrast agents for detecting hydrogen sulfide, employing exactly the same operational and measurement methodologies described previously for hydrogen detection.

When employed as selective hydrogen sulfide contrast agents, these compounds undergo distinct chemical reactions resulting in formation of stable precipitates, gels, or other reaction byproducts that alter formation properties and yield clearly measurable electromagnetic, acoustic, nuclear, and NMR logging signatures. The resulting reaction networks or byproducts may be tailored to incorporate additional detectable nuclear or electromagnetic tracers or engineered to modify reservoir properties (e.g., permeability, porosity, acoustic impedance) to provide robust and unequivocal identification of hydrogen sulfide-bearing formation intervals.

Consequently, the techniques and methods fully described herein for molecular hydrogen detection, including differential logging, temporal kinetic measurement, contrast-agent introduction via mud systems or targeted pills, and cleanup strategies, may be straightforwardly adapted to hydrogen sulfide detection applications, leveraging the distinct chemical reactivity of hydro silanes, silanes, epoxides, and acyl chlorides toward H₂S. This represents another example of the overall methodology, expanding the practical utility and versatility of the contrast-agent example for comprehensive reservoir fluid characterization.

By strategically combining contrast agents with selective chemical reactivity profiles, it becomes feasible to clearly differentiate between molecular hydrogen (H₂) and hydrogen sulfide (H₂S) within subsurface reservoirs. Specifically, the simultaneous deployment of both hydrogen-specific contrast agents (such as metal hydrides, nitriles, imines, esters, amides, and acetals) and contrast agents that exhibit nonspecific reactivity with both H₂ and H₂S (such as hydro silanes, silanes, epoxides, or acyl chlorides) provides a powerful analytical tool. Under this operational scenario, hydrogen-specific agents exclusively react with molecular hydrogen, while nonspecific agents concurrently react with both H₂ and H₂S.

This dual-agent example yields two distinct reaction signatures detectable via standard logging methods, where the differential responses between the two agents directly confirm the presence or absence of hydrogen sulfide. Specifically, if both classes of contrast agents indicate reaction and formation changes, this result strongly implies the presence of both molecular hydrogen and hydrogen sulfide. Conversely, if only the hydrogen-specific agents produce a measurable reaction, while the nonspecific agents remain largely unaltered, the presence of molecular hydrogen without significant hydrogen sulfide is clearly indicated.

Implementing this combined contrast-agent strategy significantly improves reservoir fluid characterization, providing clear chemical differentiation between H₂ and H₂S. This enhances interpretational accuracy and reduces ambiguity, especially in reservoirs where both gases may coexist. Thus, employing complementary pairs of selective and nonspecific contrast agents greatly expands analytical capability and accuracy, providing comprehensive and unequivocal detection and differentiation of molecular hydrogen and hydrogen sulfide within complex subsurface environments.

A “pill,” as commonly understood in wellbore operations, is a discrete volume of a fluid or chemical substance inserted into and temporarily displacing another fluid, typically one already occupying the wellbore, such as drilling mud or completion fluid. The pill is generally the smaller of the two fluid volumes and is purposefully introduced to achieve specific operational or analytical objectives. In the context of detecting geologic hydrogen (H₂) or other targeted subsurface components such as hydrogen sulfide (H₂S), carbon dioxide (CO₂), or specific mineralogical substances, the pill contains at least one reactive contrast agent configured to chemically interact with the targeted formation substance upon infiltration or diffusion into the reservoir formation.

In one operational example, the pill containing the reactive contrast agent is injected intermittently into the wellbore, interspersed within the normal flow of the drilling fluid during drilling operations. To prevent unwanted mixing or dilution between the pill and the primary operational fluid, a dedicated separator fluid or barrier fluid may be employed. Such separator fluids may be engineered to maintain fluid integrity based on specific physical or chemical properties, including increased viscosity, higher density, immiscibility, or enhanced surface tension and internal cohesion. The use of these separator fluids or mechanical separator devices is not limited to drilling operations but may be broadly applied without limitation to any of the pill operations described herein.

A particularly beneficial example involves systematically injecting contrast-agent-containing pills at characteristic, predetermined intervals of depth as drilling progresses. These strategically placed pills infiltrate the formation primarily via spurt loss at or near the bit, allowing rapid and controlled entry of the reactive contrast agents into the formation pore network, immediately followed by natural sealing provided by the drilling mud. This method results in a unique, recognizable vertical or lateral pattern of chemical reactions within the formation, clearly distinguishable against baseline intervals where no pill was injected. The resultant reactive pattern greatly simplifies detection and interpretation of targeted formation components such as molecular hydrogen.

By creating such deliberate injection patterns, previously uncharacterized formations may be robustly evaluated for the presence and distribution of hydrogen or other reactive targets, comprising at least one reactive component within the subsurface formation fluid, significantly enhancing reservoir characterization accuracy. Thus, the targeted use of reactive contrast-agent pills, supported by separator fluids and strategic injection methodologies, provides a versatile and effective example for precise, in situ evaluation of subsurface formations during drilling and other wellbore operations.

While the previously described set of contrast agents focused primarily on the selective detection and characterization of molecular hydrogen (H₂), analogous methodologies employing an alternative class of chemical contrast agents may be specifically adapted for highly selective detection and characterization of carbon dioxide (CO₂) within subsurface reservoir formations. Several compound classes exhibit selective and robust chemical reactivity with CO₂ under typical reservoir conditions (approximately 75-200° C., 1,000-5,000 psi and higher), forming distinct, stable reaction products that alter reservoir properties in measurable and detectable ways.

These contrast agents include the following key categories: First, an Amine and Amino-functionalized Compound. Examples: Monoethanolamine (MEA), Diethanolamine (DEA), Methyldiethanolamine (MDEA), 2-Amino-2-methyl-1-propanol (AMP), polyethyleneimines (PEIs), amino-functionalized silicas and zeolites. Reaction Mechanism: Rapid, selective formation of carbamates and bicarbonate species upon reaction with CO₂. Detectable Alterations: Formation of stable gels or precipitates detectable through acoustic velocity changes, electrical resistivity shifts, nuclear density contrasts, and distinctive NMR relaxation signatures. Selectivity: High; negligible reaction with methane (CH₄), hydrogen (H₂), nitrogen (N₂); manageable and distinguishable interference from hydrogen sulfide (H₂S). Second, an Alkaline Earth Metal Hydroxide. Examples: Calcium hydroxide (Ca(OH)₂), Magnesium hydroxide (Mg(OH)₂). Reaction Mechanism: Highly selective and irreversible precipitation of insoluble carbonate salts (CaCO₃, MgCO₃) upon CO₂ reaction. Detectable Alterations: Pronounced density and acoustic impedance increases, significant nuclear logging contrasts, resistivity changes due to precipitate formation within pore space. Selectivity: Excellent; negligible reactivity with methane, hydrogen, nitrogen, and minimal-to-moderate manageable interference from H₂S. Third, a Metal-Organic Frameworks (MOFs) Examples: Mg-MOF-74, HKUST-1, Zeolitic imidazolate frameworks (e.g., ZIF-8, ZIF-67). Reaction Mechanism: Highly selective and reversible adsorption or chemisorption of CO₂ within engineered porous crystalline structures. Detectable Alterations: Changes in formation density, acoustic impedance, nuclear logging properties, dielectric response, and porosity/permeability shifts due to solid-phase deposition. Selectivity: Exceptionally high; negligible interference from methane, hydrogen, nitrogen, and limited, typically manageable H₂S adsorption. Fourth, Organic Epoxides (to form Cyclic Carbonates) Examples: Ethylene oxide, Propylene oxide, Styrene oxide. Reaction Mechanism: Catalytically facilitated ring-opening and carbonate formation with CO₂, forming distinctive cyclic carbonates or polymeric gels. Detectable Alterations: Formation of gels or viscous fluids with distinctive NMR signatures, altered acoustic properties, permeability/porosity reductions, dielectric contrasts. Selectivity: High specificity for CO₂; however, moderate potential interference at elevated temperatures or acidic reservoir environments. Fifth, and/or, an Alkali Metal Carbonate Solution. Examples: Sodium carbonate (Na₂CO₃), Potassium carbonate (K₂CO₃). Reaction Mechanism: Formation of bicarbonates (NaHCO₃, KHCO₃) through CO₂ absorption. Detectable Alterations: Formation of soluble or insoluble precipitates and gels, influencing formation permeability, porosity, acoustic impedance, and resistivity. Selectivity: High specificity to CO₂ under neutral to slightly alkaline reservoir conditions, manageable interference at highly acidic conditions or significant H₂S presence.

The comprehensive example described herein for detecting molecular hydrogen (H₂), hydrogen sulfide (H₂S) and carbon dioxide (CO₂) in geological formations may be generalized into a versatile methodology applicable to the selective detection and characterization of virtually any reactive formation-fluid component of interest. This generalized example is founded upon the strategic use of chemically reactive contrast agents specifically engineered to react selectively and distinctly with targeted subsurface fluid components, such as molecular hydrogen, carbon dioxide, hydrogen sulfide, methane, specific hydrocarbons, acids, bases, brines, or other fluid species, while remaining largely inert or minimally reactive with commonly encountered interferent fluids (e.g., water, nitrogen, methane, or organic matter).

To achieve selective detection, suitable chemical contrast agents are introduced directly into reservoir formations through various deployment methods, including drilling mud systems, discrete fluid pills, coiled tubing, drill pipe delivery, or formation-testing tools. Upon exposure to the targeted fluid component, these contrast agents undergo selective and distinct chemical reactions that form stable precipitates, immobile gels, soluble complexes, or structurally altered phases within the reservoir pore space. The resulting reaction products or byproducts substantially alter formation properties in measurable ways, such as porosity, permeability, acoustic velocity, acoustic impedance, nuclear density, neutron absorption cross-section, resistivity, dielectric permittivity, or NMR relaxation characteristics, thus enabling direct and robust detection via conventional petrophysical logging tools.

Furthermore, by employing multiple complementary logging techniques, such as electromagnetic (EM), acoustic, nuclear, dielectric, porosity and permeability logging, nuclear magnetic resonance (NMR), and formation testing measurements, operators may reliably detect and quantify these selective reactions. Differential logging examples, involving repeated measurements before, during, and after contrast-agent deployment, provide definitive confirmation and clear temporal kinetic resolution, confirming selective contrast-agent activation. Moreover, the contrast agents may be tailored or enhanced with additional detectable signatures, such as nuclear tracers, electromagnetic markers, acoustic resonators, or structurally responsive encapsulations, further amplifying detection sensitivity and specificity.

Operational flexibility inherent in this generalized methodology enables selective detection of virtually any reactive subsurface fluid species. By appropriate selection and engineering of contrast agents, choosing among metal hydrides, nitriles, imines, amines, epoxides, esters, hydroxides, metal-organic frameworks, hydro silanes, carbamates, or other specifically reactive chemical groups, operators may tailor the detection strategy precisely to the formation-fluid component of interest. Such tailored deployments are further enhanced by reversible reaction mechanisms, engineered cleanup strategies, and controlled reaction kinetics to minimize permanent reservoir alteration.

The hydrogen detection methodologies described herein may also be effectively applied to identify and characterize minerals capable of producing molecular hydrogen through chemical reactions, particularly those stimulated by interaction with water at elevated reservoir temperatures. Certain minerals, when exposed to water under reservoir conditions, undergo specific geochemical reactions, such as serpentinization reactions involving mafic or ultramafic rocks (e.g., olivine), which generate molecular hydrogen. By deliberately introducing water into formations containing hydrogen-producing minerals, molecular hydrogen may be generated in situ and subsequently immobilized, preserved, and illuminated using reactive contrast agents.

In one example, water may be strategically delivered to the target formation via emulsions specifically engineered to break upon introduction into the reservoir, releasing water in direct contact with hydrogen-producing minerals. Upon reaction with these minerals, molecular hydrogen is produced and then selectively immobilized through subsequent or simultaneous introduction of reactive contrast agents. Another operational example involves sequential introduction of water within a drilling or completion mud system, followed immediately or shortly thereafter by injection of a reactive contrast-agent pill, thereby capturing and immobilizing the hydrogen generated by mineral-water reactions.

In other examples, discrete volumes (“pills”) of water may be injected, immediately followed by pills containing the reactive contrast agent, creating controlled and sequentially reactive patterns in the formation. Such sequential water and contrast-agent pills further enhance the detection, allowing clear differentiation of the hydrogen generated from reactive minerals. Moreover, this contrast-agent methodology may be employed as a two-step reaction process. For example, a first step involving the introduction of water containing an isotopically labeled hydrogen species, such as tritium-based water (tritiated water), could react with the hydrogen-producing mineral to yield tritiated molecular hydrogen. In a second step, this labeled hydrogen is subsequently immobilized by reaction with a suitable hydrogen-reactive contrast agent, creating a distinctly detectable radiogenic pattern uniquely identifiable by downhole logging tools.

The methods described herein for identifying and characterizing hydrogen-producing minerals within subsurface formations using reactive contrast agents may be further significantly augmented and improved by integrating conventional petrophysical logging techniques and surface-based analytical methods. Conventional nuclear logging tools capable of elemental analysis, such as gamma-ray spectroscopy, neutron-induced gamma-ray spectroscopy, and neutron activation logging, provide valuable constraints on the specific mineralogy and elemental composition of the subsurface formation. Such elemental logging data complements the contrast-agent methods by identifying characteristic elemental signatures associated with minerals capable of generating hydrogen through water-mineral interactions, thereby refining mineralogical interpretations and improving overall accuracy.

Additionally, surface data logging methods, comprising analysis of drilled cuttings or mud samples collected at the surface, may directly assess the mineralogical and elemental composition of the formation materials encountered during drilling. Although surface data logging alone generally lacks precise subsurface spatial resolution, combining it with the reactive contrast-agent logging example described herein provides a powerful synergy. The contrast-agent methods pinpoint exact subsurface locations of hydrogen-generating reactions, while surface analysis of cuttings identifies specific mineralogy and elemental composition of minerals involved, including their reaction status (e.g., spent or unreacted).

Such combined methods enable a comprehensive understanding of the formation's hydrogen-production potential without concerns related to inadvertent mineral reactions (spent minerals) occurring during drilling. Surface data logging or laboratory techniques performed on collected cuttings provide detailed mineralogical and elemental characterizations, while the downhole contrast-agent logging techniques precisely localize hydrogen generation zones in the formation. Consequently, even if minerals become partially or fully reacted during drilling, this combined example still reliably determines their original subsurface location, elemental composition, and overall hydrogen-production potential. This synergistic integration of conventional elemental logging, surface data logging, and reactive contrast-agent logging therefore represents a robust, accurate, and operationally advantageous methodology for comprehensive characterization of subsurface hydrogen-generating mineral deposits.

The identification and characterization of hydrogen-producing minerals using reactive contrast agents may be further constrained and enhanced by integrating multiple complementary logging methods, each sensitive to different physical and chemical properties resulting from mineral reactions. Electromagnetic (EM) logging, for example, may differentiate the oxidation states of iron present within minerals (e.g., distinguishing Fe²⁺ from Fe³⁺) due to their distinctly different magnetic properties. Changes in mineralogical composition associated with hydrogen generation, such as serpentinization reactions, alter iron oxidation states and hence may be directly identified by magnetic susceptibility measurements. Similarly, EM conductivity measurements may effectively indicate variations in mineralogy and the presence of mineral reaction byproducts, providing valuable radial profiles of mineral reactions occurring around the wellbore.

Acoustic logging methods offer further constraints by measuring acoustic velocity contrasts between unreacted and reacted (“spent”) minerals. Mineral alteration and hydration during hydrogen-generating reactions typically result in measurable shifts in acoustic velocity and impedance. By analyzing acoustic logging data radially from the wellbore outward, distinct zones of reacted versus unreacted minerals may be clearly delineated and characterized.

Nuclear magnetic resonance (NMR) logging techniques additionally provide insights into pore-space characteristics altered by mineral reactions. Changes in pore-size distribution, pore-space geometry, and fluid mobility arising from mineral hydration or hydrogen-generation reactions may be precisely assessed via NMR relaxation-time distributions, enabling the identification and characterization of discrete radial shells of reacted mineralogy.

Further, nuclear logging methods sensitive to bulk density and porosity variations may quantify the porosity changes resulting from mineralogical reactions. Such changes often occur as minerals transition from dense unaltered states to hydrated or reacted mineral products with increased pore space. The integration of nuclear logging to assess porosity and density contrasts thus complements and confirms findings from acoustic, EM, and NMR methods.

By integrating these complementary logging measurements, electromagnetic (including conductivity and magnetic susceptibility), acoustic, NMR, and nuclear porosity logging, reactive contrast-agent-based methodologies become significantly enhanced. The introduction of mineral-reactive components to stimulate mineral reactions can, in themselves, function as mineral-specific contrast agents, creating measurable radial patterns or “tracers” detectable across multiple logging modalities. This multi-modal, integrated example provides a robust, precise, and comprehensive assessment of hydrogen-producing mineralogy, accurately constraining mineral reaction zones, oxidation states, fluid properties, and associated reservoir potential.

These contrast-agent-based methods for hydrogen detection from reactive minerals may be applied at any operational stage, including during drilling, well evaluation, completion, or subsequent intervention phases. In some examples, contrast agents may be designed specifically to react directly with hydrogen-producing minerals, offering a further level of direct mineralogical characterization independent from subsequent hydrogen formation and capture. Thus, these techniques significantly broaden the utility of the reactive contrast-agent example, enabling robust identification and characterization of mineralogical environments capable of generating and preserving molecular hydrogen within subsurface formations.

The techniques comprehensively described herein, originally detailed for molecular hydrogen, hydrogen sulfide and carbon dioxide, and mineral detection, form the basis of a new generalized example. This methodology provides an applicable and robust framework capable of reliably detecting and characterizing a wide range of selectively reactive fluid components within geological reservoirs, thus greatly enhancing subsurface reservoir evaluation and characterization capabilities.

The techniques and examples described herein are readily applicable by one skilled in the art across various operational timelines, including logging conducted before, during, or after drilling operations; before, during, or after the chemical reaction of the reactive contrast agent within the formation; and before, during, or after subsequent cleanup processes. Additionally, injection or placement of the contrast agent into the formation may appropriately occur during active drilling operations, as well as following drilling operations during completion or subsequent intervention phases. As will be recognized by practitioners skilled in subsurface evaluation and well operations, the described methods are broadly flexible, enabling comprehensive characterization and detection of targeted formation-fluid components throughout multiple stages of reservoir assessment and well lifecycle management.

A general example of the invention comprises embedding or placing selectively reactive contrast agents or dormant sensor devices within cement, at cement-formation interfaces, within adjacent formations, or integrated into infrastructure elements, configured to activate upon exposure to a targeted fluid, such as molecular hydrogen. Upon activation, measurable physical or chemical changes occur, generating detectable signals (acoustic, electromagnetic, electrical, pressure, or chemical) that may be remotely monitored via wired, wireless, or indirect field-coupled telemetry systems. These systems enable early detection, localization, and automatic mitigation of fluid leakage, migration, or integrity breaches, thus ensuring enhanced monitoring reliability, asset protection, and operational safety for subsurface reservoirs, wellbores, pipelines, surface infrastructure, and storage facilities. Hydrogen sensitive RFID sensors distributed in cement that report to transceivers mounted on casing

An additional advantageous example involves embedding reactive contrast agents directly within the cement used to isolate wellbore zones or strategically placing these agents behind cemented zones to enable the monitoring of hydrogen (H₂) leakage or migration through or around the cement barrier. Specifically, contrast agents configured to chemically react with molecular hydrogen may be incorporated into cement formulations prior to pumping, resulting in an integrated cement-contrast agent system capable of detecting subsequent hydrogen migration through microcannula, fractures, or porosity within the cement sheath itself. In other examples, contrast agents may be deliberately placed behind the cement, either invaded into the formation or retained in the mud cake adjacent to the formation-cement interface. These agents may be bound or adsorbed onto solid carriers, such as cellulose-based fibers, nanoparticles, or other non-filterable additives, to ensure stable positioning behind the cement, within the mud cake layer, or within the formation.

In this example, the presence or migration of molecular hydrogen through the cement or along the cement-formation interface may be directly monitored through chemical reaction of the embedded or strategically placed contrast agents, producing measurable alterations in local formation and cement properties detectable by standard downhole logging tools (e.g., acoustic, electromagnetic, nuclear, or nuclear magnetic resonance). Such reactive detection allows rapid identification of hydrogen leakage pathways or failures in zonal isolation, providing an early warning indicator of potential reservoir or structural integrity issues. Additionally, by strategically distributing reactive contrast agents in a spatially controlled pattern around the cemented zone, the resulting geometric distribution of activated agents may clearly indicate specific damage patterns within the cement sheath, including microcannula formation, radial or axial fractures, or general cement deterioration. Cement deterioration may also comprise channeling, debonding, de-adhesion, voids, cavities, corrosion induced damage, shear or slip planes, thermal cracking, chemical alteration zones, perf damage, erosion, washout, compaction, or subsidence are included as a damage that could be detected.

Thus, incorporating reactive contrast agents directly within or behind cement barriers provides a dual capability: it enables reliable detection and monitoring of molecular hydrogen migration or leakage, and simultaneously offers a powerful method to assess and verify cement integrity and zonal isolation effectiveness. This other example significantly enhances well-integrity monitoring, early detection of zonal isolation failures, and reservoir management, especially for hydrogen-rich subsurface systems or critical hydrogen storage and production scenarios.

Detection capabilities may be further enhanced through integration of remotely probed sensor technologies, such as radio-frequency identification (RFID) tags or other wireless sensing devices, strategically embedded within the cement, positioned at the cement-formation interface, or placed directly within the formation. Such embedded sensors, when combined with reactive contrast agents, may remotely report the activation of contrast agents triggered by hydrogen gas migration or leakage, thereby enabling continuous or periodic monitoring throughout the well's operational lifetime. This method significantly enhances real-time monitoring of well integrity, ensuring ongoing evaluation of cement effectiveness and proactive detection of hydrogen-induced anomalies or structural changes within cemented zones or isolation barriers.

Additionally, as a monitoring technology, the contrast agents and remotely probed sensors described herein may be advantageously utilized for continuous or periodic surveillance of hydrogen storage within dedicated hydrogen storage wells. By embedding reactive contrast agents within storage well cement barriers, formation interfaces, or reservoir intervals, operators may detect and accurately track the spatial distribution, integrity, and migration of stored hydrogen gas throughout the reservoir lifecycle. The incorporation of remotely probed sensors, such as RFID tags or other wireless sensor systems, further enhances real-time reservoir surveillance by providing continuous, accessible, and actionable data regarding hydrogen containment and integrity. This capability significantly improves the safety, reliability, and operational confidence associated with geological hydrogen storage, facilitating proactive maintenance, early detection of potential leakage or containment breaches, and ensuring effective long-term storage management and environmental protection.

The described monitoring technology, encompassing reactive contrast agents and remotely probed sensors, may be broadly extended beyond hydrogen to effectively monitor other reactive or mobile subsurface fluid components including, but not limited to, carbon dioxide (CO₂), hydrogen sulfide (H₂S), water (H₂O), and specific petroleum constituents. By appropriately selecting and engineering reactive contrast agents for specific chemical affinity with these target substances, the system may reliably detect and quantify the presence, migration, leakage, or unintended movement of these fluids within cemented barriers, formation intervals, or storage reservoirs. Coupled with remotely probed sensor systems such as RFID tags, this extended monitoring example provides continuous and precise evaluation of fluid containment, storage integrity, reservoir performance, and environmental protection across a wide range of subsurface storage, production, or sequestration applications. Sending acoustic transmission along pipe and looking for change in acoustic impedance with time of flight

Monitoring reactive contrast agents and fluid migration may additionally be accomplished through advanced acoustic methods employing pitch-catch or pulse-echo techniques. These acoustic monitoring methods may be configured either in reflective modes, detecting changes in acoustic impedance due to altered density or sonic velocity of reacted zones, or in guided acoustic wave configurations along tubular structures such as casing or pipe. In guided-wave configurations, the presence and spatial distribution of reaction products formed by reactive contrast agents induce measurable changes in sonic velocities or wave propagation characteristics along the pipe or casing, providing highly sensitive, real-time monitoring capabilities. This acoustic example complements the chemical reactivity and remote sensing examples previously described, enabling comprehensive and continuous well-integrity assessment, fluid containment verification, and detection of subsurface fluid migration throughout the operational lifecycle of wells and reservoirs. permanently mounted acoustic sensors that check for changes in acoustic impedance at long-duration set intervals, low power, with means to harvest vibration (from fluid flow in pipe) or maybe the hydrogen that leak to re-charge power.

Permanently mounted acoustic sensors represent a further advantageous example for long-term monitoring of reactive contrast agents and fluid migration. These sensors may be strategically installed along casing or tubular elements to periodically measure changes in acoustic impedance indicative of contrast agent reactions, fluid leakage, or shifts in reservoir properties. Operating at low power and scheduled at extended intervals, these sensors provide a practical solution for continuous, unattended integrity monitoring. To further enhance operational longevity and reduce maintenance, the sensors may incorporate onboard power-harvesting mechanisms that utilize ambient vibrations from fluid flow within the pipe or potentially employ small-scale hydrogen fuel cells to harvest energy directly from hydrogen leaks. These hydrogen harvesting configuration (or methane harvesting configuration) may utilize on board oxidizing agents in order to facilitate the fuel cell reaction. This self-powered, low-maintenance example ensures sustained long-term monitoring capability, facilitating real-time detection and intervention for hydrogen leaks, fluid migration, or changes in cement and reservoir integrity throughout the life of the well or storage facility.

permanently mounted chemical sensors (MEMS, microfluidic, optical, electroscopic, electrophoretic, etc.) that check for changes in pH, minerology, ion concentrations, etc. (any byproducts that may result from escaped hydrogen).

A further example involves the strategic deployment of permanently mounted chemical sensors for sustained long-term monitoring of formation integrity, fluid migration, and contrast-agent reaction byproducts. Such chemical sensors may include microelectromechanical systems (MEMS), microfluidic sensors, optical sensors, electroscopic sensors, electrophoretic sensors, or combinations thereof. These sensors may detect subtle changes in local chemical environments, including variations in pH, mineralogy alterations, shifts in ion concentrations, and the presence of reaction byproducts resulting from interactions between escaped hydrogen or other targeted reservoir fluids and formation materials or reactive contrast agents.

Sensors embedded permanently behind casing, within cement, at formation interfaces, or along tubular structures facilitate continuous, autonomous, and precise monitoring of well and reservoir integrity. For example, escaped hydrogen interacting with reservoir minerals or cement materials may produce distinctive reaction by products detectable as alterations in local pH, ion distribution, or mineralogical composition. The permanently mounted chemical sensors detect and quantify these chemical signatures, providing early warning of reservoir fluid migration, hydrogen leaks, chemical degradation of cement integrity, or other subsurface changes.

The deployment of miniaturized MEMS and microfluidic sensor systems provides distinct advantages due to their low power usage, minimal maintenance, small physical footprint, and high sensitivity. Optical sensors integrated into this monitoring framework may leverage spectroscopy or colorimetric reactions to detect trace changes in chemical composition or mineralogy. Electroscopic or electrophoretic sensors enable direct measurement of ion concentration variations associated with mineral dissolution or precipitation processes resulting from hydrogen-induced chemical reactions.

By integrating these permanently installed chemical sensor technologies, operators gain continuous, high-resolution chemical monitoring capability throughout the operational lifespan of a well or hydrogen-storage reservoir. Such monitoring significantly improves the detection and remediation of leaks, the assessment of long-term cement and reservoir integrity, and overall safety and environmental compliance.

This permanently mounted chemical sensor example is also directly extendable to other reactive fluid components such as carbon dioxide (CO₂), hydrogen sulfide (H₂S), water (H₂O), petroleum-derived compounds, or mineral-specific byproducts. By selecting sensor materials, chemical receptors, or detection methods specifically responsive to these additional reactive components or their reaction byproducts, operators may comprehensively monitor various reservoir fluids or gases. The same MEMS, microfluidic, optical, electroscopic, and electrophoretic sensor platforms may thus be employed, with only minor modifications to the sensing chemistry or detection elements, to create robust monitoring systems for multiple fluid types. This versatility significantly enhances overall reservoir surveillance, operational safety, and environmental management, providing an integrated, multi-fluid example to long-term reservoir monitoring and integrity management. Mounted sensors that power up and then send signal (acoustic, EM, pressure change, etc.) when hydrogen passes over them. Dormant if system has integrity.

An additional advantageous variation involves mounted sensor systems designed to remain dormant and low power under normal operational conditions, activating only upon exposure to molecular hydrogen or other targeted reactive fluids. These sensors power up and transmit detectable signals, such as acoustic pulses, electromagnetic (EM) signals, or measurable pressure changes, only when hydrogen or other monitored fluids come into contact with the sensor elements. Under conditions where system integrity is maintained and no fluid leakage or migration occurs, the sensors remain inactive, conserving energy and reducing operational complexity. Upon detecting hydrogen passage, the sensors immediately activate and send recognizable signals, allowing rapid and unambiguous detection of integrity breaches or fluid migration events. This selective activation methodology enables highly efficient, low-maintenance, long-term monitoring solutions, significantly enhancing early-warning capabilities for hydrogen leaks and other reactive fluid migrations within subsurface storage and well integrity management systems.

Such dormant sensors may further be configured to transmit telemetry signals through various communication methods, including via electrical lines, fiber-optic cables, or wireless remote transmission. In examples utilizing wired communication (electrical or fiber-optic), the sensors need not directly contact the transmission line physically; instead, the activated sensors may alter a local acoustic, electrical, magnetic, or electromagnetic field, causing detectable changes in signals passing through the transmission line. For example, a sensor activated by hydrogen exposure might generate or modify an acoustic or electromagnetic field, causing a measurable perturbation in a guided acoustic pulse or electrical signal traversing a nearby cable, thereby indicating sensor activation without direct physical coupling. In other examples, sensors may also be directly connected into the communication line, enabling direct signal transmission upon activation in some examples. This flexible telemetry example significantly enhances long-term monitoring reliability, operational simplicity, and cost efficiency for reservoir and well-integrity management.

The examples and methodologies described herein may also be advantageously extended to monitoring hydrogen or other reactive components in a broad range of additional infrastructure and equipment, including but not limited to pipelines, subsea risers, surface and downhole equipment, processing facilities, storage tanks, and related assets. By embedding reactive contrast agents or dormant sensors within pipeline coatings, insulation materials, equipment linings, or structural interfaces, operators may continuously or intermittently detect and quantify fluid leaks, corrosion-induced integrity degradation, or unintended fluid migration. Sensors configured for selective activation upon hydrogen exposure or upon detecting other targeted chemical species provide early-warning capabilities for potential equipment failures or leaks, thus significantly enhancing operational safety, environmental protection, and asset-management efficiency. The described telemetry methods, including acoustic, electromagnetic, fiber-optic, or electrical-line-based signal transmission, further facilitate integration into existing infrastructure monitoring and asset-integrity management systems, offering comprehensive, real-time surveillance solutions across a wide array of industrial and petroleum-related applications.

Hydrogen sensors at surface (MEMS, microfluidics, optical, electroscopic, electrophoretic, etc.) to monitor for leakage in combination with automatic control (listed below) to seal or self-heal reservoir. Contrast-agent-enhanced sensing technology at the surface may further incorporate advanced hydrogen sensors, such as microelectromechanical systems (MEMS), microfluidic, optical, electroscopic, electrophoretic, or other miniaturized analytical sensors, strategically positioned around wellheads, pipelines, processing equipment, storage tanks, and surface facilities. These sensors continuously or intermittently monitor ambient conditions, rapidly detecting hydrogen leaks or releases. Coupled directly with automated control systems, surface-based hydrogen sensors may trigger immediate corrective actions, including automated valve closures, activation of sealing mechanisms, or deployment of self-healing reservoir and containment technologies. This integrated detection and automatic response capability significantly reduces the risk of hydrogen leakage incidents, improves operational safety, and maintains reservoir and infrastructure integrity, ensuring rapid, efficient remediation of integrity breaches without requiring manual intervention.

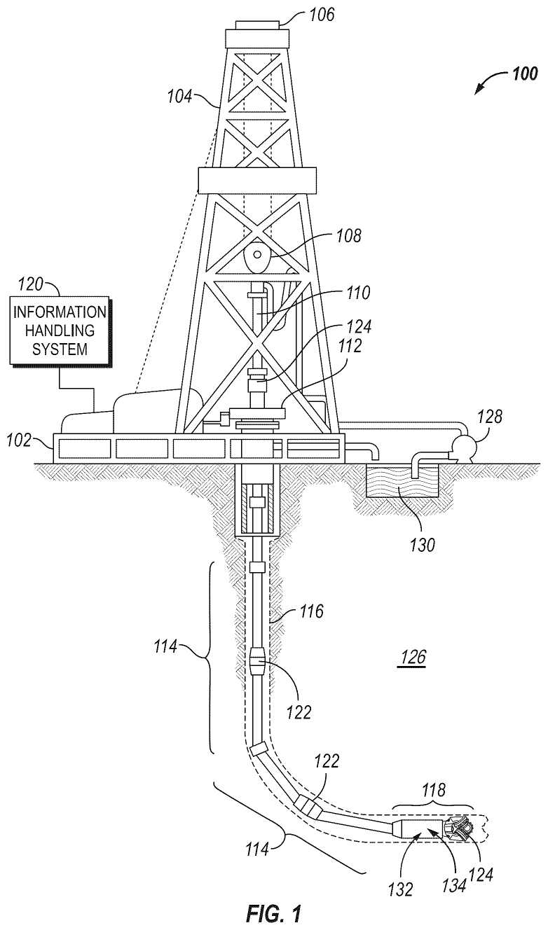

FIGS. 1-4D and 6A-6C illustrate applications of different downhole tools, however, other downhole tools may also be employed, comprising formation testing tools, any tools capable of delivering and/or intaking fluids downhole, or any tools capable of performing measurements. Moreover, these tools may be used in connection with each other or may even be combined within the same tool. As such, a single downhole tool may operate to test formation fluids or acquire cotes or any other fluid, solid, or gas), deliver fluids downhole for any reason comprising reaction-based operations, and/or perform measurements downhole with any measurement operation disclosed herein. In examples, at least one reactive component within the subsurface formation fluid may be targeted to be reacted with by a reactive contrast agent, which is delivered by a downhole tool at a targeted depth downhole. In examples, the least one reactive component within the subsurface formation fluid may Hydrogen, Hydrogen Sulfide, and/or Carbon dioxide, or a combination of thereof. Then any of the logging techniques described herein may analyze the reaction, these logging techniques may comprise any pulsed neutron source, NMR, acoustics, electromagnetics, formation testing comprising formation fluid sampling analysis, core sample analysis, and/or the like. This is an example of a Multiphysics tool and may apply any of the physics and logging operations discussed herein. In addition, the one or more formation logging measurements is on a logging while drilling (LWD) system, wireline system, or a surface data logging (SDL) system. For the reaction, reaction products or byproducts or changes in the at least one reactive component within the subsurface formation fluid with the downhole tool may be yielded. Herein, a hydride-based contrast agents or any other contrast agent may be referred to as a contrast agent composition. Moreover, there may be two or more contrast agent compositions delivered, inserted deposited, introduced, deposited as pills, and/or the like at two or more target depths.

In further examples, the downhole may be configured to embed a contrast agent composition at a first position with the downhole tool, or any number of locations and positions. The contrast agent composition reacts with hydrogen migrating through or around a cement barrier forming one or more reaction products. In addition to cement barriers, other barriers may also be applicable comprising packers or swellable metal alloy. Then, the downhole tool may be configured for performing one or more formation logging measurements capable of detecting one or more reaction products with the downhole tool; and analyzing the one or more formation logging measurements for hydrogen leakage. In examples, the first position is within a cement composition, an interface between the cement and subsurface formation, and/or within a mud cake layer disposed behind a cement sheath.

In examples, the contrast agents within a cement composition allows for detecting hydrogen migration through micro annuli, fractures, or porosity within a cement sheath itself and is bound or adsorbed onto solid carriers comprising cellulose-based fibers, nanoparticles, or a non-filterable additives to ensure stable positioning. The contrast agent composition may be a hydrogen-reactive contrast agent. Moreover, the reaction products comprise measurable changes in at least one property comprising acoustic impedance, electromagnetic response, nuclear response, dielectric properties, nuclear magnetic resonance characteristics, optical properties, thermal properties, pressure, or any measurable property. In further examples, systems and methods disclosed herein may be configured for finding damage patterns within a cement sheath comprising micro annuli formation, radial or axial fractures, or general cement deterioration from the one or more reaction products and performing one or more formation logging measurements of the one or more reaction products with one or more radio-frequency identification (RFID) tags.

FIG. 1 is a diagram of an example drilling environment 100. Drilling environment 100 may comprise platform 102 that supports derrick 104 having a traveling block 108 for raising and lowering top drive 110 and drillstring 114. Top drive 110 supports and rotates drillstring 114 as it is lowered through wellhead 112. In turn, drill bit 124, located at the end of drillstring 114, may create borehole 116. Borehole 116 may be formed through the Earth surface into a subterranean formation 126 in the Earth crust. Bottom-hole assembly 118 may comprise a pulsed neutron logging tool 132 and Nuclear Magnetic Resonance (NMR) tool 134 for logging while drilling operations.

Platform 102 is a structure which may be used to support one or more other components of drilling environment 100 (e.g., derrick 104). Platform 102 may be designed and constructed from suitable materials (e.g., concrete) which are able to withstand the forces applied by other components (e.g., the weight and counterforces experienced by derrick 104). In any example, platform 102 may be constructed to provide a uniform surface for drilling operations in drilling environment 100.

Derrick 104 is a structure which may support, contain, and/or otherwise facilitate the operation of one or more pieces of the drilling equipment. In any example, derrick 104 may provide support for crown block 106, traveling block 108, and/or any part connected to (and including) drillstring 114. Derrick 104 may be constructed from any suitable materials (e.g., steel) to provide the strength necessary to support those components.

Crown block 106 is one or more simple machine(s) which may be rigidly affixed to derrick 104 and comprise a set of pulleys (e.g., a “block”), threaded (e.g., “reeved”) with a drilling line (e.g., a steel cable), to provide mechanical advantage. Crown block 106 may be disposed vertically above traveling block 108, where traveling block 108 is threaded with the same drilling line.

Traveling block 108 is one or more simple machine(s) which may be movably affixed to derrick 104 and comprise a set of pulleys, threaded with a drilling line, to provide mechanical advantage. Traveling block 108 may be disposed vertically below crown block 106, where crown block 106 is threaded with the same drilling line. In any example, traveling block 108 may be mechanically coupled to drillstring 114 (e.g., via top drive 110) and allow for drillstring 114 (and/or any component thereof) to be lifted from (and out of) borehole 116. Both crown block 106 and traveling block 108 may use a series of parallel pulleys (e.g., in a “block and tackle” arrangement) to achieve significant mechanical advantage, allowing for the drillstring to handle greater loads (compared to a configuration that uses non-parallel tension). Traveling block 108 may move vertically (e.g., up, down) within derrick 104 via the extension and retraction of the drilling line.

Top drive 110 is a machine which may be configured to rotate drillstring 114. Top drive 110 may be affixed to traveling block 108 and configured to move vertically within derrick 104 (e.g., along with traveling block 108). In any example, the rotation of drillstring 114 (caused by top drive 110) may allow for drillstring 114 to carve borehole 116. Top drive 110 may use one or more motor(s) and gearing mechanism(s) to cause rotations of drillstring 114. In any example, a rotatory table (not shown) and a “Kelly” drive (not shown) may be used in addition to, or instead of, top drive 110.

Wellhead 112 is a machine which may comprise one or more pipes, caps, and/or valves to provide pressure control for contents within borehole 116 (e.g., when fluidly connected to a well (not shown)). In any example, during drilling, wellhead 112 may be equipped with a blowout preventer (not shown) to prevent the flow of higher-pressure fluids (in borehole 116) from escaping to the surface in an uncontrolled manner. Wellhead 112 may be equipped with other ports and/or sensors to monitor pressures within borehole 116 and/or otherwise facilitate drilling operations.

Drillstring 114 is a machine which may be used to carve borehole 116 and/or gather data from borehole 116 and the surrounding geology. Drillstring 114 may comprise one or more drillpipe(s), one or more repeater(s) 122, and bottom-hole assembly 118. Drillstring 114 may rotate (e.g., via top drive 110) to form and deepen borehole 116 (e.g., via drill bit 124) and/or via one or more motor(s) attached to drillstring 114.

Borehole 116 is a hole in the ground which may be formed by drillstring 114 (and one or more components thereof). Borehole 116 may be partially or fully lined with casing to protect the surrounding ground from the contents of borehole 116, and conversely, to protect borehole 116 from the surrounding ground.

Bottom-hole assembly 118 is a machine which may be equipped with one or more tools for creating, providing structure, and maintaining borehole 116, as well as one or more tools for measuring the surrounding environment (e.g., measurement while drilling (MWD), logging while drilling (LWD)). In any example, bottom-hole assembly 118 may be disposed at (or near) the end of drillstring 114 (e.g., in the most “downhole” portion of borehole 116).

Non-limiting examples of tools that may be comprised in bottom-hole assembly 118 comprise a drill bit (e.g., drill bit 124), casing tools (e.g., a shifting tool), a plugging tool, a mud motor, a drill collar (thick-walled steel pipes that provide weight and rigidity to aid the drilling process), actuators (and pistons attached thereto), a steering system, and any measurement tool (e.g., sensors, probes, particle generators, etc.).

Further, bottom-hole assembly 118 may comprise a telemetry sub to maintain a communications link with the surface (e.g., with information handling system 120). Such telemetry communications may be used for (i) transferring tool measurement data from bottom-hole assembly 118 to surface receivers, and/or (ii) receiving commands (from the surface) to bottom-hole assembly 118 (e.g., for use of one or more tool(s) in bottom-hole assembly 118). In examples, telemetry communications may be at least in part between bottom-hole assembly 118 and information handling system 120.

As illustrated, the information handling system 120 may comprise any instrumentality or aggregate of instrumentalities operable to compute, estimate, classify, process, transmit, broadcast, receive, retrieve, originate, switch, store, display, manifest, detect, record, reproduce, handle, or utilize any form of information, intelligence, or data for business, scientific, control, or other purposes. For example, an information handling system 120 may be a personal computer, a network storage device, or any other suitable device and may vary in size, shape, performance, functionality, and price.

Information handling system 120 may comprise a processing unit (e.g., microprocessor, central processing unit, etc.) that may process drilling data from rotary steerable system (RSS) 242, discussed below, by executing software or instructions obtained from a local non-transitory computer readable media (e.g., optical disks, magnetic disks). The non-transitory computer readable media may store software or instructions of the methods described herein. Non-transitory computer readable media may comprise any instrumentality or aggregation of instrumentalities that may retain data and/or instructions for a period of time. Non-transitory computer readable media may comprise, for example, storage media such as a direct access storage device (e.g., a hard disk drive or floppy disk drive), a sequential access storage device (e.g., a tape disk drive), compact disk, CD-ROM, DVD, RAM, ROM, electrically erasable programmable read-only memory (EEPROM), and/or flash memory; as well as communications media such wires, optical fibers, microwaves, radio waves, and other electromagnetic and/or optical carriers; and/or any combination of the foregoing. Information handling system 120 may also comprise input device(s) (e.g., keyboard, mouse, touchpad, etc.) and output device(s) (e.g., monitor, printer, etc.). The input device(s) and output device(s) provide a user interface that enables an operator to interact with any device disposed or a part of bottom-hole assembly 118, discussed below, and/or software executed by a processing unit. For example, information handling system 120 may enable an operator to select analysis options, view collected log data, view analysis results, and/or perform other tasks.

Non-limiting examples of techniques for transferring tool measurement data (to the surface) comprise mud pulse telemetry and through-wall acoustic signaling. For through-wall acoustic signaling, one or more repeater(s) 122 may detect, amplify, and re-transmit signals from bottom-hole assembly 118 to the surface (e.g., to information handling system 120), and conversely, from the surface (e.g., from information handling system 120) to bottom-hole assembly 118.

Repeater 122 is a device which may be used to receive and send signals from one component of drilling environment 100 to another component of drilling environment 100. As a non-limiting example, repeater 122 may be used to receive a signal from a tool on bottom-hole assembly 118 and send that signal to information handling system 120. Two or more repeaters 122 may be used together, in series, such that a signal to/from bottom-hole assembly 118 may be relayed through two or more repeaters 122 before reaching its destination.

A transducer is a device that may work with repeater 122 to transfer information from the surface to bottom-hole assembly 118. A transducer may be configured to convert non-digital data (e.g., vibrations, other analog data) into a digital form suitable for information handling system 120. As a non-limiting example, the one or more transducer(s) may convert signals between mechanical and electrical forms, enabling information handling system 120 to receive the signals from a telemetry sub, on bottom-hole assembly 118, and conversely, transmit a downlink signal to the telemetry sub on bottom-hole assembly 118. In any example, the transducer may be located at the surface and/or any part of drillstring 114 (e.g., as part of bottom-hole assembly 118).

Drill bit 124 is a machine which may be used to cut through, scrape, and/or crush (i.e., break apart) materials in the ground (e.g., rocks, dirt, clay, etc.). Drill bit 124 may be disposed at the frontmost point of drillstring 114 and bottom-hole assembly 118. In any example, drill bit 124 may comprise one or more cutting edges (e.g., hardened metal points, surfaces, blades, protrusions, etc.) to form a geometry which aids in breaking ground materials loose and further crushing that material into smaller sizes. In any example, drill bit 124 may be rotated and forced into (i.e., pushed against) the ground material to cause the cutting, scraping, and crushing action. The rotations of drill bit 124 may be caused by top drive 110 and/or one or more motor(s) located on drillstring 114 (e.g., on bottom-hole assembly 118).

Pump 128 is a machine that may be used to circulate drilling fluid 130 from a reservoir, through a feed pipe, to derrick 104, to the interior of drillstring 114, out through drill bit 124 (through orifices, not shown), back upward through borehole 116 (around drillstring 114), and back into the reservoir. In any example, any appropriate pump 128 may be used (e.g., centrifugal, gear, etc.) which is powered by any suitable means (e.g., electricity, combustible fuel, etc.).

Drilling fluid 130 is a liquid which may be pumped through drillstring 114 and borehole 116 to collect drill cuttings, debris, and/or other ground material from the end of borehole 116 (e.g., the volume most recently hollowed by drill bit 124). Further, drilling fluid 130 may provide conductive cooling to drill bit 124 (and/or bottom-hole assembly 118). In any example, drilling fluid 130 may be circulated via pump 128 and filtered to remove unwanted debris.

During drilling operations, bottom-hole assembly may comprise, at least in part, a pulsed neutron logging tool 132 and NMR tool 134. This may allow for logging while drilling operations to be performed. Measurements taken by pulsed neutron logging tool 132 and NMR tool 134 may be gathered and/or processed by information handling system 120. For example, measurements taken by pulsed neutron logging tool 132 and NMR tool 134 may be sent to information handling system 120 where they may be stored on memory and then processed. The processing may be performed real-time during data acquisition or after recovery of pulsed neutron logging tool 132 and NMR tool 134. Processing may in other examples occur downhole on an information handling system disposed on and/or near pulsed neutron logging tool 132 and NMR tool 134 or may occur both downhole and at surface. Information handling system 120 may process the signals, and the information contained therein may be displayed for an operator to observe and stored for future processing and reference. Information handling system 120 may also contain an apparatus for supplying control signals and power to pulsed neutron logging tool 132 and NMR tool 134. Although illustrated as disposed on bottom-hole assembly 118 in a drilling operation, pulsed neutron logging tool 132 and NMR tool 134 may also be disposed in borehole 116 in a wireline operation.

Moreover, drilling environment 100 may include hardware and other components (not illustrated) as well as an interface with information handling system 120 for surface data logging. Surface Data Logging (SDL) techniques, while valuable for providing real-time analysis of gases from subsurface formations, face inherent limitations when directly detecting molecular diatomic hydrogen (H₂). One critical limitation arises from interactions between hydrogen and components of drilling mud systems. Specifically, many conventional mud systems include additives or naturally occurring components that react chemically with hydrogen, consuming it before accurate detection at the surface is possible. This chemical consumption of hydrogen may lead to significant underestimation or complete absence of detectable H₂ signals at the surface, thereby complicating or hindering the direct identification of naturally occurring hydrogen reservoirs.

To mitigate these issues, drilling mud systems may be specifically engineered or modified to minimize or prevent the consumption of molecular hydrogen. For instance, mud systems commonly include oxygen scavengers intended to reduce oxidative corrosion in drilling equipment. However, many standard oxygen scavengers (e.g., sulfite-based compounds) may inadvertently consume hydrogen gas as well. Selecting oxygen scavengers or additives specifically formulated to be non-reactive towards molecular hydrogen may help preserve hydrogen integrity during its ascent from formation to surface. Additionally, engineering mud systems with inert or chemically passive components, such as polymers or synthetic base fluids that do not chemically interact with diatomic hydrogen, may also help maintain the original hydrogen concentrations within samples obtained at surface logging units.

Such specialized mud formulations may substantially enhance the reliability and representativeness of SDL techniques, enabling more accurate assessment of subsurface hydrogen occurrences. Maintaining the integrity of hydrogen concentrations during transport to the surface improves the fidelity of surface-based gas chromatography and isotopic analyses, aiding in effective prospecting and reservoir characterization of natural hydrogen resources.

Isotopic analysis of hydrogen (H₂) or its reaction byproducts may provide critical insights into the origin of molecular hydrogen within subsurface reservoirs. Naturally occurring hydrogen typically exhibits distinct isotopic signatures, which vary based on the mechanisms responsible for its formation. For example, hydrogen generated through geological serpentinization processes, where ultramafic rocks interact with water, often displays characteristic isotopic ratios distinctly different from hydrogen produced radiogenically through radioactive decay or other subsurface geochemical reactions.

Analyzing these isotopic signatures at the surface or from downhole samples allows differentiation between hydrogen produced by abiotic geological reactions, microbial activities, or radiogenic pathways. Specifically, isotopic ratios such as 82H (deuterium/hydrogen ratio) and 813C (in associated hydrocarbons or carbonate species influenced by hydrogen reactions) may serve as diagnostic indicators. These analyses may be performed directly on collected H₂ samples or indirectly by evaluating isotopic shifts in minerals, gases, or fluids that have chemically interacted with hydrogen, thereby providing indirect evidence of the hydrogen formation processes.

Such isotopic characterization aids in refining exploration strategies by improving the understanding of hydrogen generation mechanisms, reservoir recharge potential, and long-term sustainability. Consequently, isotopic analyses enhance the geological interpretation and economic assessment of naturally occurring hydrogen reservoirs identified by multiphysics logging techniques as described herein.

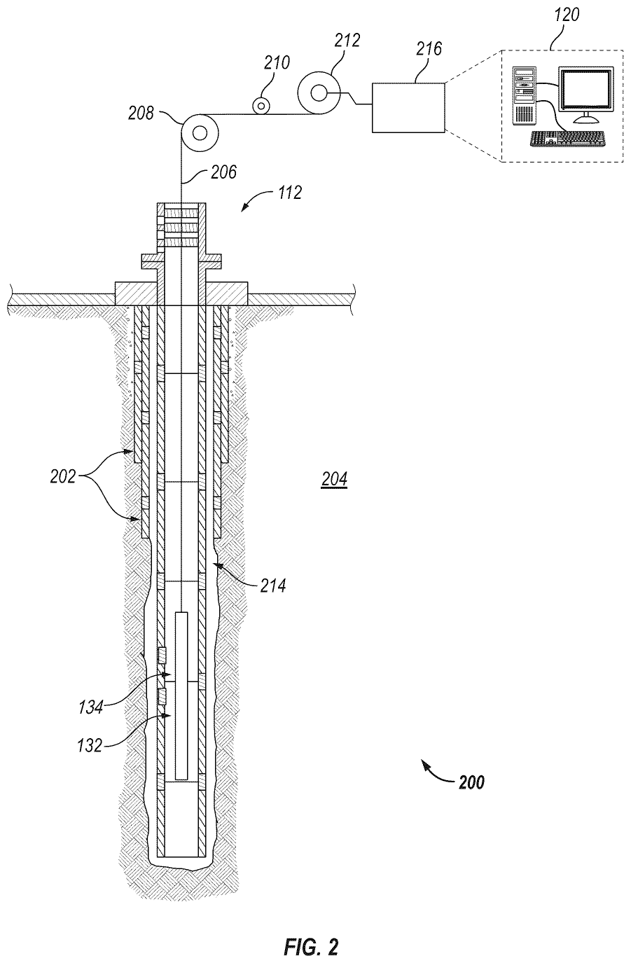

FIG. 2 illustrates a wireline operation 200, as disclosed herein, utilizing a pulsed neutron logging tool 132 and NMR tool 134. Further, FIG. 2 illustrates a cross-section of borehole 116 with a pulsed neutron logging tool 132 traveling through casing string 202. Borehole 116 may traverse through subterranean formation 204 as a vertical well and/or a horizontal well. Pulsed neutron logging tool 132 and NMR tool 134 may be suspended by a conveyance 206, which communicates power from a logging facility 216 to pulsed neutron logging tool 132 and NMR tool 134, further communicating telemetry from pulsed neutron logging tool 132 and NMR tool 134 to information handling system 120. In examples, pulsed neutron logging tool 132 and NMR tool 134 may be operatively coupled to a conveyance 206 (e.g., wireline, slickline, coiled tubing, pipe, downhole tractor, and/or the like) which may provide mechanical suspension, as well as electrical connectivity, for pulsed neutron logging tool 132 and NMR tool 134. Conveyance 206 and pulsed neutron logging tool 132 and NMR tool 134 may extend within casing string 202 to a depth within borehole 116. Conveyance 206, which may comprise one or more electrical conductors, may exit wellhead 112, may pass around pulley 208, may engage odometer 210, and may be reeled onto winch 212, which may be employed to raise and lower the tool assembly in borehole 116. Wellhead 112 may allow for entry into borehole 116 and placement of pulsed neutron logging tool 132 into pipe string 214. The position of pulsed neutron logging tool 132 and NMR tool 134 may be monitored in a number of ways, including an inertial tracker in pulsed neutron logging tool 132 and NMR tool 134 and a paid-out conveyance length monitor in logging facility 216.

Multiple such measurements may be desirable to enable the system to compensate for varying cable tension and cable stretch due to other factors. Information handling system 120 in logging facility 216 collects telemetry and position measurements and provides position-dependent logs of measurements from pulsed neutron logging tool 132 and values that may be derived therefrom.

Pulsed neutron logging tool 132 and NMR tool 134 generally comprise multiple instruments for measuring a variety of downhole parameters. Wheels, bow springs, fins, pads, or other centralizing mechanisms may be employed to keep pulsed neutron logging tool 132 and NMR tool 134 near the borehole axis during measurement operations. During measurement operations, generally, measurements may be performed as pulsed neutron logging tool 132 and NMR tool 134 is drawn up hole at a constant rate. The parameters and instruments may vary depending on the needs of the measurement operation.

Measurements taken by pulsed neutron logging tool 132 and NMR tool 134 may be gathered and/or processed by information handling system 120. For example, signals recorded by pulsed neutron logging tool 132 and NMR tool 134 may be sent to information handling system 120 where they may be stored on memory and then processed. The processing may be performed real-time during data acquisition or after recovery of pulsed neutron logging tool 132 and NMR tool 134. Processing may in other examples occur downhole on an information handling system disposed on pulsed neutron logging tool 132 and NMR tool 134 or may occur both downhole and at surface. In some examples, signals recorded by pulsed neutron logging tool 132 and NMR tool 134 may be conducted to information handling system 120 by way of conveyance 206. Information handling system 120 may process the signals, and the information contained therein may be displayed for an operator to observe and stored for future processing and reference. Information handling system 120 may also contain an apparatus for supplying control signals and power to pulsed neutron logging tool 132 and NMR tool 134.

In wireline operations 200, a digital telemetry system may be employed, wherein an electrical circuit may be used to both supply power to pulsed neutron logging tool 132 and NMR tool 134 and to transfer data between information handling system 120 and pulsed neutron logging tool 132 and NMR tool 134. A DC voltage may be provided to pulsed neutron logging tool 132 and NMR tool 134 by a power supply located above ground level, and data may be coupled to the DC power conductor by a baseband current pulse system. In other examples, pulsed neutron logging tool 132 and NMR tool 134 may be powered by batteries located within the downhole tool assembly, and/or the data provided by pulsed neutron logging tool 132 and NMR tool 134 may be stored within the downhole tool assembly, rather than transmitted to the surface during logging.

In both 100 and 200 . . . . Beyond routine tool calibration and verification, laboratory analyses of rock core and reservoir fluid samples obtained directly from the target reservoir interval play a pivotal role in fine-tuning multiphysics logging responses for site-specific conditions. Because laboratory measurements provide direct and quantitative benchmarks of hydrogen content, isotopic signatures, mineralogical composition, petrophysical properties, and fluid-rock interactions, these data are invaluable for refining and calibrating field logging interpretations, reducing uncertainty, and enhancing predictive reservoir characterization.

Multiphysics logging responses to molecular hydrogen vary according to reservoir-specific geological and geochemical contexts. Laboratory measurements of reservoir cores and fluid samples allow precise characterization of hydrogen content, isotopic signatures, fluid composition, and petrophysical properties, thus providing definitive references against which logging-derived data may be rigorously calibrated and fine-tuned. Direct laboratory characterization, including measurements of neutron absorption, gamma-ray emission spectra, acoustic velocities, NMR relaxation times, permeability, porosity, and mineralogy, permits field-specific adjustments to tool responses, environmental corrections, and inversion parameters, resulting in more accurate and reliable multiphysics interpretations.

To achieve meaningful calibration data, careful and systematic core sampling is essential. Proper coring procedures may utilize selecting representative intervals within reservoir zones and adjacent sealing units or cap rocks. Continuous or oriented cores are preferred, as these provide comprehensive geological context, maintain structural integrity, and minimize sampling bias. Upon recovery, core samples must be quickly stabilized and preserved to prevent alteration or fluid evaporation, ideally sealed immediately in airtight canisters with inert atmospheres or specialized sealing materials designed to retain molecular hydrogen and other volatile components. Cores intended for hydrogen analysis may implement minimal exposure to atmospheric conditions and prompt transfer to laboratory facilities for immediate analysis or carefully managed storage conditions (e.g., controlled temperature and pressure).

Once at the laboratory, detailed core analysis may include measurements of bulk density, porosity, permeability, neutron moderation characteristics, gamma-ray spectroscopy, acoustic velocity, and mineralogy through methods such as X-ray diffraction (XRD), CT scanning, and specialized laboratory logging techniques. Core plug samples provide direct, field-specific measurements of permeability, porosity, capillary pressure, and fluid mobility, data essential for calibrating and interpreting NMR and acoustic logging datasets. Furthermore, laboratory nuclear logging simulations, neutron moderation experiments, or acoustic velocity tests performed on core samples directly validate and fine-tune field logging responses, ensuring precise, reservoir-specific logging interpretations.

Fluid sampling from reservoir intervals using formation testers is equally critical. Obtaining accurate fluid samples may implement tools specifically configured to capture and preserve molecular hydrogen without contamination or chemical alteration. This includes minimizing elastomeric components prone to hydrogen absorption and preferentially employing metal-to-metal seals or hydrogen-resistant coatings (such as silicon oxide or aluminum oxide thin films) on sampling chambers and tool surfaces. Small-volume (micro-volume) samples, sufficient for hydrogen detection through high-precision laboratory analysis techniques such as mass spectrometry or isotopic analyses, are highly effective for minimizing contamination risks and maintaining hydrogen integrity.

Upon collection, fluid samples must be transferred into sealed, inert, high-pressure sample containers designed to prevent hydrogen diffusion or chemical interaction. Containers constructed of hydrogen-inert materials (such as stainless steel or titanium alloys with specialized coatings) ensure fluid composition stability during transport to laboratory facilities. Rapid transfer to laboratories allows accurate characterization of fluid composition, isotopic signatures, gas density, viscosity, and phase behavior. These laboratory analyses serve as essential ground-truth datasets for calibrating fluid-sensitive logging tools such as NMR, neutron logging, and acoustic logging, enabling accurate modeling of hydrogen saturation, fluid mobility, and reservoir fluid distributions.

Utilizing laboratory-derived core and fluid datasets, logging tool calibration may be precisely adjusted for the specific geological, geochemical, and petrophysical characteristics of each field. Calibration adjustments informed by laboratory neutron moderation measurements, acoustic velocity data, NMR relaxation behavior, and precise fluid compositions enhance logging measurement accuracy, sensitivity, and interpretability. For example, laboratory-measured neutron moderation rates or hydrogen indices obtained from core samples directly refine neutron logging calibration. Similarly, laboratory-measured acoustic velocities and impedances from cores accurately adjust acoustic logging responses to field conditions, particularly critical for hydrogen-bearing formations due to hydrogen's distinct acoustic properties.

NMR logging tool calibration also strongly benefits from laboratory fluid characterization. Precise measurement of hydrogen relaxation times, fluid viscosities, and pore-size distributions from laboratory NMR experiments ensures accurate selection of field NMR pulse sequences, echo spacing, and data interpretation methods tailored specifically to the reservoir conditions encountered.

Integration of rigorous core and fluid sampling and laboratory calibration procedures into routine operational workflows may implement proactive planning. Pre-drill sampling strategies, clearly defined core handling and preservation protocols, rapid fluid-sample collection, and systematic laboratory analysis scheduling must be standard practice for hydrogen reservoir characterization efforts. Detailed documentation and continuous communication between field operators, logging specialists, and laboratory analysts enable rapid, iterative adjustments to field logging methods based on laboratory feedback, maximizing logging accuracy and interpretative confidence.

In summary, proper core and fluid sampling procedures, combined with laboratory analyses, are indispensable for fine-tuning logging tool calibrations and reducing measurement uncertainty specific to hydrogen-bearing formations. By rigorously integrating laboratory-derived calibration data into multiphysics logging workflows, reservoir-specific logging interpretations become significantly more accurate, predictive, and operationally reliable, greatly enhancing reservoir assessment quality and long-term hydrogen reservoir management.

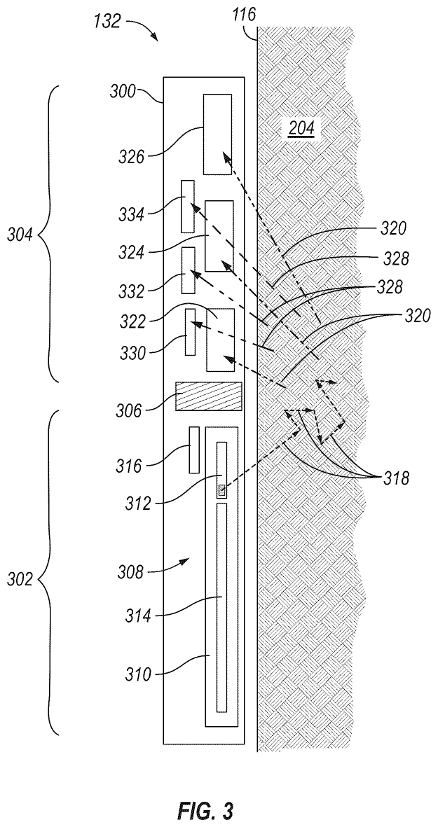

FIG. 3 illustrates pulsed neutron logging tool 132 disposed in borehole 116. It should be noted, as discussed above, that pulsed neutron logging tool 132 may be disposed on a bottom-hole assembly 118 (e.g., referring to FIG. 1) in a logging while drilling operation or utilized in a wireline operation (e.g., referring to FIG. 2). Additionally, the orientation of pulsed neutron logging tool 132, whether the generator is disposed above or below the detectors, is inconsequential.

With continued reference to FIG. 3, pulsed neutron logging tool 132 may comprise an outer housing 300 which may be formed from a heavy metal such as steel, Inconel, etc. Housing 300 may protect the internal devices of pulsed neutron logging tool 132 from the downhole environment that pulsed neutron logging tool 132 may experience in borehole 116. As illustrated, pulsed neutron logging tool 132 may be divided into a generation area 302 and a detection area 304 that are separated by shielding 306. From generation area 302, neutrons may be generated and broadcast into formation 204 (referring to FIG. 2). Detection area 304 may be operated and function to detect gamma rays that may originate from formation 204 naturally or induced by the broadcast of neutrons into formation 204.

Generation area 302 may comprise a pulsed neutron generator 308 that may be packaged within SF₆ housing 310. SF₆ housing 310 may be comprised of a heavy metal like stainless steel, etc. As noted above, within SF₆ housing 310 may be a pulsed neutron generator 308 that may comprise a neutron tube 312, which generates neutrons for broadcasting, and a high voltage (HV) ladder power supply 314 that may be utilized to power neutron tube 312. In other examples, pulsed neutron generator 308 may be replaced with a continuous neutron source such as Americium-Beryllium (Am—Be) chemical source. Outside of SF₆ housing 310 may be a fast neutron monitor 316, that may be utilized to monitor the broadcasting of neutrons 318 from generation area 302 into formation 204. For example, during operations pulsed neutron logging tool 132 may generate pulses of high energy neutrons that radiate from pulsed neutron generator 308 into the surrounding environment including borehole 116 and formation 204. The highly energetic neutrons 318 entering the surrounding environment interact with atomic nuclei, inducing gamma ray radiation. Induced inelastic and capture gamma rays 320 and thermal neutrons 328 may be sensed and recorded by detection area 304. The scattered neutrons and gamma ray spectrum may be measured to determine properties of borehole 116 and formation 204. Through processing, the measurements may be utilized to identify oil and gas in formation 204 as well as determining the flow in production wells. As illustrated, neutrons 318 may be broadcasted into formation 204, wherein neutrons 318 may interact with material within formation 204 to create inelastic and capture gamma rays 320, discussed in greater detail below. Inelastic and capture gamma rays 320 may be detected, sensed, and/or measured by devices within detection area 304 of pulsed neutron logging tool 132.

Detection area 304 may comprise a number of devices that may be utilized to detect, sense, and/or measure inelastic and capture gamma rays 320. As illustrated, a number of gamma ray scintillator detectors may be utilized, which implement a scintillation crystal coupled to a photomultiplier tube. In examples, gamma ray scintillator detectors may be identified as a near gamma ray scintillator detector 322, a far gamma ray scintillator detector 324, and a long gamma ray scintillator detector 326. Identification of each scintillator detector as near, far, and long is due to the distance from neutron generator 308. For example, the closest scintillator detector to neutron generator 308 is “near,” the second closest is “far”, and the third closest is “long.” This nomenclature may also be utilized for thermal neutron detectors that may also be disposed within detection area 304 and may operate and function to detect thermal neutrons 328 that may originate from formation 204 during the interaction of neutrons 318 with material within formation 204. For example, neutron detectors may operate and function to count thermal (around about 0.025 eV) and/or epithermal (between about 0.1 eV and 100 eV) neutrons. Suitable neutron detectors comprise Helium-3 (He-3) filled proportional counters, though other neutron counters may also be used. Thus, within detection area 304 may be a near thermal neutron detector 330, a far thermal neutron detector 332, and a long thermal neutron detector 334. As noted above, detection area 304 may be separated from generation area 302 by shielding 306.

Shielding 306 may be a structure formed of a heavy metal like tungsten. This material may operate and function to prevent neutrons 318 that may be generated from pulsed neutron generator 308 from being detected by the detectors in detection area 304. Without shielding 306, neutrons 318 generated from pulsed neutron generator 308 may saturate all detectors within detection area 304 and prevent the detection and measurement of gamma rays and neutrons from formation 204.

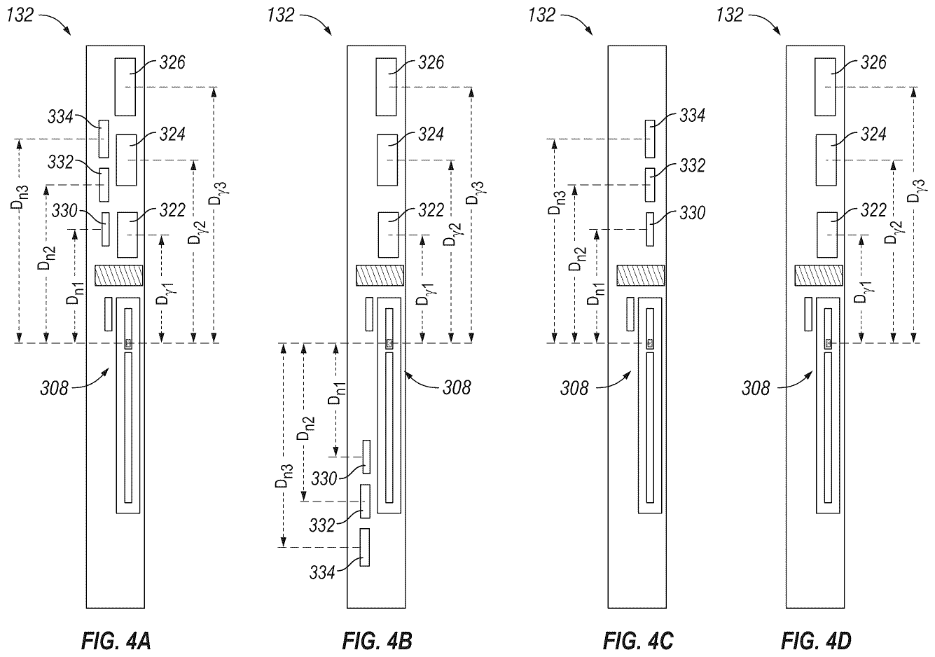

FIGS. 4A-4D illustrate different examples of pulsed neutron logging tool 132. FIG. 4A illustrates an example shown in FIG. 3. In this example, the distance from pulsed neutron generator 308 to near thermal neutron detector 330 is Dₙ₁, to far thermal neutron detector 332 is Dₙ₂, and to long thermal neutron detector 334 is Dₙ₃. Further, the distance from pulsed neutron generator 308 to near gamma ray scintillator detector 322 is D_{γ1}, a far gamma ray scintillator detector 324 is D_{γ2}, and a long gamma ray scintillator detector 326 is D_{γ3}. FIG. 4B illustrates another example in which the distances Dₙ₁, Dₙ₂, Dₙ₃ from pulsed neutron generator 308 to each thermal neutron detector 330, 332, 334 have changed as each thermal neutron detector is now disposed within generation area 302. FIG. 4C illustrates an example where only thermal neutron detectors 330, 332, 334 with distances Dₙ₁, Dₙ₂, Dₙ₃ are utilized and FIG. 4D illustrates an example where only gamma ray scintillator detectors 332, 324, and 326 distances D_{γ1}, D_{γ2}, D_{γ3} are utilized.

Multiple detectors of pulsed neutron logging tool 132, may enable pulsed neutron logging tool 132 to measure properties of formation 204 and borehole 116 (e.g., referring to FIG. 3) using any of the existing multiple-spacing techniques. In addition, the presence of gamma ray detectors which have proper distances from pulsed neutron generator 308, may enable the measurement of elemental gamma ray spectroscopy.

As discussed above, during measurement operations, neutrons 318 (e.g., referring to FIG. 3) emitted from neutron source or pulsed neutron generator 308 undergo neutron scattering and/or nuclear absorption when interacting with matter. Scattering may either be elastic (n, n) or inelastic (n, n′). In an elastic interaction a fraction of the neutrons kinetic energy is transferred to the nucleus. An inelastic interaction is similar, except the nucleus undergoes an internal rearrangement. Additionally, neutrons may also undergo an absorption interaction. During interactions, the elastic cross section is nearly constant, whereas the inelastic scattering cross section and absorption cross sections are proportional to the reciprocal of the neutron speed. For example, inelastic scatterings appear for fast neutrons in the MeV energy range, whereas absorptions happen when neutrons slowed down in the eV energy range.

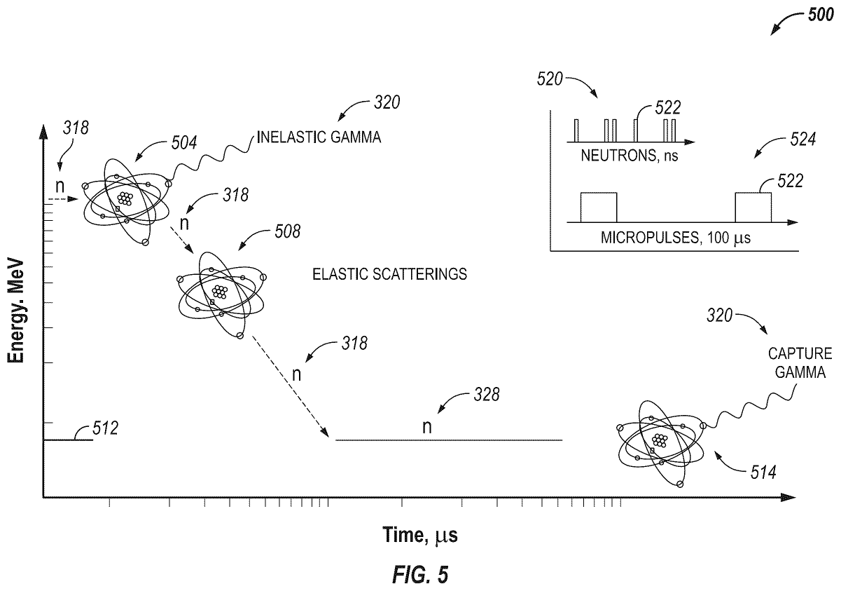

FIG. 5 illustrates a graph 500 that depicts different scattering by a neutron 318. As illustrated, neutron 318 may be traveling at a fast speed with high kinetic energy and interacts with nuclei 504, releasing inelastic gamma ray 320 and lowering the energy state of neutron 318. After the interaction, neutron 318 contains too much energy to be absorbed, thus continuing its path until it interacts with nuclei 508 releasing inelastic gamma ray 320 and again lowering its energy state again. After the interaction, neutron 318 has kinetic energy close to target energy 512, becomes a thermal neutron 328. Thus, when neutron 328 at target energy 512 interacts with nuclei 514 it will be captured. This interaction results in nuclei 514 being rearranged to contain previously traveling neutron 328 and an emitted capture gamma ray 320. Sensing these events with pulsed neutron logging tool 132 using detection area 304 may allow for the identification of oil, gas, and/or water in borehole 116 and formation 204 (e.g., referring to FIG. 3).

With continued reference to FIG. 5, the neutron to gamma ray timing information may be utilized during measurement operations in which a pulsing neutron generator is utilized. In a sub-μs time domain, inelastic gamma rays dominate, whereas in a 10-1000 μs time range, there are only capture gamma rays. Insert 520 on FIG. 5 illustrates an example of neutrons in a neutron pulse 522 and insert 524 shows the relationship of two adjacent neutron pulses 522 with a given pulse width and timing interval. Pulsing schemes allow isolation of inelastic and capture gamma rays 320 and then allow elemental determinations of different nuclei in the bore hole, formation, or fluids.

During measurement operations, pulsed neutron logging tool 132 may take any number of measurements of inelastic and capture gamma rays 320 and/or thermal neutrons 328 (e.g., referring to FIG. 3). These measurements may be further processed by additional methods and systems that may utilize information handling system 120, discussed below.

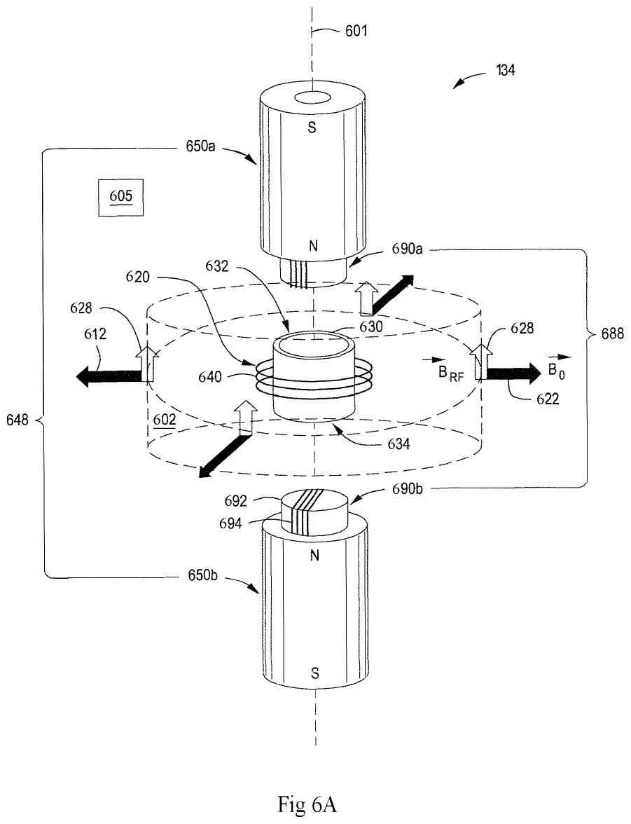

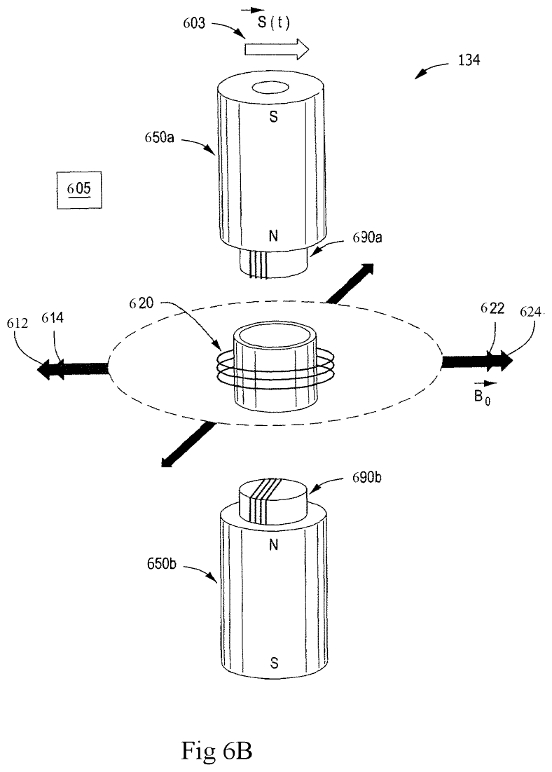

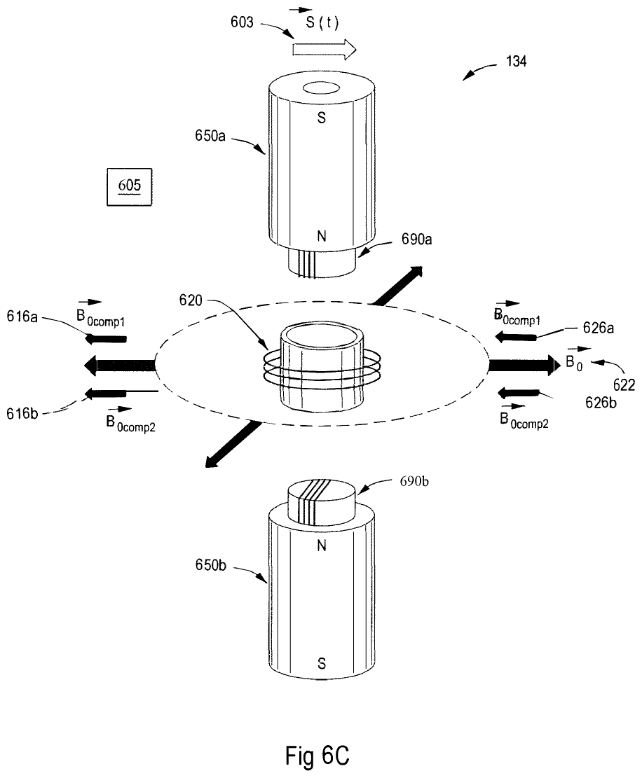

FIGS. 6A-6C depict schematic views of NMR tool 134 at different intervals of use in accordance with one or more implementations. The NMR tool 134 comprises, but is not limited to, one or more antenna assemblies 620, one or more magnet assemblies 648, and one or more compensating assemblies 688. FIG. 6A depicts the NMR tool 134 having no lateral movement, the antenna assembly 620 and the magnet assembly 648 activated and generating magnetic fields, and the compensating assembly 688 inactivated and not generating a magnetic field.

The antenna assembly 620 comprises one or more antenna windings 640 at least partially or completely wound, disposed, or positioned circumferentially around a soft magnetic core 630 (e.g., three antenna windings 640 are depicted in FIGS. 6A-6C). The soft magnetic core 630 may contain one, two, or more permanent magnets positioned therein (not shown). The soft magnetic core 630 comprises an upper axial end 632 opposite a lower axial end 634. The upper and lower axial ends 632, 634 are axially aligned about a common axis 601 of NMR tool 134.

Magnet assembly 648 comprises at least two end magnets, such as an upper end magnet 650a and a lower end magnet 650b. The upper end magnet 650a is spaced apart from the upper axial end 632 of the soft magnetic core 630 and is axially aligned about the common axis 601. The lower end magnet 650b is spaced apart from the lower axial end 634 of the soft magnetic core 630 and is axially aligned about the common axis 601. The north poles of the end magnets 650a, 650b are facing toward the antenna assembly 620, as depicted in FIGS. 6A-6C. The antenna assembly 620 and the magnet assembly 648 produce or generate a static magnetic field (represented by arrows 612, 622) and a radio-frequency magnetic field (represented by arrows 628) within a volume 602 (e.g., volume of investigation) in a subterranean region.

The compensating assembly 688 comprises an upper compensating electromagnet 690a and a lower compensating electromagnet 690b. The upper electromagnet 690a is located between the upper end magnet 650a and the upper axial end 632 of the soft magnetic core 630 and axially aligned about the common axis 601. The lower electromagnet 690b is located between the lower end magnet 650b and the lower axial end 634 of the soft magnetic core 630 and axially aligned about the common axis 601.

Each of the upper electromagnet 690a and the lower electromagnet 690b comprises one or more magnetic cores 692 and one, two, or more windings 694. The magnetic core 692 may be or contain a soft magnetic core. The windings 694 are at least partially or completely wound, disposed, or positioned around the magnetic core 692. For example, the windings 694 are wound around the upper, lower, and side surfaces of the magnetic core 692. Each of the windings 694 may be or comprise a single winding (as depicted in FIGS. 6A-6C), a two-section winding, two orthogonal, two-section windings, or have other winding configurations. For example, a compensating electromagnet 690 (also referred to as a compensating time varying dipole) comprises a plurality of windings 694 at least partially or completely wound around the magnetic core 692 may be used in the NMR tool 134.

Nuclear Magnetic Resonance (NMR) logging offers additional, highly sensitive means of detecting the uniquely tailored porosity and permeability distribution created by the metal hydride contrast-agent network. By carefully adjusting particle size distributions, alloy compositions, and incorporating inert additives, the resultant hydride network may produce distinctively characteristic pore-size distributions, thereby creating NMR T2 relaxation time signatures that differ significantly from the unaltered formation. These engineered distributions of porosity and permeability result in specific and reproducible NMR response patterns, enabling robust differentiation of reacted hydride regions from surrounding reservoir formations. Since NMR detects signals as a “Shell” around the wellbore, this method may be uniquely well suited to detect the presence of the hydride networks in the shell like pattern around the wellbore.

Furthermore, the hydrogen atoms chemically bound within the metal hydride structures provide an inherently distinctive NMR response compared to other hydrogen-bearing species present within typical reservoir environments, such as liquid water, gaseous hydrogen, methane, or hydrocarbons. Specifically, hydrogen nuclei strongly bound in a mineral-like hydride lattice typically exhibit notably shorter T2 relaxation times compared to free or loosely bound hydrogen in formation fluids or hydrocarbons. In reservoirs lacking significant clay-bound water, which typically complicates short T2 signal interpretation, this mineral-bound hydrogen within metal hydride frameworks generates a uniquely distinguishable and diagnostic NMR signal. This clear differentiation significantly enhances the capability of NMR logging methods to detect and characterize molecular hydrogen accumulations, offering both high specificity and improved reliability of subsurface hydrogen detection.

The creation of an interconnected metallic hydride network around the borehole substantially modifies the acoustic properties of the near-wellbore formation. Specifically, the dense, interlocked hydride framework significantly increases the acoustic velocity and acoustic impedance relative to the native reservoir rock, fluids, and original suspension slurry. The resultant formation alteration thus produces a clearly defined cylindrical or oblong-shaped zone characterized by elevated acoustic velocities and distinct acoustic impedance contrasts. This acoustic impedance boundary creates measurable reflections and reverberations detectable by conventional acoustic logging tools.

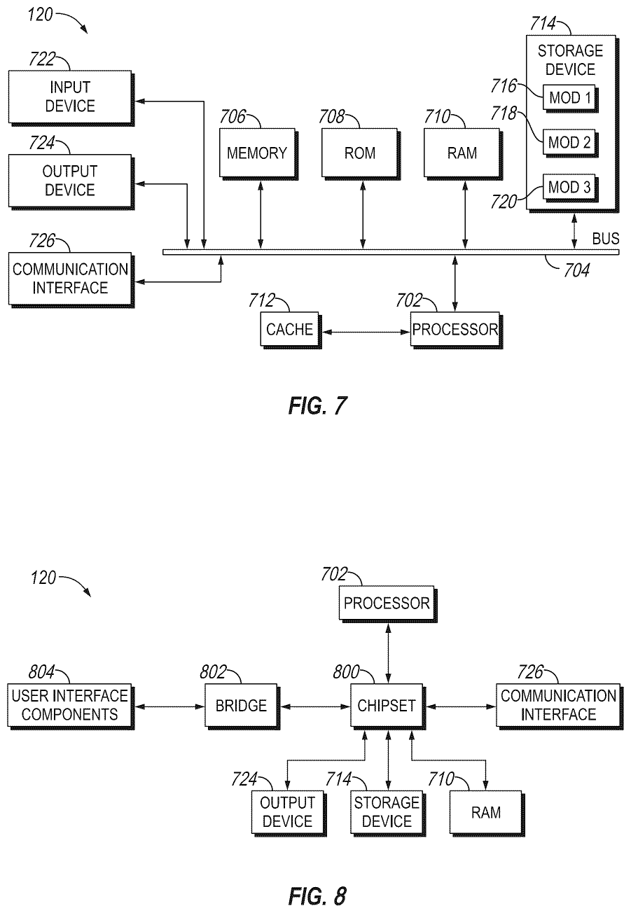

FIG. 7 further illustrates an example of an information handling system 120 which may be employed to perform various steps, methods, and techniques disclosed herein. Persons of ordinary skill in the art will readily appreciate that other system examples are possible. As illustrated, information handling system 120 comprises a processing unit (CPU or processor) 702 and a system bus 704 that couples various system components including system memory 706 such as read only memory (ROM) 708 and random-access memory (RAM) 710 to processor 702.

Processors disclosed herein may all be forms of this processor 702. Information handling system 120 may comprise a cache 712 of high-speed memory connected directly with, in close proximity to, or integrated as part of processor 702. Information handling system 120 copies data from memory 706 and/or storage device 714 to cache 712 for quick access by processor 702. In this way, cache 712 provides a performance boost that avoids processor 702 delays while waiting for data. These and other modules may control or be configured to control processor 702 to perform various operations or actions. Other system memory 706 may be available for use as well. Memory 706 may comprise multiple different types of memory with different performance characteristics. It may be appreciated that the disclosure may operate on information handling system 120 with more than one processor 702 or on a group or cluster of computing devices networked together to provide greater processing capability. Processor 702 may comprise any general-purpose processor and a hardware module or software module, such as first module 716, second module 718, and third module 720 stored in storage device 714, configured to control processor 702 as well as a special-purpose processor where software instructions are incorporated into processor 702. Processor 702 may be a self-contained computing system, containing multiple cores or processors, a bus, memory controller, cache, etc. A multi-core processor may be symmetric or asymmetric. Processor 702 may comprise multiple processors, such as a system having multiple, physically separate processors in different sockets, or a system having multiple processor cores on a single physical chip. Similarly, processor 702 may comprise multiple distributed processors located in multiple separate computing devices but working together such as via a communications network. Multiple processors or processor cores may share resources such as memory 706 or cache 712 or may operate using independent resources. Processor 702 may comprise one or more state machines, an application specific integrated circuit (ASIC), or a programmable gate array (PGA) including a field PGA (FPGA).

Each individual component discussed above may be coupled to system bus 704, which may connect each and every individual component to each other. System bus 704 may be any of several types of bus structures including a memory bus or memory controller, a peripheral bus, and a local bus using any of a variety of bus architectures. A basic input/output (BIOS) stored in ROM 708 or the like, may provide the basic routine that helps to transfer information between elements within information handling system 120, such as during start-up. Information handling system 120 further comprises storage devices 714 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. Storage device 714 may comprise software modules 716, 718, and 720 for controlling processor 702. Information handling system 120 may comprise other hardware or software modules. Storage device 714 is connected to the system bus 704 by a drive interface. The drives and the associated computer-readable storage devices provide nonvolatile storage of computer-readable instructions, data structures, program modules and other data for information handling system 120. In one aspect, a hardware module that performs a particular function comprises the software component stored in a tangible computer-readable storage device in connection with hardware components, such as processor 702, system bus 704, and so forth, to carry out a particular function. In another aspect, the system may use a processor and computer-readable storage device to store instructions which, when executed by the processor, cause the processor to perform operations, a method or other specific actions. The basic components and appropriate variations may be modified depending on the type of device, such as whether information handling system 120 is a small, handheld computing device, a desktop computer, or a computer server. When processor 702 executes instructions to perform “operations”, processor 702 may perform the operations directly and/or facilitate, direct, or cooperate with another device or component to perform the operations.

As illustrated, information handling system 120 employs storage device 714, which may be a hard disk or other types of computer-readable storage devices which may store data that are accessible by a computer, such as magnetic cassettes, flash memory cards, digital versatile disks (DVDs), cartridges, random access memories (RAMs) 610, read only memory (ROM) 708, a cable containing a bit stream and the like, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with information handling system 120, an input device 722 represents any number of input mechanisms, such as a microphone for speech, a touch-sensitive screen for gesture or graphical input, keyboard, mouse, motion input, speech and so forth. Additionally, input device 722 may receive one or more measurements from bottom-hole assembly 118 (e.g., referring to FIG. 1), discussed above. An output device 724 may also be one or more of a number of output mechanisms known to those of skill in the art. In some instances, multimodal systems enable a user to provide multiple types of input to communicate with information handling system 120. Communications interface 726 generally governs and manages the user input and system output. There is no restriction on operating on any particular hardware arrangement and therefore the basic hardware depicted may easily be substituted for improved hardware or firmware arrangements as they are developed.

As illustrated, each individual component described above is depicted and disclosed as individual functional blocks. The functions these blocks represent may be provided through the use of either shared or dedicated hardware, including, but not limited to, hardware capable of executing software and hardware, such as a processor 702, that is purpose-built to operate as an equivalent to software executing on a general-purpose processor. For example, the functions of one or more processors presented in FIG. 7 may be provided by a single shared processor or multiple processors. (Use of the term “processor” should not be construed to refer exclusively to hardware capable of executing software.) Illustrative examples may comprise microprocessor and/or digital signal processor (DSP) hardware, read-only memory (ROM) 708 for storing software performing the operations described below, and random-access memory (RAM) 710 for storing results. Very large-scale integration (VLSI) hardware examples, as well as custom VLSI circuitry in combination with a general-purpose DSP circuit, may also be provided.

FIG. 8 illustrates an example information handling system 120 having a chipset architecture that may be used in executing the described method and generating and displaying a graphical user interface (GUI). Information handling system 120 is an example of computer hardware, software, and firmware that may be used to implement the disclosed technology. Information handling system 120 may comprise a processor 702, representative of any number of physically and/or logically distinct resources capable of executing software, firmware, and hardware configured to perform identified computations. Processor 702 may communicate with a chipset 800 that may control input to and output from processor 702. In this example, chipset 800 outputs information to output device 724, such as a display, and may read and write information to storage device 714, which may comprise, for example, magnetic media, and solid-state media. Chipset 800 may also read data from and write data to RAM 710. A bridge 802 for interfacing with a variety of user interface components 804 may be provided for interfacing with chipset 800. Such user interface components 804 may comprise a keyboard, a microphone, touch detection and processing circuitry, a pointing device, such as a mouse, and so on. In general, inputs to information handling system 120 may come from any of a variety of sources, machine generated and/or human generated.

Chipset 800 may also interface with one or more communication interfaces 726 that may have different physical interfaces. Such communication interfaces may comprise interfaces for wired and wireless local area networks, for broadband wireless networks, as well as personal area networks. Some applications of the methods for generating, displaying, and using the GUI disclosed herein may comprise receiving ordered datasets over the physical interface or be generated by the machine itself by processor 702 analyzing data stored in storage device 714 or RAM 710. Further, information handling system 120 receives inputs from a user via user interface components 804 and executes appropriate functions, such as browsing functions by interpreting these inputs using processor 702.

In examples, information handling system 120 may also comprise tangible and/or non-transitory computer-readable storage devices for carrying or having computer-executable instructions or data structures stored thereon. Such tangible computer-readable storage devices may be any available device that may be accessed by a general purpose or special purpose computer, including the functional design of any special purpose processor as described above. By way of example, and not limitation, such tangible computer-readable devices may comprise RAM, ROM, EEPROM, CD-ROM or other optical disk storage, magnetic disk storage or other magnetic storage devices, or any other device which may be used to carry or store program code in the form of computer-executable instructions, data structures, or processor chip design. When information or instructions are provided via a network, or another communications connection (either hardwired, wireless, or combination thereof), to a computer, the computer properly views the connection as a computer-readable medium. Thus, any such connection is properly termed a computer-readable medium. Combinations of the above should also be comprised within the scope of the computer-readable storage devices.

Computer-executable instructions comprise, for example, instructions and data which cause a general-purpose computer, special purpose computer, or special purpose processing device to perform a certain function or group of functions. Computer-executable instructions also comprise programming modules that may be pre-executed by computers in stand-alone or network environments. Program modules comprise routines, programs, components, data structures, objects, and the functions inherent in the design of special-purpose processors, etc. that perform particular tasks or implement abstract data types. Computer-executable instructions, associated data structures, and program modules represent examples of the program code for executing steps of the methods disclosed herein. The particular sequence of such executable instructions or associated data structures represents examples of corresponding acts for implementing the functions described in such steps.

In additional examples, methods may be practiced in network computing environments with many types of computer system configurations, including personal computers, hand-held devices, multi-processor systems, microprocessor-based or programmable consumer electronics, network PCs, minicomputers, mainframe computers, and the like. Examples may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

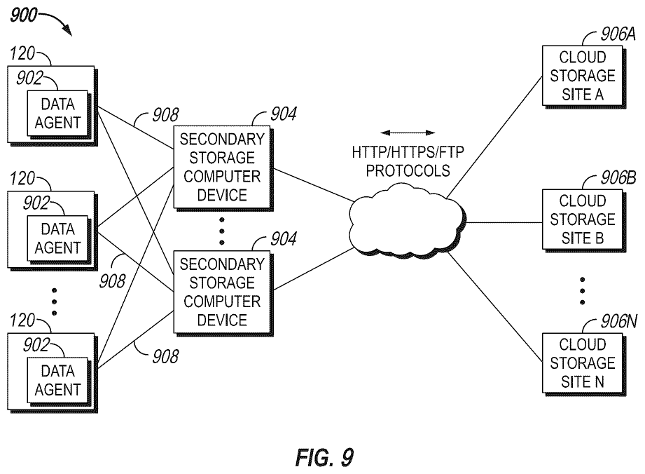

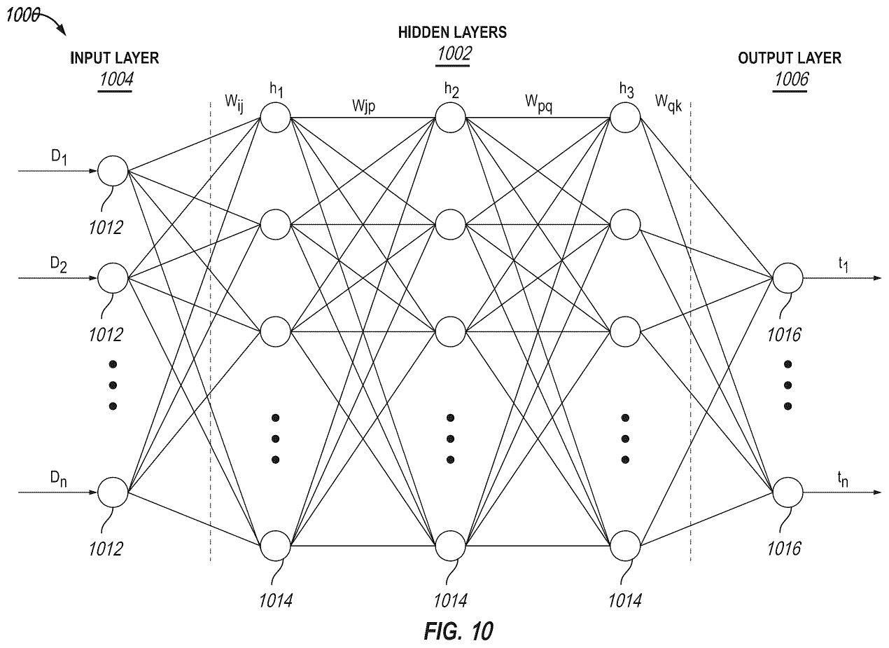

FIG. 9 illustrates an example of one arrangement of resources in a computing network 900 that may employ the processes and techniques described herein, although many others are of course possible. As noted above, an information handling system 120, as part of their function, may utilize data, which comprises files, directories, metadata (e.g., access control list (ACLS) creation/edit dates associated with the data, etc.), and other data objects. The data on the information handling system 120 is typically a primary copy (e.g., a production copy). During a copy, backup, archive or other storage operation, information handling system 120 may send a copy of some data objects (or some components thereof) to a secondary storage computing device 904 by utilizing one or more data agents 902.

A data agent 902 may be a desktop application, website application, or any software-based application that is run on information handling system 120. As illustrated, information handling system 120 may be disposed at any rig site (e.g., referring to FIG. 1), off site location, or repair and manufacturing center. The data agent may communicate with a secondary storage computing device 904 using communication protocol 908 in a wired or wireless system. Communication protocol 908 may function and operate as an input to a website application. In the website application, field data related to pre- and post-operations, generated DTCs, notes, and the like may be uploaded. Additionally, information handling system 120 may utilize communication protocol 908 to access processed measurements, operations with similar DTCs, troubleshooting findings, historical run data, and/or the like. This information is accessed from secondary storage computing device 904 by data agent 902, which is loaded on information handling system 120.

Secondary storage computing device 904 may operate and function to create secondary copies of primary data objects (or some components thereof) in various cloud storage sites 906A-N. Additionally, secondary storage computing device 904 may run determinative algorithms on data uploaded from one or more information handling systems 120, discussed further below. Communications between the secondary storage computing devices 904 and cloud storage sites 906A-N may utilize REST protocols (Representational state transfer interfaces) that satisfy basic C/R/U/D semantics (Create/Read/Update/Delete semantics), or other hypertext transfer protocol (“HTTP”)-based or file-transfer protocol (“FTP”)-based protocols (e.g., Simple Object Access Protocol).

In conjunction with creating secondary copies in cloud storage sites 906A-N, the secondary storage computing device 904 may also perform local content indexing and/or local object-level, sub-object-level or block-level deduplication when performing storage operations involving various cloud storage sites 906A-N. Cloud storage sites 906A-N may further record and maintain, EM logs, map DTC codes, store repair and maintenance data, store operational data, and/or provide outputs from determinative algorithms that are located in cloud storage sites 906A-N. In a non-limiting example, this type of network may be utilized as a platform to store, backup, analyze, import, preform extract, transform and load (“ETL”) processes, mathematically process, apply machine learning models, and augment EM measurement data sets.

A machine learning model may be an empirically derived model which may result from a machine learning algorithm identifying one or more underlying relationships within a dataset. In comparison to a physics-based model, such as Maxwell's Equations, which are derived from first principles and define the mathematical relationship of a system, a pure machine learning model may not be derived from first principles. Once a machine learning model is developed, it may be queried in order to predict one or more outcomes for a given set of inputs. The type of input data used to query the model to create the prediction may correlate both in category and type to the dataset from which the model was developed.

The structure of, and the data contained within a dataset provided to a machine learning algorithm may vary depending on the intended function of the resulting machine learning model. The rows of data, or data points, within a dataset may contain one or more independent values. Additionally, datasets may contain corresponding dependent values. The independent values of a dataset may be referred to as “features,” and a collection of features may be referred to as a “feature space.” If dependent values are available in a dataset, they may be referred to as outcomes or “target values.” Although dependent values may be a component of a dataset for certain algorithms, not all algorithms implement a dataset with dependent values. Furthermore, both the independent and dependent values of the dataset may comprise either numerical or categorical values.

While it may be true that machine learning model development is more successful with a larger dataset, it may also be the case that the whole dataset isn't used to train the model. A test dataset may be a portion of the original dataset which is not presented to the algorithm for model training purposes. Instead, the test dataset may be used for what may be known as “model validation,” which may be a mathematical evaluation of how successfully a machine learning algorithm has learned and incorporated the underlying relationships within the original dataset into a machine learning model. This may comprise evaluating model performance according to whether the model is over-fit or under-fit. As it may be assumed that all datasets contain some level of error, it may be important to evaluate and optimize the model performance and associated model fit by a model validation. In general, the variability in model fit (e.g.: whether a model is over-fit or under-fit) may be described by the “bias-variance trade-off.” As an example, a model with high bias may be an under-fit model, where the developed model is over-simplified, and has either not fully learned the relationships within the dataset or has over-generalized the underlying relationships. A model with high variance may be an over-fit model which has overlearned about non-generalizable relationships within training dataset which may not be present in the test dataset. In a non-limiting example, these non-generalizable relationships may be driven by factors such as intrinsic error, data heterogeneity, and the presence of outliers within the dataset. The selected ratio of training data to test data may vary based on multiple factors, including, in a non-limiting example, the homogeneity of the dataset, the size of the dataset, the type of algorithm used, and the objective of the model. The ratio of training data to test data may also be determined by the validation method used, wherein some non-limiting examples of validation methods comprise k-fold cross-validation, stratified k-fold cross-validation, bootstrapping, leave-one-out cross-validation, resubstituting, random subsampling, and percentage hold-out.

In addition to the parameters that exist within the dataset, such as the independent and dependent variables, machine learning algorithms may also utilize parameters referred to as “hyperparameters.” Each algorithm may have an intrinsic set of hyperparameters which guide what and how an algorithm learns about the training dataset by providing limitations or operational boundaries to the underlying mathematical workflows on which the algorithm functions. Furthermore, hyperparameters may be classified as either model hyperparameters or algorithm parameters.

Model hyperparameters may guide the level of nuance with which an algorithm learns about a training dataset, and as such model hyperparameters may also impact the performance or accuracy of the model that is ultimately generated. Modifying or tuning the model hyperparameters of an algorithm may result in the generation of substantially different models for a given training dataset. In some cases, the model hyperparameters selected for the algorithm may result in the development of an over-fit or under-fit model. As such, the level to which an algorithm may learn the underlying relationships within a dataset, including the intrinsic error, may be controlled to an extent by tuning the model hyperparameters.

Model hyperparameter selection may be optimized by identifying a set of hyperparameters which minimize a predefined loss function. An example of a loss function for a supervised regression algorithm may comprise the model error, wherein the optimal set of hyperparameters correlates to a model which produces the lowest difference between the predictions developed by the produced model and the dependent values in the dataset. In addition to model hyperparameters, algorithm hyperparameters may also control the learning process of an algorithm, however algorithm hyperparameters may not influence the model performance. Algorithm hyperparameters may be used to control the speed and quality of the machine learning process. As such, algorithm hyperparameters may affect the computational intensity associated with developing a model from a specific dataset.

Machine learning algorithms, which may be capable of capturing the underlying relationships within a dataset, may be broken into different categories. One such category may comprise whether the machine learning algorithm functions using supervised, unsupervised, semi-supervised, or reinforcement learning. The objective of a supervised learning algorithm may be to determine one or more dependent variables based on their relationship to one or more independent variables. Supervised learning algorithms are named as such because the dataset comprises both independent and corresponding dependent values where the dependent value may be thought of as “the answer,” that the model is seeking to predict from the underlying relationships in the dataset. As such, the objective of a model developed from a supervised learning algorithm may be to predict the outcome of one or more scenarios which do not yet have a known outcome. Supervised learning algorithms may be further divided according to their function as classification and regression algorithms. When the dependent variable is a label or a categorical value, the algorithm may be referred to as a classification algorithm. When the dependent variable is a continuous numerical value, the algorithm may be a regression algorithm. In a non-limiting example, algorithms utilized for supervised learning may comprise Neural Networks, K-Nearest Neighbors, Naïve Bayes, Decision Trees, Classification Trees, Regression Trees, Random Forests, Linear Regression, Support Vector Machines (SVM), Gradient Boosting Regression, and Perception Back-Propagation.

The objective of unsupervised machine learning may be to identify similarities and/or differences between the data points within the dataset which may allow the dataset to be divided into groups or clusters without the benefit of knowing which group or cluster the data may belong to. Datasets utilized in unsupervised learning may not comprise a dependent variable as the intended function of this type of algorithm is to identify one or more groupings or clusters within a dataset. In a non-limiting example, algorithms which may be utilized for unsupervised machine learning may comprise K-means clustering, K-means classification, Fuzzy C-Means, Gaussian Mixture, Hidden Markov Model, Neural Networks, and Hierarchical algorithms.

In examples to determine a relationship using machine learning, a neural network (NN) 1000, as illustrated in FIG. 10, may be utilized to identify white hydrogen from measurements taken by pulsed neutron logging tool 132 and/or NMR tool 134. FIG. 10 illustrates neural network (NN) 1000. NN 1000 may operate utilizing one or more information handling systems 120 (e.g., referring to FIG. 1) on computing network 900. Although a NN is illustrated, multiple models may be used with input output structures. These models may comprise flexible empirical models such as NN, gaussian processing methods, kriging methods, evolutionary methods such as genetic algorithms, classification methods, clustering methods empirical methods, or physics-based methods such as equations of state, thermodynamic models, geological, geochemistry, or chemistry models, or kinetic models or any combinations therein including recursive combinations of similar or dissimilar models and iterative model combinations. A NN 1000 is an artificial neural network with one or more hidden layers 1002 between input layer 1004 and output layer 1006. In examples, NN 1000 may be software on a single information handling system 120. In other examples, NN 1000 may software running on multiple information handling systems 120 connected wirelessly and/or by a hard-wired connection in a network of multiple information handling systems 120. Herein, NN 1000 may be applied in a wide array of implementations.

During operations, inputs 1008 data are given to neurons 1012 in input layer 1004. Neurons 1012, 1014, and 1016 are defined as individual or multiple information handling systems 120 connected in a computing network 900. The output from neurons 1012 may be transferred to one or more neurons 1014 within one or more hidden layers 1002. Hidden layers 1002 comprises one or more neurons 1014 connected in a network that further process information from neurons 1012. The number of hidden layers 1002 and neurons 1012 in hidden layer 1002 may be determined by personnel that designs NN 1000. Hidden layers 1002 is defined as a set of information handling system 120 assigned to specific processing. Hidden layers 1002 spread computation to multiple neurons 1012, which may allow for faster computing, processing, training, and learning by NN 1000. Output from NN 1000 may be computed by neurons 1016. An information handling system 120 (e.g., referring to FIG. 1) being utilized in a computing network 900, NN 1000, or alone may help identify white hydrogen within formation 126 using measurements form pulse neutron logging tool 132 and/or NMR tool 134.

Recent advancements in physics-informed machine learning (PIML) techniques present opportunities to enhance real-time inversion and interpretation of multiphysics logging data as disclosed herein. Methods comprising but not limited to, Physics-Informed Neural Networks (PINNs), Fourier Neural Operators (FNOs), DeepONets (Deep Operator Networks), Physics-Informed Gaussian Processes (PIGPs), and Graph Neural Networks (GNNs) are particularly well-suited for efficiently interpreting complex datasets derived from pulsed neutron logging, NMR logging, and surface data logging tools. Incorporating physics-informed machine learning examples significantly enhances the speed, accuracy, and interpretability of real-time multiphysics inversion, making them particularly advantageous in the context of white hydrogen exploration described herein.

Physics-Informed Neural Networks (PINN) s integrates the governing physical equations directly into the neural network architecture, enabling them to respect underlying physical laws such as neutron diffusion equations, nuclear magnetic relaxation models, and fluid-phase equilibrium equations. By enforcing constraints derived from these known physics models, PINNs significantly enhance the accuracy and interpretability of inversion outputs. This method is especially powerful in distinguishing subtle signatures indicative of naturally occurring hydrogen (white hydrogen), reducing uncertainty inherent in conventional data-driven methods.

Operator-based neural network architectures, including Fourier Neural Operators and Deep Operator Networks, offer accelerated and generalized solutions for real-time inversion tasks. FNOs, for example, leverage Fourier transformations to efficiently capture spatial correlations within multiphysics logging datasets, greatly accelerating the inversion of complex geophysical responses. Similarly, DeepONets facilitates fast real-time inference by learning operators capable of directly mapping sensor data into reservoir property predictions, significantly reducing computational overhead compared to traditional iterative inversion techniques.

Physics-Informed Gaussian Processes incorporate domain knowledge by embedding physical laws into the Gaussian process priors, thereby inherently managing uncertainty quantification and providing robust estimates of reservoir properties, including gas composition and saturation states. This makes them particularly beneficial in scenarios involving sparse or noisy multiphysics measurements, such as those encountered in neutron-induced gamma-ray spectroscopy and NMR relaxometry.

Graph-based methods like GNNs enable intuitive representation of complex relationships between logging sensors, subsurface geological features, and fluid distributions. By explicitly modeling these relationships as a graph structure informed by physical interactions and spatial correlations, GNNs offer rapid, accurate, and physically consistent real-time inversion of multiphysics data.

Employing these physics-informed machine learning methods ensures real-time capability in inversion tasks crucial for field operations. Rapid, physics-consistent interpretations enable operators to swiftly identify and delineate economically viable white hydrogen-bearing zones during logging operations. Moreover, integrating these methods with existing multiphysics logging examples, such as pulsed neutron, NMR, EOS modeling, and SDL analyses, produces a coherent and physically robust subsurface characterization framework, greatly improving operational decision-making and resource management.

Pulsed neutron logging tool 132, may take measurement that detect total hydrogen content within formation 126, but it does not have the capability to discern the molecular speciation of hydrogen-bearing compounds. In addition, any other measurement technique discussed above may also be applied for detecting total hydrogen content within formation 126. This means that while it may indicate the presence of hydrogen, it cannot differentiate between H₂, water, or hydrocarbons like methane (CH₄). On the other hand, NMR tool 134 may take measurements that separate methane from other gases based on its unique long T1 and short apparent T2 relaxation time. Thus, the T1/T2 apparent ratio is higher for proton in hydrocarbon gas than in liquid hydrocarbon gas or formation water. However, this T1/T2 apparent ratio parameter cannot be as effective in determining hydrogen gas, protons in H2 gas are reported to relax much faster than the protons in methane, thus the ratio is not as prominent. These factors make H₂ difficult to directly measure using standard NMR logging techniques, as the H₂ signal may decay too rapidly to be captured effectively. Consequently, while both pulsed neutron logging tool 132 and NMR tool 134 measurements contribute important insights, they are limited in their ability to independently and directly quantify hydrogen gas in its molecular form within the subsurface. On the other hand, the discernment of molecular hydrogen and the methane gas may be achieved with NMR relaxation time measurements as the large T₁ contrast between the two gases is a means to distinguish one from the other. Hydrogen gas may also be partially dissolved in the water in pore space, which may result in the water relaxation time and diffusivity change, and, thus, may be detected through NMR. Even though these features make NMR a direct fluid typing means for distinguishing molecular hydrogen from other pore fluids in the gas accumulation reservoirs however, due to the short relaxation time and the low hydrogen index of hydrogen gas compared to those in other liquid or gaseous phases of hydrogen bearing fluids, the NMR based hydrogen gas quantification could large uncertainties. With the integration of NMR and other logging sensor measurements, the uncertainty in quantification may be greatly reduced.

Combining NMR tool 134 for CH₄ measurements with pulsed neutron logging tool 132 measurements for total hydrogen index offers a promising example to identifying zones with high residual hydrogen content, which could be indicative of H₂. For example, NMR tool 134 may provide measurements of methane concentrations, while pulsed neutron logging tool 132 measurements capture the overall hydrogen content within formation 126. By comparing the methane-specific data from NMR tool 134 with the total hydrogen index from pulsed neutron logging tool 132, it is possible to identify discrepancies or residual hydrogen that cannot be accounted for by methane or water alone. These residuals may suggest the presence of H₂, particularly in formations 126 where other hydrogen-bearing compounds are less likely. This complementary use of NMR tool 134 measurements and pulsed neutron logging tool 132 measurements could thus enable a more nuanced interpretation of subsurface conditions, helping to pinpoint zones where H₂ concentrations are higher and potentially economically viable.

Once a potential zone of high residual hydrogen content is identified, which may be indicative of H₂, a stationary measurement using NMR tool 134 may be employed to improve the signal-to-noise ratio (SNR) and enhance the accuracy of the detection. By taking stationary measurements in the identified zone, the NMR pulse sequence may be specifically tuned to target H₂, thereby increasing the sensitivity of the measurement. Given the extremely short T1 relaxation time of H₂, a short repetition time pulse sequence such as the Carr-Purcell-Meiboom-Gill (CPMG) sequence could be effective. This sequence allows for rapid acquisition of multiple echoes, improving SNR while minimizing signal loss from the fast-relaxing H₂. Additionally, by carefully selecting the echo spacing to match the T2 relaxation time of H₂, this sequence may further enhance the detection capability. The stationary measurement example, combined with an optimized pulse sequence, provides a robust method to confirm the presence of H₂ in the formation, thereby strengthening the interpretation and reducing the uncertainty in evaluating the economic potential of the zone.

Using the methods and systems described above, surface data logging, using at least in part information handling system 120, may help in identifying broad areas of interest by providing an initial overview of the gas composition in the subsurface. This technique may confirm the ratio of hydrogen to other gases within a broad area, albeit as a merged signal that combines contributions from multiple layers as the gas travels up the mud system. Once these areas of interest are identified, measurements from NMR tool 134 and pulsed neutron logging tool 132 may be analyzed in a merged fashion to validate these ratios and detect any potential missing gases, such as He that does on rare occasion infiltrate the reservoir, that were not accounted for in the 4-gas model. Additionally, surface data logging gas chromatograms offer the capability to precisely identify and quantify the gases present in the sample. This allows for the elimination of certain gases from consideration, sharpening the focus on those that are present and may indicate the presence CO2, N2 or CH4. Elimination of all hydrocarbon gases may indicate measurements of signals obtained from NMR tool 134 and/or pulsed neutron logging tool 132 may be due to the presence of H2. Liquid or bound hydrogen is very separable in T1, T2 NMR space and may be directly accounted for in measurements from NMR tool 134. The integration of surface data logging with subsurface NMR tool 134 and pulsed neutron logging tool 132 measurements thus provides a comprehensive example to confirming the gas composition, improving the accuracy of hydrogen prospecting efforts.

Once high-potential layers are identified through conventional logging and surface data logging, formation testing may be employed to gather detailed information about the reservoir sections. This may comprise measuring the pressure within these potential reservoir sections to develop a pressure gradient, which is directly related to the reservoir's gas density. Formation testing allows for stationary measurements during pumpouts, where the methane content, and higher hydrocarbons, if necessary, along with CO₂ content, may be precisely determined. Additionally, the formation tester may record crucial parameters such as pressure, temperature, gas compressibility, viscosity, mobility and gas density during these pumpouts. The gas density measured by the pumpout sensor may then be calibrated against the density derived from the pressure gradient, ensuring accuracy and providing a comprehensive understanding of the reservoir's gas composition. This integration of formation testing with other logging data enables a more accurate characterization of the reservoir, further validating the presence and concentration of economically viable levels of hydrogen.

Information handling system 120 may utilize equation of state (EOS) modeling, which may be performed at least in part on information handling system 123, to quantitatively determine the concentrations of gas components within a reservoir, even for those gases that cannot be directly observed. By integrating data from at least two of the multiphysics tools discussed such as NMR tool 134, pulsed neutron logging tool 132, surface data logging (SDL) gas analysis, and formation testing, EOS modeling enables a more complete and accurate characterization of the gas mixture in the reservoir. The model works by describing the thermodynamic properties of the gas mixture, including pressure, temperature, volume, and composition, allowing for the estimation of the concentration of individual gas components based on available measurements. Further, utilizing multiple of the multiphysics measurements, a best fit estimate of the gas concentrations may be made. The best fit analysis may additionally be refined for the water saturated gas estimate. Also, by comprising the uncertainty estimates of each of the multiphysics measurements, an estimate of the gas concentration in the reservoir may be made that optimizes the total uncertainty.

When combining measurements from NMR tool 134 and formation testing with EOS modeling, the process begins with NMR tool 134, which may provide detailed information about the relaxation times (T1 and T2) of the gases present. While measurements from NMR tool 134 may directly measure methane (CH₄) concentrations, it may not directly observe hydrogen (H₂) due to its short T1 and T2 relaxation times. Formation testing, on the other hand, provides critical measurements of gas density, compressibility, pressure, temperature, and viscosity, along with the concentrations of gases like CH₄ and CO₂. These data points are crucial inputs for EOS modeling, which uses them to estimate the overall composition of the gas mixture, including components like H₂ and N₂ that are not directly detected by NMR tool 134 or formation tester.

EOS modeling may reconcile the NMR-derived methane concentrations with the overall gas density and compressibility measurements obtained from formation testing. By applying the EOS to this integrated dataset, it is possible to infer the presence and concentration of H₂ and other undetected gases. For instance, if the modeled gas density from the EOS is higher than what would be expected from the methane and CO₂ concentrations alone, the model may suggest the presence of additional gases like H₂, contributing to the overall density.

Another effective combination involves pulsed neutron logging and SDL gas analysis. Measurements from pulsed neutron logging tool 132 may provide a total hydrogen index, which reflects the presence of all hydrogen-bearing compounds in formation 126. However, it may not be able to distinguish between different hydrogen-containing molecules, such as H₂, CH₄, and water. SDL gas analysis, performed at the surface, may measure the relative concentrations of different gases, including those that might be difficult to detect downhole. These surface measurements, although they provide merged signals from various depths, may be integrated with downhole data in the EOS model to refine the interpretation.

In this case, EOS modeling takes the hydrogen index from pulsed neutron logging tool 134 measurements and compares it with the known concentrations of CH₄ and other gases from SDL analysis. By using the EOS to account for the contributions of each gas to the overall hydrogen index, the model may infer the proportion of hydrogen that may be attributed to H₂, as opposed to CH₄ or water. This quantitative determination is crucial for assessing the economic viability of hydrogen extraction from the reservoir, particularly in identifying zones where H₂ concentration is sufficiently high to warrant further development.

The stated combinations are exemplary and other combinations not directly stated may be combined using equation of state modeling. Equation of state (EOS) modeling techniques comprise a range of examples tailored to different applications, from the Ideal Gas Law, which assumes perfect gas behavior, to the Van der Waals equation, which corrects for molecular size and intermolecular forces. More sophisticated models like the Peng-Robinson and Soave-Redlich-Kwong (SRK) equations are widely used in petroleum engineering to predict the behavior of real gases under high pressure and temperature conditions. Additionally, PC-SAFT (Perturbed Chain-Statistical Associating Fluid Theory) offers a molecular-based EOS that is particularly effective for complex mixtures, such as those involving associating or polymeric fluids. Experimental techniques, such as laboratory PVT (Pressure-Volume-Temperature) analysis, complement these models by providing empirical data to refine and validate EOS predictions, ensuring accuracy in real-world applications.

Proxy modeling techniques, including but not limited to machine learning and symbolic regression models, as well as empirical modeling, may serve as effective alternatives to traditional equation of state (EOS) models. These examples leverage large datasets to identify patterns and relationships within complex systems, enabling the development of predictive models that may approximate the behavior of gas mixtures under various conditions. Machine learning models, for example, may be trained on historical data to predict gas properties with high accuracy, while symbolic regression may generate interpretable equations that mimic the underlying physics of the system. Empirical models, which are based on observed data rather than theoretical principles, may also provide reliable estimates for specific applications where conventional EOS models may fall short. These proxy models offer flexibility and adaptability, making them valuable tools in scenarios where traditional EOS methods are either too complex or not feasible.

The preceding description provides various examples of the systems and methods of use disclosed herein which may contain different method steps and alternative combinations of components.

Although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods may also “consist essentially of” or “consist of” the various components and steps. Moreover, the indefinite articles “a” or “an,” as used in the claims, are defined herein to mean one or more than one of the elements that it introduces.

For the sake of brevity, only certain ranges are explicitly disclosed herein. However, ranges from any lower limit may be combined with any upper limit to recite a range not explicitly recited, as well as ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any comprised range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present examples are well adapted to attain the ends and advantages mentioned as well as those that are inherent therein. The particular examples disclosed above are illustrative only and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

In examples, methods and systems disclosed herein may comprise formation testing. A method for detecting the presence of at least one selectively one reactive component within the subsurface formation fluid reactive component within a subsurface formation fluid using a formation-testing tool, comprising: positioning the formation-testing tool in contact with the subsurface formation at a selected depth containing a selectively reactive contrast agent; drawing formation fluid into the internal measurement module, thereby enabling selective reaction between the contrast agent and the selectively reactive component present in said formation fluid; detecting changes induced by the selective reaction using at least one internal sensor within the formation-testing tool, wherein the at least one internal sensor measures formation fluid properties selected from the group consisting of optical properties, fluid density, capacitance, dielectric permittivity, resistivity, ultrasonic acoustic response, nuclear magnetic resonance relaxation, and fluid mobility; and interpreting the detected changes in the measured formation fluid properties to determine the presence and/or concentration of the selectively reactive component within the subsurface formation fluid.

In other examples, methods and systems disclosed herein may comprise safety. A method of enhancing operational safety during drilling operations by selectively capturing molecular hydrogen (H₂) from subsurface formations, comprising: circulating within a wellbore a drilling mud composition containing at least one selectively reactive contrast agent, wherein said contrast agent specifically reacts chemically with molecular hydrogen entering the drilling mud during drilling; selectively converting molecular hydrogen present within said drilling mud into a chemically immobilized and stable reaction product, thereby significantly reducing the concentration of free hydrogen gas circulating within the drilling mud system; and safely returning said drilling mud to surface, wherein the chemically immobilized hydrogen is retained within the mud composition, thereby minimizing surface accumulation of combustible hydrogen gas and substantially improving drilling operational safety.

In examples, methods and systems disclosed herein may comprise field characterizations. A method of field calibration for petrophysical logging tools for detecting molecular hydrogen (H₂) in subsurface formations, comprising: selecting a representative subterranean reservoir formation having petrophysical and geological characteristics substantially similar to a formation targeted for hydrogen exploration; introducing a known concentration of molecular hydrogen into said representative reservoir formation through an injection method selected from the group consisting of coiled tubing injection, drill stem testing injection, and formation-tester injection; performing one or more baseline petrophysical logging measurements prior to hydrogen introduction to obtain initial reservoir property data; performing subsequent petrophysical logging measurements after the introduction of said known concentration of molecular hydrogen, thereby obtaining altered reservoir property data; analyzing and comparing the baseline and altered reservoir property data to determine characteristic logging responses indicative of molecular hydrogen presence; and using the determined characteristic logging responses as calibration standards for interpreting logging measurements performed in other analogous subterranean formations to accurately identify and quantify the presence of molecular hydrogen therein.

In examples, methods and systems disclosed herein may comprise a formation testing sensor. The method comprising performing downhole fluid characterization using a chip-based mass spectroscopy sensor, wherein said chip-based mass spectroscopy sensor comprises: a microfabricated mass spectrometry chip pre-packaged within an ultrahigh vacuum-sealed static measurement chamber configured to selectively detect at least one of molecular hydrogen (H₂), atomic hydrogen (H), helium (He), nitrogen (N₂), carbon dioxide (CO₂), hydrogen sulfide (H₂S), water vapor (H₂O), or methane (CH₄) or mercury (Hg); an integrated ionization source selected from the group consisting of a miniature radioactive ionization source and a vacuum ultraviolet (VUV) ionization source; and an internal getter material comprising at least one of a zeolite sorbent, a chemically active getter, or a desiccant material, configured to maintain the ultrahigh vacuum condition and to remove interfering water vapor or contaminants from the sample gas prior to analysis, wherein the chip-based sensor analyzes gas samples of volume ranging from microliters to nanoliters extracted from the subsurface formation fluid.

In examples, methods and systems disclosed herein may comprise sample preservation. A method for preserving molecular hydrogen (H₂) in subsurface samples obtained from a geological formation, comprising: providing at least one hydrogen-selective reactive contrast agent configured to chemically react with and immobilize molecular hydrogen; placing said reactive contrast agent in direct contact with at least one subsurface sample selected from the group consisting of core samples and fluid samples collected at or near bottom-hole reservoir conditions, wherein said contact occurs either (i) within the subsurface formation prior to sample collection, (ii) within a coring device configured to recover said core sample, or (iii) within a sealed sample chamber configured to collect and store said fluid sample; allowing molecular hydrogen present within the subsurface sample or released from the subsurface sample upon depressurization to chemically react with said contrast agent, thereby chemically immobilizing said molecular hydrogen and substantially reducing hydrogen loss during sample recovery and transport to surface; and transporting said subsurface sample to surface in a preserved state, wherein the molecular hydrogen remains chemically immobilized within said sample, thereby enabling accurate measurement and characterization of hydrogen content within said subsurface sample.

In examples, methods and systems disclosed herein may comprise patterning of pill injection. A method of characterizing a subsurface formation by patterned injection of reactive fluid pills, comprising: injecting at least one reactive pill containing a contrast agent into a wellbore fluid intermittently at characteristic and predetermined depths or intervals during a drilling or completion operation, wherein said contrast agent is chemically reactive with at least one targeted formation-fluid or mineralogical component; allowing the reactive pill to infiltrate, invade, or diffuse into the formation at the predetermined depths or intervals, thereby selectively reacting with said targeted formation-fluid or mineralogical component to form reaction products or byproducts within the formation, said reaction products or byproducts having distinct petrophysical properties measurable by downhole logging techniques; performing at least one downhole petrophysical logging measurement after infiltration of the reactive pills, said logging measurement selected from the group consisting of acoustic logging, electromagnetic logging, nuclear logging, nuclear magnetic resonance logging, dielectric logging, porosity logging, permeability logging, and formation testing measurements; identifying a recognizable vertical or lateral pattern of formation property alteration, clearly distinguishing intervals with injected reactive pills from baseline intervals without injected reactive pills; and interpreting said pattern to determine the presence, spatial distribution, or concentration of said targeted formation-fluid or mineralogical component within the subsurface formation.

In examples, methods and systems disclosed herein may comprise detection of mineralogy producing potential. A method for assessing the hydrogen-production potential of minerals within a subsurface formation, comprising: introducing water or a water-based fluid into a subsurface formation at reservoir conditions sufficient to stimulate a hydrogen-producing reaction with reactive minerals present within said formation, thereby producing molecular hydrogen (H₂); capturing said produced molecular hydrogen by reaction with a reactive contrast agent specifically configured to chemically immobilize molecular hydrogen, resulting in formation-property alterations detectable by downhole logging techniques; conducting downhole petrophysical logging measurements after said reactions to quantitatively measure said alterations in formation properties and to quantify the produced hydrogen; analyzing said measured formation-property alterations to determine the rate, extent, and efficiency of hydrogen generation from mineral-water interactions; and using the determined hydrogen generation characteristics to evaluate and quantify the overall hydrogen-production potential and economic viability of the subsurface formation.

In examples, methods and systems disclosed herein may comprise detection of hydrogen producing minerals. A method for detecting and characterizing hydrogen-producing mineralogy within a subsurface formation, comprising: introducing water into the subsurface formation, thereby initiating a geochemical reaction with hydrogen-producing minerals present within the formation to generate molecular hydrogen (H₂); subsequently introducing a reactive contrast agent specifically configured to chemically react with and immobilize said molecular hydrogen within the formation, thereby forming stable reaction products or byproducts having measurable petrophysical properties; performing at least one downhole petrophysical logging measurement selected from the group consisting of acoustic logging, electromagnetic logging, nuclear logging, nuclear magnetic resonance logging, dielectric logging, porosity logging, permeability logging, and formation testing measurements to detect said stable reaction products or byproducts; and

interpreting the measurable petrophysical properties detected by said logging measurement to identify the presence, distribution, and concentration of hydrogen-producing mineralogy within the subsurface formation.

In examples, methods and systems disclosed herein may comprise Equation of State Modeling. A method for identifying molecular hydrogen (H₂) within a subterranean reservoir, the method comprising: obtaining multiphysics logging data from at least two measurements from at least one of a neutron logging tool, a nuclear magnetic resonance (NMR) logging tool, a surface data logging (SDL) system, and a formation testing system; integrating the obtained multiphysics logging data using an equation of state (EOS) model configured to represent thermodynamic relationships between reservoir pressure, temperature, gas compressibility, and gas density; modeling the composition of a gas mixture within the subterranean reservoir based at least in part on the EOS model and the multiphysics logging data; and determining a concentration of molecular hydrogen (H₂) by quantifying residual hydrogen content not accounted for by other identified gases within the modeled gas mixture.

In examples, methods and systems disclosed herein may comprise Surface Data Logging. A method for identifying naturally occurring molecular hydrogen (H₂) in a subterranean formation, comprising: circulating a drilling fluid through a borehole and recovering the drilling fluid at surface, wherein the drilling fluid is formulated with components selected to minimize or prevent chemical reaction with molecular hydrogen; performing Surface Data Logging (SDL) at surface on gases extracted from the recovered drilling fluid, wherein the SDL comprises gas chromatography, isotopic analysis, or a combination thereof; analyzing a signature of hydrogen or hydrogen-reacted components present in the extracted gases to determine a at least one of presence, concentration and origin of molecular hydrogen.

In examples, methods and systems disclosed herein may comprise Stationary NMR measurement to enhance resolution separation. A method for detecting molecular hydrogen (H₂) from other forms of hydrogen within a subterranean formation using Nuclear Magnetic Resonance (NMR), comprising: identifying a zone of interest likely containing molecular hydrogen based on preliminary NMR logging measurements; positioning an NMR logging tool within the identified zone of interest; performing stationary NMR measurements using an optimized pulse sequence configured to detect fluids characterized by rapid nuclear magnetic relaxation times, with pulse spacing selected to match the T2 relaxation characteristics of molecular hydrogen; acquiring multiple NMR echoes in rapid succession to enhance signal-to-noise ratio (SNR) specific to molecular hydrogen; and processing the acquired stationary NMR measurements to quantify the concentration of molecular hydrogen present within the subterranean formation.

In examples, methods and systems disclosed herein may comprise physics informed machine learning. A method for identifying and quantifying molecular hydrogen (H₂) within a subterranean formation, comprising: acquiring multiphysics logging measurements from at least two measurements from at least one logging tool selected from a pulsed neutron logging tool, a nuclear magnetic resonance (NMR) logging tool, an acoustic logging tool, and a formation testing tool; integrating the acquired multiphysics logging measurements using a physics-informed machine learning model, wherein the physics-informed machine learning model comprises at least one of: constraining the physics-informed machine learning model with governing physical equations selected from neutron diffusion equations, nuclear magnetic relaxation equations, acoustic wave propagation equations, fluid transport equations, equations of state, or combinations thereof; and generating, from the physics-informed machine learning model, a quantitative interpretation indicating the presence, concentration, and spatial distribution of molecular hydrogen within the subterranean formation. Wherein the physics informed machine learning model is one of: a Physics-Informed Neural Network (PINN), a Fourier Neural Operator (FNO), a Deep Operator Network (DeepONet), a Physics-Informed Gaussian Process (PIGP), or a Graph Neural Network (GNN).

In examples, methods and systems disclosed herein may comprise long-term integrity monitoring. A method for long-term integrity monitoring of cemented wellbores or storage facilities, comprising: embedding permanently mounted sensor devices into a cement sheath, at cement-formation interfaces, or within the formation adjacent to cemented zones, said sensor devices configured to remain dormant under conditions of maintained integrity and to activate upon exposure to migrating molecular hydrogen or another targeted reactive fluid; configuring said sensor devices upon activation to emit detectable signals selected from acoustic, electromagnetic, electrical, or pressure-change signals; and remotely detecting said emitted signals to confirm fluid migration, hydrogen leakage, or degradation of cement or formation integrity.

In examples, methods and systems disclosed herein may comprise remote monitoring. A method for remotely monitoring well integrity using dormant sensors activated by hydrogen or other reactive fluids, comprising: positioning at least one dormant sensor device configured for low-power operation within or adjacent to cemented regions, said sensor device activating only upon exposure to molecular hydrogen or another targeted fluid; causing the activated sensor device to alter a local acoustic, electrical, or magnetic field, thereby modifying a signal propagating through a nearby telemetry transmission line or a fiber-optic cable without direct physical connection; and interpreting changes in said propagating signal remotely at the surface or another monitoring station, thereby indicating fluid leakage or reservoir integrity breach.

In examples, methods and systems disclosed herein may comprise monitoring hydrogen leakage. A system for permanently monitoring hydrogen leakage or reservoir-fluid migration at surface installations, comprising: deploying surface-mounted sensors selected from MEMS-based, microfluidic, optical, electroscopic, or electrophoretic hydrogen sensors positioned on or near pipelines, wellheads, processing equipment, or storage facilities; continuously or intermittently detecting hydrogen presence indicative of leakage or unintended fluid migration; and automatically triggering corrective actions, including at least one of automatic valve closures, automated sealing mechanisms, or activation of reservoir self-healing technologies, thereby mitigating leakage and maintaining facility integrity.

In examples, methods and systems disclosed herein may comprise long-term integrity monitoring. A method for long-term integrity and leakage monitoring of subsurface reservoirs, pipelines, subsea risers, downhole equipment, or surface equipment, comprising: embedding selectively reactive contrast agents or dormant sensors responsive to targeted reactive fluids within coatings, linings, insulation, or structural interfaces of said infrastructure; allowing said contrast agents or dormant sensors to activate upon exposure to fluid leakage or migration, thereby producing measurable changes detectable by acoustic, electromagnetic, nuclear, dielectric, or nuclear magnetic resonance logging methods or remotely probed sensing methods; and continuously or periodically monitoring said measurable changes to ensure ongoing integrity, containment effectiveness, and operational safety of infrastructure and equipment.

In examples, methods and systems disclosed herein may comprise A method for monitoring cement integrity and detecting leakage of molecular hydrogen (H₂) within a wellbore. Such methods and systems comprise: embedding at least one hydrogen-reactive contrast agent within a cement composition, or placing said hydrogen-reactive contrast agent at an interface between the cement and the formation, or within a mud cake layer disposed behind a cement sheath; allowing said reactive contrast agent to chemically react upon exposure to molecular hydrogen migrating through or around the cement barrier, thereby forming reaction products having measurable changes in at least one property selected from the group consisting of acoustic impedance, electromagnetic response, nuclear response, dielectric properties, and nuclear magnetic resonance characteristics; performing downhole logging measurements sensitive to said measurable changes; and interpreting the measured changes to identify hydrogen leakage and assess cement integrity.
Statement 1. A method for comprising: disposing a downhole tool into a subsurface formation; embedding a contrast agent composition at a first position with the downhole tool, wherein the contrast agent composition reacts with at least one target subsurface fluid or gas migrating through or around a barrier forming one or more reaction products; performing one or more formation logging measurements capable of detecting one or more reaction products with the downhole tool; and analyzing the one or more formation logging measurements for hydrogen leakage.
Statement 2. The method of statement 1, wherein the first position is within a cement composition.
Statement 3. The method of statement 2, wherein contrast agents within a cement composition allows for detecting hydrogen migration through micro annuli, fractures, or porosity within a cement sheath itself.
Statement 4. The method of statements 1-3, wherein the first position at an interface between cement and subsurface formation.
Statement 5. The method of statement 4, wherein contrast agent composition is bound or adsorbed onto solid carriers comprising cellulose-based fibers, nanoparticles, or a non-filterable additives to ensure stable positioning.
Statement 6. The method of statements 1-5, wherein the first position is within a mud cake layer disposed behind a cement sheath.
Statement 7. The method of statements 1-6, wherein the contrast agent composition is a hydrogen-reactive contrast agent.
Statement 8. The method of statements 1-7, wherein the reaction products comprise measurable changes in at least one property comprising acoustic impedance, electromagnetic response, nuclear response, dielectric properties, nuclear magnetic resonance characteristics, optical properties, thermal properties, pressure, or any measurable property.
Statement 9. The method of statements 1-8, further comprising finding damage patterns within a cement sheath comprising micro annuli formation, radial or axial fractures, or general cement deterioration from the one or more reaction products.
Statement 10. The method of statements 1-9, further comprising performing one or more formation logging measurements of the one or more reaction products with one or more radio-frequency identification (RFID) tags.
Statement 11. The method of statements 1-10, wherein at least one target subsurface fluid or gas is hydrogen, hydrogen sulfide, carbon dioxide, methane, ethane, any downhole fluid or gas and/or any combination thereof.
Statement 12. The method of statements 1-11, wherein the barrier is a cement barrier, a packer, or a swellable metal alloy.
Statement 13. A system comprising: a downhole tool disposed into a subsurface formation configured to: embed a contrast agent composition at a first position with the downhole tool, wherein the contrast agent composition reacts with at least one target subsurface fluid or gas migrating through or around a barrier forming one or more reaction products; and perform one or more formation logging measurements capable of detecting one or more reaction products with the downhole tool; and an information handling system in communication with the downhole tool and configured to: analyze the one or more formation logging measurements for hydrogen leakage.
Statement 14. The system of statement 13, wherein the first position is within a cement composition.
Statement 15. The system of statement 14, wherein contrast agents within a cement composition allows for detecting hydrogen migration through micro annuli, fractures, or porosity within a cement sheath itself.
Statement 16. The system of statements 13-15, wherein the first position at an interface between cement and subsurface formation.
Statement 17. The system of statement 16, wherein contrast agent composition is bound or adsorbed onto solid carriers comprising cellulose-based fibers, nanoparticles, or a non-filterable additives to ensure stable positioning.
Statement 18. The system of statements 13-17, wherein the first position is within a mud cake layer disposed behind a cement sheath.
Statement 19. The system of statements 13-18, wherein the contrast agent composition is a hydrogen-reactive contrast agent.
Statement 20. The system of statements 13-19, wherein the reaction products comprise measurable changes in at least one property comprising acoustic impedance, electromagnetic response, nuclear response, dielectric properties, nuclear magnetic resonance characteristics, optical properties, thermal properties, pressure, or any measurable property.

The preceding description provides various examples of the systems and methods of use disclosed herein which may contain different method steps and alternative combinations of components. It should be understood that, although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the elements that it introduces.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present examples are well adapted to attain the ends and advantages mentioned as well as those that are inherent therein. The particular examples disclosed above are illustrative only and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

What is claimed is:

1. A method for comprising:
disposing a downhole tool into a subsurface formation;
embedding a contrast agent composition at a first position with the downhole tool, wherein the contrast agent composition reacts with at least one target subsurface fluid or gas migrating through or around a barrier forming one or more reaction products;
performing one or more formation logging measurements capable of detecting one or more reaction products with the downhole tool; and
analyzing the one or more formation logging measurements for hydrogen leakage.

2. The method of claim 1, wherein the first position is within a cement composition.

3. The method of claim 2, wherein contrast agents within a cement composition allows for detecting hydrogen migration through micro annuli, fractures, or porosity within a cement sheath itself.

4. The method of claim 1, wherein the first position at an interface between cement and subsurface formation.

5. The method of claim 4, wherein contrast agent composition is bound or adsorbed onto solid carriers comprising cellulose-based fibers, nanoparticles, or a non-filterable additives to ensure stable positioning.

6. The method of claim 1, wherein the first position is within a mud cake layer disposed behind a cement sheath.

7. The method of claim 1, wherein the contrast agent composition is a hydrogen-reactive contrast agent.

8. The method of claim 1, wherein the reaction products comprise measurable changes in at least one property comprising acoustic impedance, electromagnetic response, nuclear response, dielectric properties, nuclear magnetic resonance characteristics, optical properties, thermal properties, pressure, or any measurable property.

9. The method of claim 1, further comprising finding damage patterns within a cement sheath comprising micro annuli formation, radial or axial fractures, or general cement deterioration from the one or more reaction products.

10. The method of claim 1, further comprising performing one or more formation logging measurements of the one or more reaction products with one or more radio-frequency identification (RFID) tags.

11. The method of claim 1, wherein at least one target subsurface fluid or gas is hydrogen, hydrogen sulfide, carbon dioxide, methane, ethane, any downhole fluid or gas and/or any combination thereof.

12. The method of claim 1, wherein the barrier is a cement barrier, a packer, or a swellable metal alloy.

13. A system comprising:
a downhole tool disposed into a subsurface formation configured to:
embed a contrast agent composition at a first position with the downhole tool, wherein the contrast agent composition reacts with at least one target subsurface fluid or gas migrating through or around a barrier forming one or more reaction products; and
perform one or more formation logging measurements capable of detecting one or more reaction products with the downhole tool; and
an information handling system in communication with the downhole tool and configured to:
analyze the one or more formation logging measurements for hydrogen leakage.

14. The system of claim 13, wherein the first position is within a cement composition.

15. The system of claim 14, wherein contrast agents within a cement composition allows for detecting hydrogen migration through micro annuli, fractures, or porosity within a cement sheath itself.

16. The system of claim 13, wherein the first position at an interface between cement and subsurface formation.

17. The system of claim 16, wherein contrast agent composition is bound or adsorbed onto solid carriers comprising cellulose-based fibers, nanoparticles, or a non-filterable additives to ensure stable positioning.

18. The system of claim 13, wherein the first position is within a mud cake layer disposed behind a cement sheath.

19. The system of claim 13, wherein the contrast agent composition is a hydrogen-reactive contrast agent.

20. The system of claim 13, wherein the reaction products comprise measurable changes in at least one property comprising acoustic impedance, electromagnetic response, nuclear response, dielectric properties, nuclear magnetic resonance characteristics, optical properties, thermal properties, pressure, or any measurable property.
